(19) United States
(12) Patent Application Publication
(10) Pub. No.: US 2022/0379525 A1
(43) Pub. Date: Dec. 1, 2022

(54) COMPOSITIONS AND METHODS FOR THREE-DIMENSIONAL PRINTING

(71) Applicant: Holo, Inc., Newark, CA (US)

(72) Inventors: Brian ADZIMA, Millbrae, CA (US); Satyajit BANERJEE, Hercules, CA (US); Hany Basam EITOUNI, Oakland, CA (US)

(21) Appl. No.: 17/742,883

(22) Filed: May 12, 2022

Related U.S. Application Data
(63) Continuation of application No. PCT/US20/60552, filed on Nov. 13, 2020.
(60) Provisional application No. 62/935,783, filed on Nov. 15, 2019.
(60) Provisional application No. 62/939,251, filed on Nov. 22, 2019.

(51) Int. Cl. B29C 35/08; B33Y 10/00; B33Y 70/10; B29C 64/124

(52) U.S. Cl. CPC B29C 35/0805; B33Y 10/00; B33Y 70/10; B29C 64/124; B29K 2101/00

(57) ABSTRACT

The present disclosure provides mixtures, systems, and methods for printing a three-dimensional (3D) object. In some aspects, the present disclosure provides a mixture for printing a 3D object, comprising a plurality of granulated particles. In some aspects, the present disclosure provides a mixture for printing a 3D object, comprising a plurality of precursor compounds configured to react to form a plurality of particles.

### CROSS-REFERENCE

This application is a continuation of International Patent Application No. PCT/US20/60552, filed Nov. 13, 2020, which claims the benefit of U.S. Provisional Patent Application No. 62/935,783, filed Nov. 15, 2019, and U.S. Provisional Patent Application No. 62/939,251, filed Nov. 22, 2019, each of which is entirely incorporated herein by reference.

### BACKGROUND

Additive manufacturing techniques, such as three-dimensional (3D) printing, are rapidly being adopted as useful techniques for a number of different applications, including rapid prototyping and fabrication of specialty components. Examples of 3D printing include powder-based printing, fused deposition modeling (FDM), and stereolithography (SLA).

Photopolymer-based 3D printing technology (e.g., SLA) may produce a 3D structure in a layer-by-layer fashion by using light to selectively cure polymeric precursors into a polymeric material within a photoactive resin. Photopolymer-based 3D printers that use bottom up illumination may project light upwards through an optically transparent window of a vat containing photoactive resin to cure at least a portion of the resin. Such printers may build a 3D structure by forming one layer at a time, where a subsequent layer adheres to the previous layer. In some cases, the photoactive resin may comprise a plurality of particles to build a 3D structure comprising the plurality of particles.

### SUMMARY

The present disclosure describes technologies relating to three-dimensional (3D) printing, e.g., metal and/or ceramic 3D printing. In some aspects, the present disclosure describes modifying a morphology of one or more particles to improve 3D printing processes (e.g., production speed, volume, or efficiency) or quality (e.g., resolution, size reduction or expansion) of a final 3D structure.

An aspect of the present disclosure provides a mixture for printing a 3D object, comprising: a plurality of polymer precursors; and a plurality of granulated particles, which plurality of granulated particles comprises a granulated particle having a cross-sectional size greater than 10 micrometers, wherein the granulated particle comprises an aggregation of a plurality of individual particles.

In some embodiments, the mixture comprises the plurality of granulated particles at an amount of at least 5% by weight of the mixture. In some embodiments, the mixture comprises the plurality of granulated particles at an amount of at most 50% by weight of the mixture. In some embodiments, the mixture comprises the plurality of granulated particles at an amount of at most 80% by weight of the mixture.

In some embodiments of any one of the mixtures disclosed herein, the cross-sectional size of the granulated particle is greater than 50 micrometers. In some embodiments of any one of the mixtures disclosed herein, the cross-sectional size of the granulated particle is greater than 100 micrometers. In some embodiments of any one of the mixtures disclosed herein, an individual particle of the plurality of individual particles has a cross-sectional size greater than 500 nanometers. In some embodiments of any one of the mixtures disclosed herein, an individual particle of the plurality of individual particles has a cross-sectional size greater than 1 micrometer.

In some embodiments of any one of the mixtures disclosed herein, the granulated particle further comprises a binder configured to bind at least a portion of the plurality of individual particles.

In some embodiments of any one of the mixtures disclosed herein, the plurality of individual particles comprises at least one metal particle or at least one ceramic particle. In some embodiments, the at least one metal particle comprises a material selected from the group consisting of stainless steel, copper, titanium, cobalt, chromium, tungsten, gold, silver, platinum, palladium, rhodium, and alloys thereof. In some embodiments, the at least one ceramic particle comprises a material selected from the group consisting of aluminum nitride, silicon carbide, silicon nitride, tungsten carbide cobalt, tungsten carbide copper, silica, alumina, titania, and yttria. In some embodiments of any one of the mixtures disclosed herein, the granulated particle comprises amorphous carbon, lamp black, or pyrolytic graphite.

In some embodiments of any one of the mixtures disclosed herein, the plurality of individual particles comprises one or more water-atomized individual particles.

In some embodiments of any one of the mixtures disclosed herein, the mixture further comprises an initiator configured to initiate formation of a polymeric material from at least a subset of the plurality of polymer precursors upon exposure to a stimulus. In some embodiments, the initiator is a photoinitiator. In some embodiments, wherein the stimulus is electromagnetic radiation.

In some embodiments of any one of the mixtures disclosed herein, the mixture further comprises an inhibitor configured to inhibit formation of a polymeric material from at least a subset of the plurality of polymer precursors upon exposure to a stimulus. In some embodiments, the inhibitor is a photoinhibitor. In some embodiments, the stimulus is electromagnetic radiation.

Another aspect of the present disclosure provides a green body for forming a 3D object, comprising: a plurality of granulated particles, which plurality of granulated particles comprises a granulated particle having a cross-sectional size greater than 10 micrometers, wherein the granulated particle comprises an aggregation of a plurality of individual particles; and a polymeric material at least partially encapsulating the granulated particle.

In some embodiments, the green body comprises the plurality of granulated particles at an amount of at least 5% by weight of the green body. In some embodiments, the green body comprises the plurality of granulated particles at an amount of at most 80% by weight of the green body.

In some embodiments of any one of the green bodies disclosed herein, the cross-sectional size of the granulated particle is greater than 50 micrometers. In some embodiments, the cross-sectional size of the granulated particle is greater than 100 micrometers. In some embodiments, an individual particle of the plurality of individual particles has a cross-sectional size greater than 500 nanometers. In some embodiments, an individual particle of the plurality of individual particles has a cross-sectional size greater than 1 micrometer.

In some embodiments of any one of the green bodies disclosed herein, the granulated particle further comprises a binder configured to bind at least a portion of the plurality of individual particles.

In some embodiments of any one of the green bodies disclosed herein, the plurality of individual particles comprises at least one metal particle or at least one ceramic particle. In some embodiments, the at least one metal particle comprises a material selected from the group consisting of stainless steel, copper, titanium, cobalt, chromium, tungsten, gold, silver, platinum, palladium, rhodium, and alloys thereof. In some embodiments, the at least one ceramic particle comprises a material selected from the group consisting of aluminum nitride, silicon carbide, silicon nitride, tungsten carbide cobalt, tungsten carbide copper, silica, alumina, titania, and yttria. In some embodiments, the granulated particle comprises amorphous carbon, lamp black, or pyrolytic graphite.

In some embodiments of any one of the green bodies disclosed herein, the plurality of individual particles comprises one or more water-atomized individual particles.

Another aspect of the present disclosure provides a method for printing a three-dimensional (3D) object, comprising: (a) providing a mixture comprising (i) a plurality of polymer precursors and (ii) a plurality of granulated particles, which plurality of granulated particles comprises a granulated particle having a cross-sectional size greater than 10 micrometers, wherein the granulated particle comprises an aggregation of a plurality of individual particles; and (b) exposing the mixture to a stimulus to cause at least a subset of the plurality of polymer precursors to form a polymeric material that at least partially encapsulates the granulated particle.

In some embodiments, the mixture comprises the plurality of granulated particles at an amount of at least 5% by weight of the mixture. In some embodiments, the mixture comprises the plurality of granulated particles at an amount of at most 50% by weight of the mixture. In some embodiments, the mixture comprises the plurality of granulated particles at an amount of at most 80% by weight of the mixture.

In some embodiments of any one of the methods disclosed herein, the cross-sectional size of the granulated particle is greater than 50 micrometers. In some embodiments, the cross-sectional size of the granulated particle is greater than 100 micrometers. In some embodiments, an individual particle of the plurality of individual particles has a cross-sectional size greater than 500 nanometers. In some embodiments, an individual particle of the plurality of individual particles has a cross-sectional size greater than 1 micrometer.

In some embodiments of any one of the methods disclosed herein, the granulated particle further comprises a binder configured to bind at least a portion of the plurality of individual particles.

In some embodiments of any one of the methods disclosed herein, the plurality of individual particles comprises at least one metal particle or at least one ceramic particle. In some embodiments, the at least one metal particle comprises a material selected from the group consisting of stainless steel, copper, titanium, cobalt, chromium, tungsten, gold, silver, platinum, palladium, rhodium, and alloys thereof. In some embodiments, the at least one ceramic particle comprises a material selected from the group consisting of aluminum nitride, silicon carbide, silicon nitride, tungsten carbide cobalt, tungsten carbide copper, silica, alumina, titania, and yttria. In some embodiments of any one of the methods disclosed herein, the granulated particle comprises amorphous carbon, lamp black, or pyrolytic graphite.

In some embodiments of any one of the methods disclosed herein, the plurality of individual particles comprises one or more water-atomized individual particles.

In some embodiments of any one of the methods disclosed herein, the mixture is provided adjacent to a window, and the stimulus is directed through the window and towards the mixture.

In some embodiments of any one of the methods disclosed herein, the mixture comprises an initiator that initiates formation of the polymeric material from the at least the subset of the plurality of polymer precursors upon exposure to the stimulus. In some embodiments, the initiator is a photoinitiator. In some embodiments, the stimulus is electromagnetic radiation.

In some embodiments of any one of the methods disclosed herein, the method further comprises exposing the mixture to an additional stimulus to prevent formation of the polymeric material from at least an additional subset of the plurality of polymer precursors. In some embodiments, the mixture is provided adjacent to a window, and the additional stimulus is directed through the window and towards the mixture. In some embodiments of any one of the methods disclosed herein, the mixture comprises an inhibitor that inhibits formation of the polymeric material from the at least the additional subset of the plurality of polymer precursors upon exposure to the additional stimulus. In some embodiments, the inhibitor is a photoinhibitor. In some embodiments, the additional stimulus is electromagnetic radiation.

In some embodiments of any one of the methods disclosed herein, the method further comprises subjecting at least the polymeric precursor to heating, to thereby heat at least the granulated particle. In some embodiments, the heating is under conditions sufficient to sinter the granulated particle.

Another aspect of the present disclosure provides a mixture for printing a three-dimensional (3D) object, comprising: a plurality of polymer precursors; and a plurality of particles comprising granulated particles and non-granulated particles.

In some embodiments, the granulated particles and the non-granulated particles comprise a same material, and the plurality of particles comprises the non-granulated particles at an amount of greater than 10% by weight of the plurality of particles.

In some embodiments, the granulated particles and non-granulated particles comprise different materials, and the plurality of particles comprises the non-granulated particles at an amount of at most 10% by weight of the plurality of particles.

In some embodiments of any one of the mixtures disclosed herein, the plurality of particles comprises the granulated particles at an amount of at least 1% by weight of the plurality of particles. In some embodiments of any one of the mixtures disclosed herein, the plurality of particles comprises the granulated particles at an amount of at most 50% by weight of the plurality of particles. In some embodiments of any one of the mixtures disclosed herein, the plurality of particles comprises the granulated particles at an amount ranging from about 2% to about 5% by weight of the plurality of particles.

In some embodiments of any one of the mixtures disclosed herein, an individual granulated particle of the granulated particles comprises a binder.

In some embodiments of any one of the mixtures disclosed herein, (i) the granulated particles or (ii) the non-granulated particles comprise metal or ceramic. In some embodiments, the metal is selected from the group consisting of stainless steel, copper, titanium, cobalt, chromium, tungsten, gold, silver, platinum, palladium, rhodium, and alloys thereof. In some embodiments, the ceramic is selected from the group consisting of aluminum nitride, silicon carbide, silicon nitride, tungsten carbide cobalt, tungsten carbide copper, silica, alumina, titania, and yttria. In some embodiments of any one of the mixtures disclosed herein, (i) the granulated particles or (ii) the non-granulated particles comprise amorphous carbon, lamp black, or pyrolytic graphite.

In some embodiments of any one of the mixtures disclosed herein, an individual particle of (i) the granulated particles or (ii) the non-granulated particles is water-atomized.

In some embodiments of any one of the mixtures disclosed herein, the mixture further comprises an initiator configured to initiate formation of a polymeric material from at least a subset of the plurality of polymer precursors upon exposure to a stimulus. In some embodiments, the initiator is a photoinitiator. In some embodiments, the stimulus is electromagnetic radiation.

In some embodiments of any one of the mixtures disclosed herein, the mixture further comprises an inhibitor configured to inhibit formation of a polymeric material from at least a subset of the plurality of polymer precursors upon exposure to a stimulus. In some embodiments, the inhibitor is a photoinhibitor. In some embodiments, the stimulus is electromagnetic radiation.

Another aspect of the present disclosure provides a green body for producing a sintered three-dimensional (3D) object, comprising: a plurality of particles comprising granulated particles and non-granulated particles; and a polymeric material at least partially encapsulating the plurality of particles.

In some embodiments, the granulated particles and the non-granulated particles comprise a same material, and the plurality of particles comprises the non-granulated particles at an amount of greater than 10% by weight of the plurality of particles.

In some embodiments of any one of the green bodies disclosed herein, the granulated particles and non-granulated particles comprise different materials, and the plurality of particles comprises the non-granulated particles at an amount of at most 10% by weight of the plurality of particles.

In some embodiments of any one of the green bodies disclosed herein, the plurality of particles comprises the granulated particles at an amount of at least 1% by weight of the plurality of particles. In some embodiments of any one of the green bodies disclosed herein, the plurality of particles comprises the granulated particles at an amount of at most 50% by weight of the plurality of particles. In some embodiments of any one of the green bodies disclosed herein, the plurality of particles comprises the granulated particles at an amount ranging from about 2% to about 5% by weight of the plurality of particles.

In some embodiments of any one of the green bodies disclosed herein, an individual granulated particle of the granulated particles comprises a binder.

In some embodiments of any one of the green bodies disclosed herein, (i) the granulated particles or (ii) the non-granulated particles comprise metal or ceramic. In some embodiments, the metal is selected from the group consisting of stainless steel, copper, titanium, cobalt, chromium, tungsten, gold, silver, platinum, palladium, rhodium, and alloys thereof. In some embodiments, the ceramic is selected from the group consisting of aluminum nitride, silicon carbide, silicon nitride, tungsten carbide cobalt, tungsten carbide copper, silica, alumina, titania, and yttria. In some embodiments of any one of the green bodies disclosed herein, (i) the granulated particles or (ii) the non-granulated particles comprise amorphous carbon, lamp black, or pyrolytic graphite.

In some embodiments of any one of the green bodies disclosed herein, an individual particle of (i) the granulated particles or (ii) the non-granulated particles is water-atomized.

Another aspect of the present disclosure provides a method for printing a three-dimensional (3D) object, comprising: (a) providing a mixture comprising (i) a plurality of polymer precursors and (ii) a plurality of particles comprising granulated particles and non-granulated particles; and (b) exposing the mixture to a stimulus to cause at least a subset of the plurality of polymer precursors to form a polymeric material that at least partially encapsulates the plurality of particles.

In some embodiments, the granulated particles and the non-granulated particles comprise a same material, and the plurality of particles comprises the non-granulated particles at an amount of greater than 10% by weight of the plurality of particles.

In some embodiments of any one of the methods disclosed herein, the granulated particles and non-granulated particles comprise different materials, and the plurality of particles comprises the non-granulated particles at an amount of at most 10% by weight of the plurality of particles.

In some embodiments of any one of the methods disclosed herein, the granulated particles are present in the mixture at a concentration of at least 1% of the plurality of particles. In some embodiments of any one of the methods disclosed herein, the granulated particles are present in the mixture eat a concentration of at most 50% of the plurality of particles. In some embodiments of any one of the methods disclosed herein, the granulated particles are present in the mixture at a concentration of about 2% to about 5% of the plurality of particles.

In some embodiments of any one of the methods disclosed herein, an individual granulated particle of the granulated particles comprises a binder.

In some embodiments of any one of the methods disclosed herein, (i) the granulated particles or (ii) the non-granulated particles comprise metal or ceramic. In some embodiments, the metal is selected from the group consisting of stainless steel, copper, titanium, cobalt, chromium, tungsten, gold, silver, platinum, palladium, rhodium, and alloys thereof. In some embodiments, the ceramic is selected from the group consisting of aluminum nitride, silicon carbide, silicon nitride, tungsten carbide cobalt, tungsten carbide copper, silica, alumina, titania, and yttria. In some embodiments of any one of the methods disclosed herein, (i) the granulated particles or (ii) the non-granulated particles comprise amorphous carbon, lamp black, or pyrolytic graphite.

In some embodiments of any one of the methods disclosed herein, an individual particle of (i) the granulated particles or (ii) the non-granulated particles is water-atomized.

In some embodiments of any one of the methods disclosed herein, the mixture is provided adjacent to a window, and the stimulus is directed through the window and towards the mixture.

In some embodiments of any one of the methods disclosed herein, the mixture comprises an initiator that initiates formation of the polymeric material from the at least the subset of the plurality of polymer precursors upon exposure to the stimulus. In some embodiments, the initiator is a photoinitiator. In some embodiments, the stimulus is electromagnetic radiation.

In some embodiments of any one of the methods disclosed herein, the method further comprises exposing the mixture to an additional stimulus to prevent formation of the polymeric material from at least an additional subset of the plurality of polymer precursors. In some embodiments, the mixture is provided adjacent to a window, and the additional stimulus is directed through the window and towards the mixture. In some embodiments of any one of the methods disclosed herein, the mixture comprises an inhibitor that inhibits formation of the polymeric material from the at least the additional subset of the plurality of polymer precursors upon exposure to the additional stimulus. In some embodiments, the inhibitor is a photoinhibitor. In some embodiments, the additional stimulus is electromagnetic radiation.

In some embodiments of any one of the methods disclosed herein, the method further comprises subjecting at least the polymeric precursor to heating, to thereby heat at least the granulated particle. In some embodiments, the heating is under conditions sufficient to sinter the granulated particle.

In some aspects, the present disclosure describes using a mixture comprising a plurality of precursor compounds configured to form a plurality of particles (e.g., a plurality of nanoparticles).

An aspect of the present disclosure provides a mixture for printing a three-dimensional (3D) object, comprising: a plurality of polymeric precursors configured to form a polymeric material; at least one photoinitiator configured to initiate formation of the polymeric material from the plurality of polymeric precursors; and a first plurality of precursor compounds configured to react to form a first plurality of particles.

In some embodiments, a precursor of the plurality of precursor compounds comprises an inorganic material coupled to an organic material, wherein a plurality of the inorganic material is configured to form the first plurality of particles.

In some embodiments of any one of the subject mixtures, the plurality of precursor compounds is configured to decompose to form the first plurality of particles. In some embodiments of any one of the subject mixtures, (i) at least a portion of the polymeric material is configured to decompose at a first temperature and (ii) the plurality of precursor compounds is configured to decompose at a second temperature. In some embodiments, the first temperature and the second temperature are substantially the same. In some embodiments, the first temperature and the second temperature are different.

In some embodiments of any one of the subject mixtures, the first plurality of particles comprises a plurality of nanoparticles, and a nanoparticle of the plurality of nanoparticles has a size less than about 500 nanometers (nm). In some embodiments of any one of the subject mixtures, the first plurality of particles comprises a plurality of nanoparticles, and a nanoparticle of the plurality of nanoparticles has a size between about 1 nm and about 200 nm.

In some embodiments of any one of the subject mixtures, the mixture further comprises a second plurality of particles, wherein (i) a size of a particle of the second plurality of particles is greater than (ii) a size of a particle of the first plurality of particles. In some embodiments, the size of the particle of the second plurality of particles is greater than about 500 nm. In some embodiments, the size of the particle of the second plurality of particles is between about 1 micrometer (μm) and about 100 μm. In some embodiments, an inorganic material of the particle of the second plurality of particles and an inorganic material of the particle of the first plurality of particles are the same. In some embodiments, an inorganic material of the particle of the second plurality of particles and an inorganic material of the particle of the first plurality of particles are different.

In some embodiments of any one of the subject mixtures, the first plurality of particles comprises one or more members selected from the group comprising at least one metal particle, at least one ceramic particle, and at least one cermet particle. In some embodiments of any one of the subject mixtures, the first plurality of particles comprises at least one copper particle (e.g., copper nanoparticle), and the plurality of precursor compounds comprises one or more members selected from the group comprising copper (ii) acetate, copper (ii) d-gluconate, copper (ii) tartrate hydrate, monobutyl phthalate copper (ii), copper (ii) tert-butylacetoacetate, copper (ii) 3,5-diisopropylsalicylate hydrate, copper (ii) cyclohexanebutyrate, benzoic acid, and copper (ii) salt dehydrate. In some embodiments of any one of the subject mixtures, the first plurality of particles comprises at least one alumina particle (e.g., alumina nanoparticle), and the plurality of precursor compounds comprises one or more members selected from the group comprising aluminum diacetate hydroxide, aluminum sulfate, and aluminum potassium sulfate. In some embodiments of any one of the subject mixtures, the first plurality of particles comprises at least one silica particle (e.g., silica nanoparticle), and the plurality of precursor compounds comprises tetramethylsilane or hexamethylcyclotrisiloxane.

In some embodiments of any one of the subject mixtures, the mixture further comprises an inert filler. In some embodiments, at least a portion of the polymeric material is configured to decompose at a first temperature, and at least a portion of the inert filler is configured to (i) decompose at a lower temperature than the first temperature or (ii) dissolve in a solvent at a lower temperature than the first temperature. In some embodiments, the inert filler comprises a wax.

In some embodiments of any one of the subject mixtures, the mixture further comprises at least one photoinhibitor configured to inhibit the formation of the polymeric material from the plurality of polymeric precursors.

Another aspect of the present disclosure provides a green body for generating a three-dimensional (3D) object, comprising: a polymeric material; at least one photoinitiator; and a plurality of precursor compounds configured to react to form a first plurality of particles.

In some embodiments, a precursor of the plurality of precursor compounds comprises an inorganic material coupled to an organic material, wherein a plurality of the inorganic material is configured to form the first plurality of particles.

In some embodiments of any one of the subject green bodies, the plurality of precursor compounds is configured to decompose to form the first plurality of particles. In some embodiments of any one of the subject green bodies, (i) at least a portion of the polymeric material is configured to decompose at a first temperature and (ii) the plurality of precursor compounds is configured to decompose at a second temperature. In some embodiments, the first temperature and the second temperature are substantially the same. In some embodiments, the first temperature and the second temperature are different.

In some embodiments of any one of the subject green bodies, the first plurality of particles comprises a plurality of nanoparticles, and a nanoparticle of the plurality of nanoparticles has a size less than about 500 nanometers (nm). In some embodiments of any one of the subject green bodies, the first plurality of particles comprises a plurality of nanoparticles, and a nanoparticle of the plurality of nanoparticles has a size between about 1 nm and about 200 nm.

In some embodiments of any one of the subject green bodies, the green body further comprises a second plurality of particles, wherein (i) a size of a particle of the second plurality of particles is greater than (ii) a size of a particle of the first plurality of nanoparticles. In some embodiments, the size of the particle of the second plurality of particles is greater than about 500 nm. In some embodiments, the size of the particle of the second plurality of particles is between about 1 micrometer (μm) and about 100 μm. In some embodiments, an inorganic material of the particle of the second plurality of particles and an inorganic material of the particle of the first plurality of particles are the same. In some embodiments, an inorganic material of the particle of the second plurality of particles and an inorganic material of the particle of the first plurality of particles are different.

In some embodiments of any one of the subject green bodies, the first plurality of particles comprises one or more members selected from the group comprising at least one metal particle, at least one ceramic particle, and at least one cermet particle. In some embodiments of any one of the subject green bodies, the first plurality of particles comprises at least one copper particle, and the plurality of precursor compounds comprises one or more members selected from the group comprising copper (ii) acetate, copper (ii) d-gluconate, copper (ii) tartrate hydrate, monobutyl phthalate copper (ii), copper (ii) tert-butylacetoacetate, copper (ii) 3,5-diisopropylsalicylate hydrate, copper (ii) cyclohexanebutyrate, benzoic acid, and copper (ii) salt dehydrate. In some embodiments of any one of the subject green bodies, the first plurality of particles comprises at least one alumina particle, and the plurality of precursor compounds comprises one or more members selected from the group comprising aluminum diacetate hydroxide, aluminum sulfate, and aluminum potassium sulfate. In some embodiments of any one of the subject green bodies, the first plurality of particles comprises at least one silica particle, and the plurality of precursor compounds comprises tetramethylsilane or hexamethylcyclotrisiloxane.

In some embodiments of any one of the subject green bodies, the green body further comprises an inert filler. In some embodiments, at least a portion of the polymeric material is configured to decompose at a first temperature, and at least a portion of the inert filler is configured to (i) decompose at a lower temperature than the first temperature or (ii) dissolve in a solvent at a lower temperature than the first temperature. In some embodiments, the inert filler comprises a wax.

In some embodiments of any one of the subject green bodies, the green body further comprises at least one photoinhibitor configured to inhibit the formation of the polymeric material from the plurality of polymeric precursors.

In some embodiments of any one of the subject green bodies, the plurality of precursor compounds are encapsulated by the polymeric material.

In another aspect, the present disclosure provides a method for printing a three-dimensional (3D) object, comprising: (a) providing, adjacent to a build surface, a mixture comprising (i) a plurality of polymeric precursors configured to form a polymeric material, (ii) at least one photoinitiator configured to initiate formation of the polymeric material from the plurality of polymeric precursors, and (iii) a plurality of precursor compounds configured to react to form a first plurality of particles; and (b) exposing the mixture to a light under conditions sufficient to cause the at least one photoinitiator to initiate the formation of the polymeric material from the plurality of polymeric precursors, wherein the polymeric material encapsulates at least the plurality of precursor compounds, to print at least a portion of the 3D object.

In some embodiments of any one of the subject methods, the method further comprises, subsequent to (b), repeating (a) and (b) to print an additional portion of the 3D object adjacent to the at least the portion of the 3D object.

In some embodiments of any one of the subject methods, a precursor of the plurality of precursor compounds comprises an inorganic material coupled to an organic material, wherein a plurality of the inorganic material is configured to form the first plurality of particles.

In some embodiments of any one of the subject methods, the method further comprises, subsequent to (b), decomposing the plurality of precursors to form the first plurality of particles. In some embodiments of any one of the subject methods, the method further comprises (i) exposing the polymeric material to heat at a first temperature to decompose the at least the portion of the polymeric material and (ii) exposing the plurality of precursor compounds to heat at a second temperature to decompose the plurality of precursor compounds. In some embodiments, the first temperature and the second temperature are substantially the same. In some embodiments, the first temperature and the second temperature are different.

In some embodiments of any one of the subject methods, the first plurality of particles comprises a plurality of nanoparticles, and a nanoparticle of the plurality of nanoparticles has a size less than about 500 nanometers (nm). In some embodiments of any one of the subject methods, the first plurality of particles comprises a plurality of nanoparticles, and a nanoparticle of the plurality of nanoparticles has a size between about 1 nm and about 200 nm.

In some embodiments of any one of the subject methods, the mixture further comprises a second plurality of particles, wherein (i) a size of a particle of the second plurality of particles is greater than (ii) a size of a particle of the first plurality of particles. In some embodiments, the method further comprises (i) forming the first plurality of particles from the plurality of precursor compounds and (ii) subjecting the second plurality of particles and the first plurality of particles to heat at a third temperature, to coalesce the second plurality of particles and the first plurality of particles to heat and form a 3D structure. In some embodiments, the third temperature is between about 400 degrees Celsius (° C.) and about 3000° C. In some embodiments, the third temperature is between about 800 degrees Celsius (° C.) and about 2000° C. In some embodiments, the size of the particle of the second plurality of particles is greater than about 500 nm. In some embodiments, the size of the particle of the second plurality of particles is between about 1 micrometer (μm) and about 100 μm. In some embodiments, an inorganic material of the particle of the second plurality of particles and an inorganic material of the particle of the first plurality of particles are the same. In some embodiments, an inorganic material of the particle of the second plurality of particles and an inorganic material of the particle of the first plurality of particles are different.

In some embodiments of any one of the subject methods, the first plurality of particles comprises one or more members selected from the group comprising at least one metal particle, at least one ceramic particle, and at least one cermet particle. In some embodiments of any one of the subject methods, the first plurality of particles comprises at least one copper particle, and the plurality of precursor compounds comprises one or more members selected from the group comprising copper (ii) acetate, copper (ii) d-gluconate, copper (ii) tartrate hydrate, monobutyl phthalate copper (ii), copper (ii) tert-butylacetoacetate, copper (ii) 3,5-diisopropylsalicylate hydrate, copper (ii) cyclohexanebutyrate, benzoic acid, and copper (ii) salt dehydrate. In some embodiments of any one of the subject methods, the first plurality of particles comprises at least one alumina particle, and the plurality of precursor compounds comprises one or more members selected from the group comprising aluminum diacetate hydroxide, aluminum sulfate, and aluminum potassium sulfate. In some embodiments of any one of the subject methods, the first plurality of particles comprises at least one silica particle, and the plurality of precursor compounds comprises tetramethylsilane or hexamethylcyclotrisiloxane.

In some embodiments of any one of the subject methods, the mixture further comprises an inert filler. In some embodiments, at least a portion of the polymeric material is configured to decompose at a first temperature, and at least a portion of the inert filler is configured to (i) decompose at a lower temperature than the first temperature or (ii) dissolve in a solvent at a lower temperature than the first temperature. In some embodiments, the inert filler comprises a wax.

In some embodiments of any one of the subject methods, the method further comprises at least one photoinhibitor configured to inhibit the formation of the polymeric material from the plurality of polymeric precursors.

Yet in another aspect, the present disclosure provides a feedstock (e.g., a resin, a mixture, etc.) for three-dimensional (3D) printing, comprising: (i) a mixture comprising: a plurality of polymeric precursors configured to form a polymeric material, wherein the polymeric material is configured to decompose at a first temperature; a photoinitiator configured to initiate formation of the polymeric material from the plurality of polymeric precursors when exposed to photoradiation having a first wavelength; and particles comprising metal, ceramic, or cermet; and (ii) a soluble precursor compound configured to react at the second temperature and form nanoparticles comprising the metal, ceramic, or cermet.

In some embodiments, the feedstock further comprises an inert filler. In some embodiments, the inert filler is configured to decompose at a second temperature that is less than the first temperature or to be dissolvable in a solvent at a temperature below the first temperature. In some embodiments, the inert filler comprises a wax.

In some embodiments of any one of the subject feedstocks, the plurality of polymeric precursors comprises one or more acrylates. In some embodiments of any one of the subject feedstocks, the photoinitiator compound comprises camphorquinone or a functional variant thereof. In some embodiments of any one of the subject feedstocks, the feedstock further comprises a photoinhibitor configured to inhibit formation of the polymeric material from the plurality of polymeric precursors when exposed to photoradiation having a second wavelength. In some embodiments, the photoinhibitor comprises a hexaarylbiimidazole or a functional variant thereof.

In some embodiments of any one of the subject feedstocks, the particles comprise metal, and the particles have an average particle size (e.g., d₅₀) between 30 μm and 60 μm in size.

In some embodiments of any one of the subject feedstocks, the particles comprise metal. In some embodiments, the metal is copper, and the soluble precursor compound is selected from the group consisting of copper (ii) acetate, copper (ii) d-gluconate, copper (ii) tartrate hydrate, monobutyl phthalate copper (ii), copper (ii) tert-butylacetoacetate, copper (ii) 3,5-diisopropylsalicylate hydrate, copper (ii) cyclohexanebutyrat, benzoic acid, copper (ii) salt dehydrate, and combinations thereof.

In some embodiments of any one of the subject feedstocks, the particles comprise ceramic. In some embodiments, the ceramic is silica, and the soluble precursor compound is selected from the group consisting of tetramethylsilane and hexamethylcyclotrisiloxane.

In some embodiments of any one of the subject feedstocks, the particles comprise ceramic. In some embodiments, the ceramic is alumina, and the soluble precursor compound is selected from the group consisting of aluminum diacetate hydroxide, aluminum sulfate, and aluminum potassium sulfate.

In some embodiments of any one of the subject feedstocks, the nanoparticles comprising the metal have diameters between 10 nanometers (nm) and 100 nm.

In a different aspect, the present disclosure provides a green part for forming a three-dimensional object, comprising: a polymeric material configured to decompose at a first temperature; a photoinitiator; particles comprising a metal or ceramic; and a soluble metal compound configured to react at a second temperature that is greater than the first temperature to form nanoparticles comprising the metal or ceramic.

In a different aspect, the present disclosure provides a method for generating a three-dimensional (3D) object, comprising: (a) providing, adjacent to a build surface in a 3D printer, a feedstock comprising a plurality of polymeric precursors configured to form a polymeric material, particles comprising a metal or ceramic, and a soluble precursor compound configured to react to form nanoparticles comprising the metal or ceramic metal; (b) exposing the feedstock to photoradiation to form a green part corresponding to the 3D object, wherein the green part comprises the polymeric material, the photoinitiator, the particles, and the soluble precursor compound; and (c) heating the green part to cause the soluble precursor compound to react to form nanoparticles comprising the metal or ceramic, and to decompose at least a portion of the polymeric material, thereby forming a brown part corresponding to the 3D object, wherein the brown part comprises a portion of the polymeric material, the particles comprising the metal or ceramic, and nanoparticles comprising the metal or ceramic, wherein at least a portion of the nanoparticles decorate the particles; and (d) heating the 3D object at a sintering temperature to form a densified 3D metal object. In some embodiments, the sintering temperature is between 800° C. and 2000° C.

Another aspect of the present disclosure provides a non-transitory computer readable medium comprising machine executable code that, upon execution by one or more computer processors, implements any of the methods above or elsewhere herein.

Another aspect of the present disclosure provides a system comprising one or more computer processors and computer memory coupled thereto. The computer memory comprises machine executable code that, upon execution by the one or more computer processors, implements any of the methods above or elsewhere herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1A shows an example of a scanning electron microscopy (SEM) image of a plurality of metal particles that are not granulated;

FIG. 1B shows an example of a SEM image of granulated metal particles formed from smaller metal particles;

FIG. 2A shows a graph illustrating a change of cured layer thickness as a function of the photoinitiation light for a mixture (energy per unit area);

FIG. 2B shows a graph illustrating a penetration depth light as a function of inverse volume fraction of granulated particles in a mixture;

FIG. 2C shows a graph illustrating light scattering diameter of small metal particles as a function of mean particle diameter;

FIG. 2D shows a graph illustrating a change of cured layer thickness as a function of the photoinitiation light for a different mixture (energy per unit area);

FIG. 3 shows an example flowchart of a method for printing a 3D object;

FIG. 4 shows an example flowchart of another method for printing a 3D object

FIG. 5 schematically illustrates an example of a mixture for 3D printing; and

FIG. 6 shows a flowchart of an example method for printing a 3D object.

FIG. 7 shows an example of a 3D printing system;

FIG. 8 shows an example of another 3D printing system; and

FIG. 9 shows a computer system that is programmed or otherwise configured to implement methods provided herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “three-dimensional object” (also “3D object”), as used herein, generally refers to an object or a part of an object that is printed by three-dimensional (3D) printing. The 3D object may be at least a portion of a larger 3D object or an entirety of the 3D object. The 3D object may be fabricated (e.g., printed) in accordance with a computer model of the 3D object.

The term “mixture,” as used herein, generally refers to a material that is usable to print a 3D object. The mixture may be referred to as a feedstock, liquid, or resin (e.g., a photoactive resin). In some cases, the mixture may be held inside a vat. A layer of the mixture to be subjected to the light may be confined between a bottom of the vat (e.g., a window) and the build head. The bottom of the vat may be a build surface. Alternatively, a layer of the mixture to be subjected to the light may be confined between the build head and the surface of the mixture. The surface of the mixture may be a build surface. In some cases, the mixture may be deposited on or adjacent to an open platform. A layer of the mixture to be subjected to the light may be defined by pressing the mixture (e.g., by a blade or a build head) into a film of the mixture. The open platform may be a build surface. In the embodiments described herein, a thickness of the layer of the mixture may be adjustable. In some cases, the mixture may comprise one or more members from polymeric precursors, photoinitiators, photoinhibitors, co-initiators for curing, other light absorbers (e.g., ultravilenet (UV) light absorbers), radical inhibitors, organic and/or inorganic particulate materials, solvent, filters (e.g., inert fillers), etc.).

The mixture may include a photoactive resin. The photoactive resin may include a polymerizable and/or cross-linkable component (e.g., a polymeric precursor) and a photoinitiator that activates curing of the polymerizable and/or cross-linkable component, to thereby subject the polymerizable and/or cross-linkable component to polymerization and/or cross-linking. Such polymerization and/or cross-linking of the polymerizable and/or cross-linkable component, respectively, may form a polymeric material. The photoactive resin may include a photoinhibitor that inhibits curing of the polymerizable and/or cross-linkable component. The 3D printing may be performed with greater than or equal to about 1, 2, 3, 4, 5, 6, 7, 8, 9, 10 or more mixtures. As an alternative, the 3D printing may be performed with less than or equal to about 10, 9, 8, 7, 6, 5, 4, 3, 2 mixtures, or no mixture (e.g., a single component). A plurality of mixtures may be used for printing a multi-material 3D object.

The polymeric precursor in the mixture may comprise monomers to be polymerized into the polymeric material, oligomers to be cross-linked into the polymeric material, or both. The monomers may be of the same or different types. An oligomer may comprise two or more monomers that are covalently linked to each other. The oligomer may be of any length, such as at least 2 (dimer), 3 (trimer), 4 (tetramer), 5 (pentamer), 6 (hexamer), 7, 8, 9, 10, 20, 30, 40, 50, 100, 200, 300, 400, 500, or more monomers. Alternatively or in addition to, the polymeric precursor may include a dendritic precursor (monodisperse or polydisperse). The dendritic precursor may be a first generation (G1), second generation (G2), third generation (G3), fourth generation (G4), or higher with functional groups remaining on the surface of the dendritic precursor. The resulting polymeric material may comprise a monopolymer and/or a copolymer. The copolymer may be a linear copolymer or a branched copolymer. The copolymer may be an alternating copolymer, periodic copolymer, statistical copolymer, random copolymer, and/or block copolymer.

Examples of monomers include one or more of hydroxyethyl methacrylate; n-Lauryl acrylate; tetrahydrofurfuryl methacrylate; 2, 2, 2-trifluoroethyl methacrylate; isobornyl methacrylate; polypropylene glycol monomethacrylates, aliphatic urethane acrylate (i.e., Rahn Genomer 1122); hydroxyethyl acrylate; n-Lauryl methacrylate; tetrahydrofurfuryl acrylate; 2, 2, 2-trifluoroethyl acrylate; isobornyl acrylate; polypropylene glycol monoacrylates; trimethylpropane triacrylate; trimethylpropane trimethacrylate; pentaerythritol tetraacrylate; pentaerythritol tetraacrylate; triethyleneglycol diacrylate; triethylene glycol dimethacrylate; tetrathyleneglycol diacrylate; tetrathylene glycol dimethacrylate; neopentyldimethacrylate; neopentylacrylate; hexane dioldimethacylate; hexane diol diacrylate; polyethylene glycol 400 dimethacrylate; polyethylene glycol 400 diacrylate; diethylglycol diacrylate; diethylene glycol dimethacrylate; ethyleneglycol diacrylate; ethylene glycol dimethacrylate; ethoxylated bis phenol A dimethacrylate; ethoxylated bis phenol A diacrylate; bisphenol A glycidyl methacrylate; bisphenol A glycidyl acrylate; ditrimethylolpropane tetraacrylate; and ditrimethylolpropane tetraacrylate.

Polymeric precursors may be present in an amount ranging between about 3 weight % (wt %) to about 90 wt % in the mixture. The polymeric precursors may be present in an amount of at least about 3 wt %, 4 wt %, 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, 90 wt %, or more in the mixture. The polymeric precursors may be present in an amount of at most about 90 wt %, 85 wt %, 80 wt %, 75 wt %, 70 wt %, 65 wt %, 60 wt %, 55 wt %, 50 wt %, 45 wt %, 40 wt %, 35 wt %, 30 wt %, 25 wt %, 20 wt %, 15 wt %, 10 wt %, 5 wt %, 4 wt %, 3 wt %, or less in the mixture.

In some cases, the mixture may include a plurality of particles (e.g., metal, non-metal, or a combination thereof). The mixture may be a slurry or a paste. The plurality of particles may be solids or semi-solids (e.g., gels). The plurality of particles may be suspended throughout the mixture in a monodisperse distribution or a polydisperse distribution.

A resin may be a raw material usable for a digital light processing (DLP)-based 3D printing process or stereolithography (SLA)-based 3D printing process. In some cases, the resin may not comprise pre-polymerized and/or cross-linked polymers. Alternatively, the resin may comprise pre-polymerized and/or cross-linked polymers. In some cases, the resin may comprise other components such as photoinhibitors, UV absorbers, and inert fillers. The term “composite resin” may generally refer to a resin that comprises (i) metal, ceramic, or other suspended particles and/or (ii) a plurality of precursor compounds thereof, as provided herein.

The term “polymeric material” as used herein, generally refer to compositions based on polymers, oligomers, or monomers, which can be selectively polymerized and/or crosslinked upon exposure to a stimulus. In some cases, the stimulus may be electromagnetic radiation (light or actinic radiation), and the polymeric material may be referred to a photopolymer.

In some cases, the stimulus to form a polymeric material from a plurality of polymeric precursors may be one or more lights. One or more lights (e.g., from one or more light sources) may be used to initiate (activate) curing of a portion of the film, thereby to print at least a portion of the 3D object. In some cases, one or more lights (e.g., from one or more light sources) may be used to inhibit (prevent) curing of a portion of the film adjacent to a surface of the film (e.g., a surface adjacent to one or more sides of the vat or a surface of the open platform). In some cases, one or more lights (e.g., from one or more light sources) may be used by one or more sensors to determine a profile and/or quality of the film.

The 3D printing may be performed with one wavelength. The 3D printing may be performed with at least about 2, 3, 4, 5, 6, 7, 8, 9, 10 or more wavelengths that are different. The 3D printing may be performed with at least about 1, 2, 3, 4, 5, 6, 7, 8, 9, 10 or more lights. The 3D printing may be performed with at least about 1, 2, 3, 4, 5, 6, 7, 8, 9, 10 or more light sources, and it may be desirable to prevent curing of a portion of the film adjacent to the surface of the film.

The one or more lights may comprise electromagnetic radiation. The term “electromagnetic radiation,” as used herein, generally refers to one or more wavelengths from the electromagnetic spectrum including, but not limited to x-rays (about 0.1 nanometers (nm) to about 10.0 nm; or about 10¹⁸ Hertz (Hz) to about 10¹⁶ Hz), UV rays (about 10.0 nm to about 380 nm; or about 8×10¹⁶ Hz to about 10¹⁵ Hz), visible light (about 380 nm to about 750 nm; or about 8×10¹⁴ Hz to about 4×10¹⁴ Hz), infrared (IR) light (about 750 nm to about 0.1 centimeters (cm); or about 4×10¹⁴ Hz to about 5×10¹¹ Hz), and microwaves (about 0.1 cm to about 100 cm; or about 10⁸ Hz to about 5×10¹¹ Hz).

The one or more light sources may comprise an electromagnetic radiation source. The term “electromagnetic radiation source,” as used herein, generally refers to a source that emits electromagnetic radiation. The electromagnetic radiation source may emit one or more wavelengths from the electromagnetic spectrum.

In some cases, the mixture may include a plurality of particles (e.g., metal, non-metal, or a combination thereof). The mixture may be a slurry or a paste. The plurality of particles may be solids or semi-solids (e.g., gels). The plurality of particles may be suspended throughout the mixture in a monodisperse distribution or a polydisperse distribution.

The term “particles,” as used herein, generally refers to any particulate material that may be melted or sintered (e.g., not completely melted). The particulate material may be in powder form. The particles may be inorganic materials. The inorganic materials may be metallic (e.g., aluminum or titanium), intermetallic (e.g., steel alloys), ceramic (e.g., metal oxides) materials, or any combination thereof. In some cases, the term “metal” or “metallic” may refer to both metallic and intermetallic materials. The metallic materials may include ferromagnetic metals (e.g., iron and/or nickel). The particles may have various shapes and sizes. For example, a particle may be in the shape of a sphere, cuboid, or disc, or any partial shape or combination of shapes thereof. The particle may have a cross-section that is circular, triangular, square, rectangular, pentagonal, hexagonal, or any partial shape or combination of shapes thereof. Upon heating, the particles may sinter (or coalesce) into a solid or porous object that may be at least a portion of a larger 3D object or an entirety of the 3D object. The 3D printing may be performed with at least about 1, 2, 3, 4, 5, 6, 7, 8, 9, 10 or more types of particles. As an alternative, the 3D printing may be performed with less than or equal to about 10, 9, 8, 7, 6, 5, 4, 3, 2, or 1 particle, or no particles. A particle may be a nanoparticle. A particle may be a microparticle.

The metallic materials for the particles may include one or more of aluminum, calcium, magnesium, barium, scandium, titanium, vanadium, chromium, manganese, iron, cobalt, nickel, copper, zinc, yttrium, niobium, molybdenum, ruthenium, rhodium, silver, cadmium, actinium, and gold. The particles may comprise a rare earth element. The rare earth element may include one or more of scandium, yttrium, and elements of the lanthanide series having atomic numbers from 57-71.

The intermetallic materials for the particles may be a solid-state compound exhibiting metallic bonding, defined stoichiometry and ordered crystal structure (i.e., alloys). The intermetallic materials may be in pre-alloyed powder form. Examples of such pre-alloyed powders may include, but are not limited to, brass (copper and zinc), bronze (copper and tin), duralumin (aluminum, copper, manganese, and/or magnesium), gold alloys (gold and copper), rose-gold alloys (gold, copper, and zinc), nichrome (nickel and chromium), and stainless steel (iron, carbon, and additional elements including manganese, nickel, chromium, molybdenum, boron, titanium, silicon, vanadium, tungsten, cobalt, and/or niobium). The pre-alloyed powders may include superalloys. The superalloys may be based on elements including iron, nickel, cobalt, chromium, tungsten, molybdenum, tantalum, niobium, titanium, and/or aluminum.

The ceramic materials for the particles may comprise metal (e.g., aluminum, titanium, etc.), non-metal (e.g., oxygen, nitrogen, etc.), and/or metalloid (e.g., germanium, silicon, etc.) atoms primarily held in ionic and covalent bonds. Examples of the ceramic materials include, but are not limited to, an aluminide, boride, beryllia, carbide, chromium oxide, hydroxide, sulfide, nitride, mullite, kyanite, ferrite, titania zirconia, yttria, and magnesia.

The term “particle size,” as used herein, generally refers to a mean or median particle size of a population of particles. The particle size may be obtained from a direct measurement or an indirect measurement. The particle size may be measured by obtaining visualization (e.g., images, pictures, micrographs such as scanning electron microscopy (SEM) image, transmission electron microscopy (TEM) image, atomic force microscopy (AFM) image, etc.), and calculating the mean or median particle size of a population of particles shown in such visualization. The particle size may be measured by dynamic light scattering (DLS) measurements. In some cases, the particle size may be obtained by a model that transforms (e.g., in an abstract way) a real particle shape into a simple and standardized shape (e.g., a mathematical shape, such as a sphere). In some cases, a spherical shape may be used when a size parameter such as diameter makes sense. A population of particles may be monodisperse with substantially the same particle dimension (or size). In some cases, a population of particles may be polydisperse with different dimensions (or sizes), and the term “particle size distribution,” as used herein, may reflect such polydispersity. In some cases, a particle size of a collection of particles may generally refer to a d₅₀ of the particles, which is the diameter for which 50% of the particles have a smaller diameter and 50% percent have a larger diameter. The d₅₀ can also be referred to as the median diameter for the collection of particles.

The terms “granulated particle” or “agglomerated particle,” as used interchangeably herein, generally refers to an aggregation of a plurality of individual particles. A plurality of individual particles may be bound one another within a granulated particle. The plurality of individual particles may be coupled (e.g., fused) to one another. Such fusion of the plurality of individual particles may be a result of a stimulus, which stimulus may be electromagnetic radiation (e.g., laser) or thermal energy. Alternatively or in addition to, the plurality of individual particles may be indirectly bound to one another by one or more binders. In an example, one or more binders may encapsulate a plurality of individual particles to from a granulated particle.

The term “particle precursor,” “particle precursor compound,” “precursor compound,” or “soluble precursor compound, as used interchangeably herein, generally refers to a compound configured to from a particle (e.g., a nanoparticle, a microparticle, etc.) with one or more additional molecules. The one or more additional molecules may be another particle precursor of the same material or different materials. The one or more additional molecules may be a pre-formed particle (e.g., a nanoparticle, a microparticle, etc.). In some cases, a plurality of particle precursors may form a particle upon exposure to a stimulus (e.g., an electromagnetic radiation comprising one or more wavelengths). Such particle may be formed in the absence of a binder. Alternatively, the plurality of particle precursors may form the particle in the presence of a binder. A particle precursor may or may not be water-soluble. A particle precursor may be soluble in a mixture for 3D printing. Examples of a particle precursor may include, but are not limited to, a metal precursor compound (e.g., a soluble metal precursor compound), a ceramic precursor compound (e.g., a soluble ceramic precursor compound), or a cermet precursor compound (e.g., a soluble cermet precursor compound). Exposure of the particle precursor to the stimulus may be performed under inert, oxidative, or reductive conditions.

In some cases, a plurality of precursor compounds may be soluble in a 3D printing resin to form a homogeneous resin mixture. Alternatively, the plurality of precursor compounds may form a heterogeneous resin mixture. In some cases, one or more lights (e.g., photoinitiation light and/or photoinhibition light) may be used during 3D printing, and the plurality of precursor compounds in a resin may scatter the light(s) less than lager particles (e.g., nanoparticles, microparticles) in a resin. In an example, a plurality of organometallic compounds in a resin may scatter the light(s) less than larger particles formed of the same metal in a resin. Scattering of the light(s) by the plurality of precursor compounds in a resin may be less than scattering of the light(s) by the lager particles in a resin by at least about 1%, about 2%, about 3%, 4%, about 5%, about 10%, about 15%, about 20%, about 25%, about 30%, about 35%, about 40%, about 45%, about 50%, about 55%, about 60%, about 65%, about 70%, about 75%, about 80%, about 85%, about 90%, about 95%, about 99%, or more. In some cases, the plurality of precursor compounds may not scatter the light(s).

The term “photoinitiation,” as used herein, generally refers to a process of subjecting a portion of a mixture to a light to cure (or gel) a photoactive resin in the portion of the mixture. The light (photoinitiation light) may have a wavelength that activates a photoinitiator that initiates curing of a polymerizable and/or cross-linkable component in the photoactive resin.

The term “photoinhibition,” as used herein, generally refers to a process of subjecting a portion of a mixture to a light to inhibit curing of a photoactive resin in the portion of the mixture. The light (photoinhibition light) may have a wavelength that activates a photoinhibitor that inhibit curing of a polymerizable and/or cross-linkable component in the photoactive resin. The wavelength of the photoinhibition light and another wavelength of a photoinitiation light may be different wavelengths. In some examples, the photoinhibition light and the photoinitiation light may be projected from the same optical source. In some examples, the photoinhibition light and the photoinitiation light may be projected from different optical sources.

The terms “photoinitiation light” and “first light” may be used synonymously herein. The terms “photoinhibition light” and “second light” may be used synonymously herein.

The terms “energy,” as used herein, generally refers to an electromagnetic (e.g., ultraviolet ray or visible light) exposure per unit area (e.g., millijoule per square centimeter; mJ/cm²). The term “intensity,” as used herein, generally refers to the energy (as described above) per time (e.g., milliwatt per square centimeter; mW/cm²).

The term “vat,” as used herein, generally refers to a structure (e.g., a container, holder, reservoir, etc.) that holds a mixture during 3D printing. The mixture may be usable for 3D printing. One or more sides of the vat (e.g., a bottom or side surface) may include an optically transparent or semi-transparent window (e.g., glass or a polymer) to direct light through the window and to the mixture. In some cases, the window may be precluded. In such a scenario, light may be provided to the mixture from above the vat, and it may be desirable to prevent curing of a portion of the mixture adjacent to the surface of the mixture.

The term “open platform,” as used herein, generally refers to a structure that supports a mixture or a film of the mixture during 3D printing. The mixture may have a viscosity that is sufficient to permit the mixture to remain on or adjacent to the open platform during 3D printing. The open platform may be flat. The open platform may include an optically transparent or semi-transparent print window (e.g., glass or a polymer) to direct light through the window and to the mixture or the film of the mixture. In some cases, the window may be precluded. In such a scenario, light may be provided to the mixture of the film of the mixture from above the open platform, such as directly above or from a side of the open platform.

The term “window,” as used herein, generally refers to a structure that is part of a vat or a container. In some cases, the window may be in contact with the mixture. In some cases, the window may not be in contact with the mixture. The window may be transparent or semitransparent (translucent). The window may be comprised of an optical window material, such as, for example, glass or a polymeric material (e.g., polymethylmethacrylate (PMMA)). In some cases, the window may be comprised of polydimethylsiloxane (PDMS) or other polymeric materials that are permeable to oxygen. During printing, the oxygen dissolved in the window may (i) diffuse into a contact surface between the window and the mixture comprising the photoactive resin (the window-mixture interface) and (ii) inhibit curing of the photoactive resin at the contact surface. The window may be positioned above an optical source for photopolymer-based 3D printing using bottom-up illumination. As an alternative, the window may be positioned below the optical source. As another alternative, the window may be positioned between a first optical source and a second optical source.

The term “build head,” as used herein, generally refers to a structure that supports and/or holds at least a portion (e.g., a layer) of a 3D object. The build head may be configured to move along a direction away from a bottom of a vat or an open platform. Such movement may be relative movement, and thus the moving piece may be (i) the build head, (ii) the vat or the open platform, or (iii) both. The moving piece may comprise a mechanical gantry capable of motion in one or more axes of control (e.g., one or more of the XYZ planes) via one or more actuators during 3D printing.

The term “green body,” as used herein, generally refers to a 3D object that includes a polymeric material matrix in which a plurality of particles (e.g., metal, ceramic, cermet, inorganic carbon, or a combination thereof) is encapsulated. The particles may be configured for sintering or melting. The green body may be self-supporting. The green body may be heated in a heater (e.g., a furnace) to burn off at least a portion of the polymeric material. Some of the metal, ceramic, and/or cermet particles may begin to coalesce during this process.

The term “brown body,” as used herein, generally refers to a green body that has undergone partial debinding, that is, has been treated, such as by solvent treatment, heat treatment, or pressure treatment, to remove at least a portion (e.g., 20% to 95%) of the polymeric material within the green body. The brown body retains the metal, ceramic, and/or cermet particles of the green body and still held together with a certain amount of organic binder from the original binder formulation. The particles may be configured for sintering or melting. The brown body may be self-supporting. The brown body may be heated in a heater (e.g., a furnace) to burn off at least a portion of any remaining polymeric material and to coalesce and densify the metal, ceramic, and/or cermet particles into a finished 3D object.

All ranges disclosed herein are meant to include all ranges subsumed therein unless specifically stated otherwise. As used herein, “any range subsumed therein” means any range that is within the stated range.

Overview

Photopolymer-based 3D printers that use bottom-up illumination project a light upwards through an optically transparent window and towards a resin that contains a plurality of polymeric precursors. As the light passes through at least a portion of the resin, the light is attenuated by absorption by one or more components of the resin (e.g., polymeric precursors, particles, etc.). Thus, the resin may be exposed to the greatest photoradiation intensity of the light at the resin-window interface. For example, an intensity of the projected light may be greater at the resin-window interface as compared to other portions of the mixture away from the resin-window interface. In some cases, a solidification rate of the resin (e.g., polymerization rate of the plurality of polymeric precursors) may be proportional to photon flux of the irradiated light (e.g., proportional to the square root of the photon flux). Thus, the resin may be exposed to the greatest solidification rate at the resin/window interface.

A resin for 3D printing may comprise a plurality of metal or ceramic particles (e.g., suspended within the resin) and a plurality of polymeric precursors configured to form a polymeric material comprising the plurality of metal or ceramic particles. When the resin is illuminated with photoradiation (e.g., photoinitiation light) to form the polymeric material, the photoradiation may be scattered by the plurality of metal and ceramic particles within the resin. In some cases, the plurality of may have high refractive indices and scatter the projected light, which may result in shallow curing depths of the plurality of polymeric precursors to form the polymeric material. In some cases, when the volume fraction of the plurality of metal or ceramic particles exceeds a threshold (e.g., about 35% by weight of the resin), a penetration depth of the photoradiation (e.g., limited by light attenuation) may be on the order of a dimension (e.g., an average diameter) of the plurality of metal or ceramic particles.

Printed 3D structures comprising the polymeric material and the plurality of particles may be metallic or ceramic green bodies usable to generate final 3D structures. The metallic or ceramic green bodies may be thermally treated (e.g., sintered in an oven), during which the plurality of metal or ceramic particles may be joined together to become a monolithic, finished part. The thermal treatment may reduce or eliminate porosity in the metallic or ceramic green bodies.

In some cases, large particles may be difficult to sinter due to, for example, a small surface-to-volume ratio of such particles, and insufficient sintering process may result in a final 3D object with poor mechanical properties. Thus, in some cases, using particles of small dimensions may be desirable for 3D printing.

Thus, in certain aspects, recognized herein is an unmet need for alternative systems and methods for particle-based 3D printing and sintering. The present disclosure provides systems and methods of 3D printing, in which a plurality of particles in a mixture (e.g., a photoreactive mixture) may behave as (i) large particles to yield sufficiently thick curing depths and (ii) small particles for improved sintering. The present disclosure further provides configurations and methods of 3D printing using two lights with different wavelengths to achieve photoinitiation and photoinhibition.

In some cases, when the plurality of metal or ceramic particles in the green bodies have an average diameter between about 500 nanometers (nm) and about 10 micrometers (μm), sintering may form a finished part that have a metal or ceramic density of about 90% or more (e.g., 98% or more). On the other hand, if the plurality of metal or ceramic particles have an average diameter between about 15 μm and about 45 μm, sintering may form a finished part that have a metal or ceramic density of about 80% or less (e.g., 75% or less), under the same sintering conditions.

Small metal or ceramic particles (e.g., nanoparticles) may be usable for sintering and generating high density 3D objects. On the other hand, small particles may reduce light penetration into the resin and printed layer depth/thickness. For example, a resin comprising finer powders (e.g., 500 nm to 10 μm in size) may yield thin printed layers because of the aforementioned relationship between particle size and light penetration depth. As such, layer with limited thickness may increase the total number of layers needed to print a 3D object as compared to layers with higher thickness, thus requiring more time to print the 3D object. In some cases, it may difficult to print a 3D object with such thin layers. For example, adhesion between a thin, newly-printed layer to a previously deposited layer may be difficult to achieve. In addition, having to print more layers may increase the chance of errors during the 3D printing process.

Thus, in certain aspects, recognized herein is a tradeoff. For 3D printing with a resin comprising particles, large particles may be desirable to reach high penetration depth (thus, thicker printed layers), but large particles may not sinter to desirable high densities. On the other hand, small particles may sinter to high densities, but the layer thickness for printing (e.g., polymerization and/or crosslinking via radiation) may be too thin for printing in a reasonable time or, in some cases, at all.

Overall, there is an unmet need to make a resin that comprises metal or ceramic particles or adjust processing conditions thereof to achieve both adequately thick printed layers and high-density sintering.

Compositions for 3D Printing and Methods Thereof.

The present disclosure describes technologies relating to 3D printing. A mixture or feedstock used for such 3D printing may comprise a plurality of particles (e.g., a plurality of suspended particles in the mixture). The particles may impart specific desired material properties, e.g., toughness, conductivity, heat capacity, or visual properties such as reflectivity or surface sheen. Examples of such particles include, but are not limited to, metal particles, ceramic particles, carbon black, graphite, carbon fibers, colored particles, or even particles made of a polymer type that is not easily polymerized by light exposure. In some cases, suspended particles may be useful for their role in the asprinted “green” state, but they may also be useful the properties they contribute after a part undergoes further processing, such as sintering. For example, metal or ceramic particles may be suspended in a mixture, and after removal of the polymeric material encapsulating the particles and subsequent sintering, the particles may be densified into metal or ceramic 3D objects.

During a 3D printing process, (e.g., DLP-based or SLA-based 3D printing process), photoradiation may penetrate into a feedstock to cure or print a layer and bond it to a previously printed layer. Jacobs (P. F. Jacobs, Rapid Prototyping and Manufacturing: Fundamentals of Stereolithography, Soc. of Mechanical Engineers, 1992) derived an expression for the curing depth (1) based on the Beer-Lambert law and is given as

$$l = {d}_{p} ln ( \frac{E}{{E}_{c}} ) \qquad ( 1 )$$

where E is the amount of energy transmitted at the incident surface, E_{c} is the amount of energy required to cure the polymer, and dₚ is the penetration depth that is related to the attenuation of light in the material. Generally, the curing depth may range between about 0.2 to about 5.0 times the penetration depth. In some 3D printing applications, a light attenuating species may be added to achieve adequate resolution and prevent undesirable curing in previously cured layers.

Conversely, metal particles, ceramic particles, cermet particles, or other highly scattering components may be added to a feedstock to form a composite feedstock, and it may be challenging to obtain a cured layer that is sufficiently thick. Griffith and Halloran (Griffith, M. L. & Halloran, J. W., “Scattering of ultraviolet radiation in turbid suspensions,” J. Appl. Phys. 81, 2538-2546 (1997)) showed that for mixtures of plurality of polymeric precursors and ceramic particles, the penetration depth can be expressed as:

$${d}_{p} = \frac{2 〈 d 〉}{3 Q ϕ} \qquad ( 2 )$$

where Φ is the volume fraction of the ceramic particles, Q is the scattering efficiency of the composite feedstock, and <d> is the size of the ceramic particles estimated as the harmonic mean of the particle size distribution, where smaller particles are more highly weighted and have a larger influence than larger particles.

The refractive indices (n) for the plurality of polymeric precursors and the plurality of particles (e.g., a plurality of micron-scale particles in suspension, such as metal, ceramic, or cermet particles) may be different. For composite feedstocks comprising the plurality of polymeric precursors and the plurality of particles, Mie scattering may dominate, and the scattering efficiency Q may be approximately 2. This means that the penetration depth, as expressed in equation (2) may depend strongly on volume fraction and particle size. For high volume fractions, the penetration depth approaches (and can go below) the harmonic mean of the particle size distribution (<d>). Thus, the (harmonic) mean particle size may be the upper limit on the penetration depth that can be expected in 3D printing with highly loaded feedstocks, (e.g., feedstocks with suspended particles at a concentration of at least about 35 volume %).

In some 3D printing techniques (e.g., DLP or SLA printing), a desired layer thickness may be between about 1 micrometer (μm) and about 500 μm. In some cases, the desired layer thickness may be between about 10 μm and about 200 μm, about 10 μm and about 100 μm, or about 50 μm and 100 μm. Thinner layers (e.g., at most about 10 μm, 9 μm, 8 μm, 7 μm, 6 μm, 5 μm, 4 μm, 3 μm, 2 μm, 1 μm, or less) may increase an amount of time required to process a part (e.g., print at least a portion of a 3D object), as more layers may be needed to make the part as compared to using thicker layers. Thus, to achieve a desired layer thicknesses, a preferred (or harmonic) mean particle size of the plurality of particles in the feedstock may be at least about 10 μm or more (e.g., at least about 10 μm, 20 μm, 30 μm, 40 μm, 50 μm, 60 μm, 70 μm, 80 μm, 90 μm, 100 μm, or more).

On the other hand, a green body that contains a plurality of particles (e.g., metal or ceramic particles) may b subjected to heating (e.g., sintered) to densify into a finished part. Large particles may be difficult to sinter due to their small surface-to-volume ratio. Thus, it may be desirable for the size of the plurality of particles in the green body to be less than about 10 μm (e.g., less than about 10 μm, 9 μm, 8 μm, 7 μm, 6 μm, 5 μm, 4 μm, 3 μm, 2 μm, 1 μm, or less) in order to form sintered parts that have high density and sufficient mechanical properties. This is the opposite of what may be desired for the 3D printing process itself, where small particle sizes may yield undesirable, thin printed layers.

For some composite mixtures, refractive indices (n) of the suspended particles and the plurality of polymeric precursors may be well matched. An example of such a composite mixture may comprise a plurality of silica suspended particles (n=about 1.56) and an acrylamide (n=about 1.53) as the photopolymer. Such composite mixtures may experience less scattering of the illuminated light. Thus, the penetration depth of the light may be less effected by (e.g., not limited by) the average size of the suspended particles, and the composite mixtures may be cured in layers having a thickness greater than that expected from the average size of the suspended particles, as aforementioned. However, for other particle materials, such as silicon nitride, silicon carbide, aluminum nitride, copper, and stainless steel, there may be a mismatch between the refractive indices of the particles and the plurality of polymeric precursors. Mixtures comprising such particles may be difficult to use for in certain 3D printing applications since the penetration depth of illuminated light (e.g., photoinitiation light) may be greatly affected by (e.g., limited by) the average size of the suspended particles.

The present disclosure provides compositions and methods to mitigate the scattering of illuminated light by suspended particles (e.g., metal, ceramic, and/or cermet particles) in a mixture to form 3D objects (e.g., brown bodies).

A. Granulated Particles

In some aspects, the present disclosure describes mixtures comprising textured or granulated particles (e.g., in suspension within the mixture) for 3D printing. A mixture may comprise textured or granulated particles (e.g., gas-atomized particles) such that (i) the largest particles (e.g., the particles that may define the minimum printable layer thickness) and (ii) the smallest particles (e.g., the particles that may limit the penetration depth of the illuminated light) may be of a similar size range. In other words, a population of textured or granulated particles may exhibit a narrow particle size distribution. In some cases, a metric to quantify the particle size distribution is the span, S,

$$S = \frac{{d}_{90} - {d}_{10}}{{d}_{50}} \qquad ( 3 )$$

in which dₓ is the diameter for which X percent of the particles has a smaller diameter than the value X and (100-X) percent of the particles has a larger diameter than the value X. Composite mixtures that contain such particles at concentrations of about 35-45 vol % have been 3D printed successfully at thicknesses roughly twice the size of the d₅₀. It is important to note that the largest particles limit the minimum thickness of a layer to be cured, as a layer formed from a composite mixture cannot be thinner than the largest particles. On the other hand, as seen in equation (2), the limit for the maximum thickness of the layer that is cured can be determined by the smallest particle sizes because of their outsized effect on the light penetration. Narrow size distributions can help to narrow the difference between these limits

In some cases, small particles can be aggregated using a stimulus (e.g., electromagnetic radiation, heat, shearing, etc.) or an aggregating binder to form a granulated particle comprising a plurality of the small particles in aggregation. From a light-scattering perspective, such granulated particles may function as large particles. From a sintering perspective, the plurality of small particles that make up the granulated particles may function as small particles. The plurality of small particles may have a high surface-to-volume ratio and can be sintered easily after the aggregating binder is removed. In an example, a granulated particle comprising an aggregation of a plurality of smaller particles may have a high surface-to-ratio as compared to a non-granulated particle of a similar size or volume, and the granulated particle may be sintered more easily (e.g., after at least a portion of the aggregating binder is removed, if any) than the non-granulated particle of the similar size or volume.

The granulated particles can be made using various processes. Spray drying may yield granulated particles that are spherical and nearly mono-disperse, which may allow the granulated particles to flow easily in composite mixtures.

Suspended granulated particles may be used in 3D printing mixtures. An aggregating binder may be used to aggregate small particles into larger granulated particles. In some cases, the diameters of the small particles may be between 100 nanometer (nm) and 20 μm. In some cases, the diameters of the granulated particles may be between 10 μm and 500 μm. Examples of materials that can be used in such granulated particles may include, but are not limited to, metals and alloys such as of stainless steel, copper, titanium, cobalt, chromium, tungsten, gold, silver, platinum, palladium, rhodium, and alloys thereof; carbides such as silicon carbide, tungsten carbide cobalt, and tungsten carbide copper; nitrides such as silicon nitride and aluminum nitride; oxide ceramics such as titania, alumina, silica, and yttria; and glasses.

Non-spherical and irregularly-shaped particles, which particles do not flow well and thus do not work well as suspended particles in 3D printing mixtures, can be agglomerated into granulated particles that have more spherical morphologies than do the individual particles that make up the granulated particles. Such granulated particles may have improved flow characteristics and may be more suitable for 3D printing mixtures of the present disclosure.

Small particles that are too small for 3D printing (e.g., particles having an average diameter of less than 10 μm) can be agglomerated into granulated particles that have a larger particle size (e.g., a larger particle diameter). Such granulated particles may have sizes that are more suitable for 3D printing mixtures than are the individual particles that make up the granulated particles.

Examples of materials whose conventional particles (e.g., non-granulated) (i) may be too irregular or too small (e.g., particles having an average diameter of less than 10 μm) for 3D printing and (ii) may be aggregated to form one or more granulated particles include, but are not limited to, metal carbides and other cermet materials such as Tungsten Carbide-Cobalt (WC—Co) and Tungsten Carbide-Copper (WC—Cu).

The granulated particles of the present disclosure may be made from smaller particles or powders (e.g., water-atomized powders, gas-atomized powders, etc.). In some cases, water-atomized powders may be considerably cheaper than gas-atomized powders. In some cases, the water-atomized particles may flow poorly (e.g., exhibiting a lower volumetric flow rate) when compared to the gas-atomized powders. In some cases, the water-atomized particles may exhibit lower sphericity than the gas-atomized powders, and thus, may be difficult to incorporate (e.g., suspend homogeneously) into 3D printing mixtures. In some cases, use of smaller water atomized particles to produce a plurality of granulated particles may overcome the abovementioned shortcomings of particle flow and overall cost of the production.

The granulated particles of the present disclosure may comprise carbon materials including, but are not limited to, graphite, amorphous carbon, lamp black, pyrolytic graphite, carbon nanotube, graphene, fullerene, etc. Even though parts made from such materials may be useful for a range of technology applications (e.g., heat exchangers for thermal management), 3D printing with one or more carbon materials has been proven difficult. In an example, one or more carbon materials may have dimensions in the nanometer range. In another example, one or more carbon materials may scatter or absorb light strongly, thereby reducing or inhibiting a degree of photopolymerization during 3D printing. Even at concentrations less than about 1% by volume of the mixture, incorporating carbon materials (e.g., carbon particles) may be difficult. On the other hand, larger carbon materials (e.g., granulated carbon particles) may be incorporated into mixtures for 3D printing while avoiding one or more of the abovementioned shortcomings of smaller, non-granulated carbon particles.

The granulated particles of the present disclosure may be prepared by binder-assisted agglomeration of small individual particles. In some examples, a small amount of aggregating binder may be used, e.g., less than 10% by weight (wt. %) of the small individual particles or less than 1 wt. % of the smaller individual particles. The binders may be selected based on the material or the surface chemistry of the small individual particles. Alternatively, one or more binds may be usable for a number of different small individual particles. The binders may be selected based on a desired method of debinding prior to sintering (e.g., thermal, solvent, or catalytic debinding methods). Examples of binders to aggregate the small individual particles into one or more granulated particles may include, but are not limited to polypeptides (e.g., proteins), starches, triglycerides, cellulosics, acrylics, styrenics, polyolefins, polyethylene glycol, polytetrahydrofuran, polyoxymethylene, paraformaldehyde, aliphatic polycarbonates, polyesters, novolacs, polyurethanes, epoxies, natural and synthetic waxes, steric acid, lithium stearate (and other metal soaps), adamantane, camphor, naphthalene, and polycarbonates.

The small individual particles of the present disclosure may be formed into one or more granulated particles using several different processes including, but may not be limited to, spray drying, cryogenic spray drying, steam granulation, melt granulation, moist granulation, thermal adhesion granulation, foam granulation, freeze granulation, high shear mixing, and reverse wet granulation. The granulation process may be a simple and low-cost process.

A refractive index of a mixture for 3D printing that does not comprise any suspended particles (e.g., metal or ceramic particles) may range from about 1.3 to about 1.6. Scattering of electromagnetic radiation that is directed towards the mixture may occur significantly (e.g., most strongly) in mixtures comprising a plurality of suspended particles. Such mixtures comprising the plurality of suspended particles (e.g., a plurality of non-granulated particles) may be characterized by having a large difference between the refractive indices of (i) the polymeric precursors and (ii) the suspended particles (e.g., a difference of at least about 1.0, 1.1, 1.2, 1.3, 1.4, 1.5, or more). On the contrary, using a plurality of granulated particles as the suspended particles in the mixture may enhance penetration depth of the electromagnetic radiation, and the resulting mixture may be characterized by having a smaller difference between the refractive indices of (i) the polymeric precursors and (ii) the suspended particles (e.g., a difference of at most about 1.0, 0.9, 0.8, 0.7, 0.6, 0.5, 0.4, 0.3, 0.2, 0.1, or less).

An aspect of the present disclosure provides a mixture for printing a three-dimensional (3D) object. The mixture may comprise a plurality of polymer precursors. The mixture may further comprise a plurality of granulated particles. The plurality of granulated particles may comprise a granulated particle having a cross-sectional size greater than 1 μm (e.g., greater than 10 μm). The granulated particle may comprise an aggregation of a plurality of individual particles. An individual particle of the plurality of individual particles may be smaller than the granulated particle.

Within the aggregation, the plurality of individual particles may be bound to one another. The plurality of individual particles may be directly bound (e.g., in contact with one another, or fused to one another) or indirectly bound (e.g., via one or more binders, i.e., aggregating binders). In some cases, a granulated particle may be formed by both direct binding and indirect binding of the individual particles. In an example, a plurality of individual particles that are fused to one another may be in contact with and/or encapsulated by one or more binders. Examples of a granulation process to generate such granulated particles are presented in the present disclosure.

Examples of the binder for us in the granulation of the plurality of individual particles into one or more granulated articles may include, but are not limited to, polyethylene, polypropylene, poly(n-vinylpryrolidone), poly(styrene-co-maleic anhyride), polyvinyl alcohol, melamine-formaldehyde resin, polycaprolactone, polystyrene, poly(styrene-co-alpha methyl stryene), polytetrahydrofuran, polymethylmethacrylate, poly(aliphatic carbonate), polypropylenecarbonate, poly(styrene-co-methylmethacrylate), polyoxymethylene, paraformaldehyde, functional variants thereof, and combinations thereof.

The mixture may comprise the plurality of granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 20%, 25%, 30%, 35%, 40%, 45%, 50%, 55%, 60%, 65%, 70%, 75%, 80%, 85%, 90%, 95%, or more by weight of the mixture. The mixture may comprise the plurality of granulated particles at an amount of at most about 95%, 90%, 85%, 80%, 75%, 70%, 65%, 60%, 55%, 50%, 45%, 40%, 35%, 30%, 25%, 20%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the mixture.

The mixture may comprise the plurality of granulated particles at an amount of about 0.1% to about 90% by weight of the mixture. The mixture may comprise the plurality of granulated particles at an amount of at least about 0.1% by weight of the mixture. The mixture may comprise the plurality of granulated particles at an amount of at most about 90% by weight of the mixture. The mixture may comprise the plurality of granulated particles at an amount of about 0.1% to about 1%, about 0.1% to about 5%, about 0.1% to about 10%, about 0.1% to about 20%, about 0.1% to about 30%, about 0.1% to about 4%, about 0.1% to about 50%, about 0.1% to about 60%, about 0.1% to about 70%, about 0.1% to about 80%, about 0.1% to about 90%, about 1% to about 5%, about 1% to about 10%, about 1% to about 20%, about 1% to about 30%, about 1% to about 4%, about 1% to about 50%, about 1% to about 60%, about 1% to about 70%, about 1% to about 80%, about 1% to about 90%, about 5% to about 10%, about 5% to about 20%, about 5% to about 30%, about 5% to about 4%, about 5% to about 50%, about 5% to about 60%, about 5% to about 70%, about 5% to about 80%, about 5% to about 90%, about 10% to about 20%, about 10% to about 30%, about 10% to about 4%, about 10% to about 50%, about 10% to about 60%, about 10% to about 70%, about 10% to about 80%, about 10% to about 90%, about 20% to about 30%, about 20% to about 4%, about 20% to about 50%, about 20% to about 60%, about 20% to about 70%, about 20% to about 80%, about 20% to about 90%, about 30% to about 4%, about 30% to about 50%, about 30% to about 60%, about 30% to about 70%, about 30% to about 80%, about 30% to about 90%, about 4% to about 50%, about 4% to about 60%, about 4% to about 70%, about 4% to about 80%, about 4% to about 90%, about 50% to about 60%, about 50% to about 70%, about 50% to about 80%, about 50% to about 90%, about 60% to about 70%, about 60% to about 80%, about 60% to about 90%, about 70% to about 80%, about 70% to about 90%, or about 80% to about 90% by weight of the mixture. The mixture may comprise the plurality of granulated particles at an amount of about 0.1%, about 1%, about 5%, about 10%, about 20%, about 30%, about 4%, about 50%, about 60%, about 70%, about 80%, or about 90% by weight of the mixture.

The cross-sectional size of the granulated particle may be greater than about 100 nm, 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, or more. The cross-sectional size of the granulated particle may be smaller than about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, or less.

An individual particle of the plurality of individual particles may have a cross-sectional size greater than about 1 nm, 2 nm, 3 nm, 4 nm, 5 nm, 6 nm, 7 nm, 8 nm, 9 nm, 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, or more. An individual particle of the plurality of individual particles may have a cross-sectional size smaller than about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, 90 nm, 80 nm, 70 nm, 60 nm, 50 nm, 40 nm, 30 nm, 20 nm, 10 nm, 9 nm, 8 nm, 7 nm, 6 nm, 5 nm, 4 nm, 3 nm, 2 nm, 1 nm, or less.

The plurality of individual particles may be capable of being melted or sintered (e.g., not completely melted). The plurality of individual particles may be inorganic materials. The inorganic materials may be metallic materials, ceramic materials, cermet materials, or any combination thereof. The metallic materials may comprise intermetallic materials. The plurality of individual particles may comprise at least one metallic material, at least one ceramic material, or any combination thereof. The at least one metallic material may comprise at least one intermetallic material.

The metallic materials may include one or more of aluminum, calcium, magnesium, barium, scandium, titanium, vanadium, chromium, manganese, iron, cobalt, nickel, copper, zinc, yttrium, niobium, molybdenum, ruthenium, rhodium, silver, cadmium, actinium, and gold. In some cases, the particles may comprise a rare earth element. The rare earth element may include one or more of scandium, yttrium, and elements of the lanthanide series having atomic numbers from 57-71.

The intermetallic materials may be a solid-state compound exhibiting metallic bonding, defined stoichiometry and ordered crystal structure (i.e., alloys). The intermetallic materials may be in prealloyed powder form. Examples of such prealloyed powders may include, but are not limited to, brass (copper and zinc), bronze (copper and tin), duralumin (aluminum, copper, manganese, and/or magnesium), gold alloys (gold and copper), rose-gold alloys (gold, copper, and zinc), nichrome (nickel and chromium), and stainless steel (iron, carbon, and additional elements including manganese, nickel, chromium, molybdenum, boron, titanium, silicon, vanadium, tungsten, cobalt, and/or niobium). In some cases, the prealloyed powders may include superalloys. The superalloys may be based on elements including iron, nickel, cobalt, chromium, tungsten, molybdenum, tantalum, niobium, titanium, and/or aluminum.

The ceramic materials may comprise metal (e.g., aluminum, titanium, etc.), non-metal (e.g., oxygen, nitrogen, etc.), and/or metalloid (e.g., germanium, silicon, etc.) atoms primarily held in ionic and covalent bonds. Examples of the ceramic materials include, but are not limited to, an aluminide, boride, beryllia, carbide, chromium oxide, hydroxide, sulfide, nitride, mullite, kyanite, ferrite, titania zirconia, yttria, and magnesia.

The cermet materials may be materials comprising a ceramic phase and a metallic phase. In some cases, the ceramic phase of a cermet may be a hard constituent, and the metallic phase of the cermet may be a binder phase. A hard constituent of a cermet may comprise carbides or carbonitrides of one or more members from Ta, Ti, Nb, Cr, Hf, V, Mo, and Zr (e.g., TiN, TiC, and TiCN). In some examples, a cermet may be a cemented carbide, wherein a ceramic phase comprises Tungsten Carbide (TC) and a metallic phase comprises one or more members of Co, Ni, Fe, Cr, and Mo.

The plurality of individual particles may comprise a carbon material. Examples of the carbon material may include, but are not limited to, amorphous black, acetylene black, furnace black, Ketj en black, channel black, lamp black, thermal black, asphalt pitch, coal tar, active carbon, mesophase pitch, and polyacetylenes, natural graphites, flaky graphite, plate-like graphite; high-temperature sintered carbon products obtained, for example, from petroleum coke, coal coke, celluloses, saccharides, and mesophase pitch; artificial graphites, including pyrolytic graphite; carbon nanostructures such as carbon nanotubes; or graphene and graphene-based carbon structures, fullerenes, etc.

The plurality of individual particles may comprise one or more atomized individual particles. The individual particles may be atomized by one or more atomization processes including, but are not limited to, water atomization, gas atomization, electrothermal atomization, flame atomization, glow-discharge atomization, hydride atomization, and cold-vapor atomization.

Another aspect of the present disclosure provides a green body for forming 3D object. The green body may comprise a plurality of granulated particles, which plurality of granulated particles comprises a granulated particle having a cross-sectional size greater than 10 micrometers, wherein the granulated particle comprises an aggregation of a plurality of individual particles. The green body may further comprise a polymeric material at least partially encapsulating the granulated particle. Any of the subject mixtures of the present disclosure may be used to form the green body. Thus, the green body may further comprise one or more components of the subject mixtures of the present disclosure. In some cases, an amount of the one or more components in the subject mixtures may be substantially the same as an amount of the one or more component in the green body.

The green body may comprise the plurality of granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 20%, 25%, 30%, 35%, 40%, 45%, 50%, 55%, 60%, 65%, 70%, 75%, 80%, 85%, 90%, 95%, or more by weight of the green body. The green body may comprise the plurality of granulated particles at an amount of at most about 95%, 90%, 85%, 80%, 75%, 70%, 65%, 60%, 55%, 50%, 45%, 40%, 35%, 30%, 25%, 20%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the green body.

The green body may comprise the plurality of granulated particles at an amount of about 0.1% to about 90% by weight of the green body. The green body may comprise the plurality of granulated particles at an amount of at least about 0.1% by weight of the green body. The green body may comprise the plurality of granulated particles at an amount of at most about 90% by weight of the green body. The green body may comprise the plurality of granulated particles at an amount of about 0.1% to about 1%, about 0.1% to about 5%, about 0.1% to about 10%, about 0.1% to about 20%, about 0.1% to about 30%, about 0.1% to about 4%, about 0.1% to about 50%, about 0.1% to about 60%, about 0.1% to about 70%, about 0.1% to about 80%, about 0.1% to about 90%, about 1% to about 5%, about 1% to about 10%, about 1% to about 20%, about 1% to about 30%, about 1% to about 4%, about 1% to about 50%, about 1% to about 60%, about 1% to about 70%, about 1% to about 80%, about 1% to about 90%, about 5% to about 10%, about 5% to about 20%, about 5% to about 30%, about 5% to about 4%, about 5% to about 50%, about 5% to about 60%, about 5% to about 70%, about 5% to about 80%, about 5% to about 90%, about 10% to about 20%, about 10% to about 30%, about 10% to about 4%, about 10% to about 50%, about 10% to about 60%, about 10% to about 70%, about 10% to about 80%, about 10% to about 90%, about 20% to about 30%, about 20% to about 4%, about 20% to about 50%, about 20% to about 60%, about 20% to about 70%, about 20% to about 80%, about 20% to about 90%, about 30% to about 4%, about 30% to about 50%, about 30% to about 60%, about 30% to about 70%, about 30% to about 80%, about 30% to about 90%, about 4% to about 50%, about 4% to about 60%, about 4% to about 70%, about 4% to about 80%, about 4% to about 90%, about 50% to about 60%, about 50% to about 70%, about 50% to about 80%, about 50% to about 90%, about 60% to about 70%, about 60% to about 80%, about 60% to about 90%, about 70% to about 80%, about 70% to about 90%, or about 80% to about 90% by weight of the green body. The green body may comprise the plurality of granulated particles at an amount of about 0.1%, about 1%, about 5%, about 10%, about 20%, about 30%, about 4%, about 50%, about 60%, about 70%, about 80%, or about 90% by weight of the green body.

Another aspect of the present disclosure provides a mixture for printing a 3D object. The mixture may comprise a plurality of polymer precursors. The mixture may further comprise a plurality of particles comprising granulated particles and non-granulated particles. The mixture herein may further comprise one or more components of any of the subject mixtures of the present disclosure. In some cases, an amount of the one or more components in the subject mixtures may be substantially the same as an amount of the one or more component in the green body.

The granulated particles and the non-granulated particles may comprise a same material (e.g., the same metal (or intermetallic), ceramic, cermet, or carbon material). In some cases, the plurality of particles may comprise the non-granulated particles at an amount of greater than about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles. Alternatively, the plurality of particle may comprise the non-granulated particles at an amount of less than about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles. In some cases, the plurality of particles may comprise the granulated particles at an amount of greater than about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles. Alternatively, the plurality of particle may comprise the granulated particles at an amount of less than about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles.

The granulated particles and non-granulated particles may comprise different materials. In some cases, the granulated particles may comprise a material selected from the group consisting of metal, ceramic, cermet, and carbon materials, and the non-granulated particles may comprise a different material selected from the group consisting of metal, ceramic, cermet, and carbon materials. In some cases, the plurality of particles may comprise the non-granulated particles at an amount of at most about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles. Alternatively, the plurality of particles may comprise the non-granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles. In some cases, the plurality of particles may comprise the granulated particles at an amount of at most about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles. Alternatively, the plurality of particles may comprise the granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles.

The plurality of particles may comprise the granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 20%, 25%, 30%, 35%, 40%, 45%, 50%, 55%, 60%, 65%, 70%, 75%, 80%, 85%, 90%, 95%, or more by weight of the plurality of particles. Alternatively, the plurality of particles may comprise the granulated particles at an amount of at most about 95%, 90%, 85%, 80%, 75%, 70%, 65%, 60%, 55%, 50%, 45%, 40%, 35%, 30%, 25%, 20%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles.

The plurality of particles may comprise the granulated particles at an amount of about 0.1% to about 90% by weight of the plurality of particles. The plurality of particles may comprise the granulated particles at an amount of at least about 0.1% by weight of the plurality of particles. The plurality of particles may comprise the granulated particles at an amount of at most about 90% by weight of the plurality of particles. The plurality of particles may comprise the granulated particles at an amount of about 0.1% to about 1%, about 0.1% to about 2%, about 0.1% to about 3%, about 0.1% to about 4%, about 0.1% to about 5%, about 0.1% to about 10%, about 0.1% to about 20%, about 0.1% to about 40%, about 0.1% to about 60%, about 0.1% to about 80%, about 0.1% to about 90%, about 1% to about 2%, about 1% to about 3%, about 1% to about 4%, about 1% to about 5%, about 1% to about 10%, about 1% to about 20%, about 1% to about 40%, about 1% to about 60%, about 1% to about 80%, about 1% to about 90%, about 2% to about 3%, about 2% to about 4%, about 2% to about 5%, about 2% to about 10%, about 2% to about 20%, about 2% to about 40%, about 2% to about 60%, about 2% to about 80%, about 2% to about 90%, about 3% to about 4%, about 3% to about 5%, about 3% to about 10%, about 3% to about 20%, about 3% to about 40%, about 3% to about 60%, about 3% to about 80%, about 3% to about 90%, about 4% to about 5%, about 4% to about 10%, about 4% to about 20%, about 4% to about 40%, about 4% to about 60%, about 4% to about 80%, about 4% to about 90%, about 5% to about 10%, about 5% to about 20%, about 5% to about 40%, about 5% to about 60%, about 5% to about 80%, about 5% to about 90%, about 10% to about 20%, about 10% to about 40%, about 10% to about 60%, about 10% to about 80%, about 10% to about 90%, about 20% to about 40%, about 20% to about 60%, about 20% to about 80%, about 20% to about 90%, about 40% to about 60%, about 40% to about 80%, about 40% to about 90%, about 60% to about 80%, about 60% to about 90%, or about 80% to about 90% by weight of the plurality of particles. The plurality of particles may comprise the granulated particles at an amount of about 0.1%, about 1%, about 2%, about 3%, about 4%, about 5%, about 10%, about 20%, about 40%, about 60%, about 80%, or about 90% by weight of the plurality of particles.

A cross-sectional size of the granulated particle may be greater than about 100 nm, 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, or more. A cross-sectional size of the granulated particle may be smaller than about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, or less.

A granulated particle may comprise a plurality of individual particles. An individual particle of the plurality of individual particles may have a cross-sectional size greater than about 1 nm, 2 nm, 3 nm, 4 nm, 5 nm, 6 nm, 7 nm, 8 nm, 9 nm, 10 nm, 20 nm, 30 nm, 40 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, or more. An individual particle of the plurality of individual particles may have a cross-sectional size smaller than about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, 90 nm, 80 nm, 70 nm, 60 nm, 50 nm, 40 nm, 30 nm, 20 nm, 10 nm, 9 nm, 8 nm, 7 nm, 6 nm, 5 nm, 4 nm, 3 nm, 2 nm, 1 nm, or less.

A cross-sectional size of the non-granulated particle may be greater than about 100 nm, 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, or more. A cross-sectional size of the non-granulated particle may be smaller than about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, or less.

Another aspect of the present disclosure provides a green body for forming 3D object. The green body may comprise a plurality of particles comprising granulated particles and non-granulated particles. The green body may further comprise a polymeric material at least partially encapsulating the plurality of particles. Any of the subject mixtures of the present disclosure may be used to form the green body. Thus, the green body may further comprise one or more additional components of the subject mixture of the present disclosure. In some cases, an amount of one or more components in the mixture may be substantially the same as an amount of the one or more component in the green body.

The granulated particles and the non-granulated particles of the green body may comprise a same material (e.g., the same metal (or intermetallic), ceramic, cermet, or carbon material). In some cases, the plurality of particles may comprise the non-granulated particles at an amount of greater than about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles. Alternatively, the plurality of particle may comprise the non-granulated particles at an amount of less than about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles. In some cases, the plurality of particles may comprise the granulated particles at an amount of greater than about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles. Alternatively, the plurality of particle may comprise the granulated particles at an amount of less than about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles.

The granulated particles and non-granulated particles of the green body may comprise different materials. In some cases, the granulated particles may comprise a material selected from the group consisting of metal, ceramic, cermet, and carbon materials, and the non-granulated particles may comprise a different material selected from the group consisting of metal, ceramic, cermet, and carbon materials. In some cases, the plurality of particles may comprise the non-granulated particles at an amount of at most about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles. Alternatively, the plurality of particles may comprise the non-granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles. In some cases, the plurality of particles may comprise the granulated particles at an amount of at most about 90%, 85%, 80%, 75%, 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles. Alternatively, the plurality of particles may comprise the granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, 75%, 80%, 85%, 90%, or more by weight of the plurality of particles.

The plurality of particles of the green body may comprise the granulated particles at an amount of at least about 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 20%, 25%, 30%, 35%, 40%, 45%, 50%, 55%, 60%, 65%, 70%, 75%, 80%, 85%, 90%, 95%, or more by weight of the plurality of particles. Alternatively, the plurality of particles may comprise the granulated particles at an amount of at most about 95%, 90%, 85%, 80%, 75%, 70%, 65%, 60%, 55%, 50%, 45%, 40%, 35%, 30%, 25%, 20%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, or less by weight of the plurality of particles.

The plurality of particles of the green body may comprise the granulated particles at an amount of about 0.1% to about 90% by weight of the plurality of particles. The plurality of particles may comprise the granulated particles at an amount of at least about 0.1% by weight of the plurality of particles. The plurality of particles may comprise the granulated particles at an amount of at most about 90% by weight of the plurality of particles. The plurality of particles may comprise the granulated particles at an amount of about 0.1% to about 1%, about 0.1% to about 2%, about 0.1% to about 3%, about 0.1% to about 4%, about 0.1% to about 5%, about 0.1% to about 10%, about 0.1% to about 20%, about 0.1% to about 40%, about 0.1% to about 60%, about 0.1% to about 80%, about 0.1% to about 90%, about 1% to about 2%, about 1% to about 3%, about 1% to about 4%, about 1% to about 5%, about 1% to about 10%, about 1% to about 20%, about 1% to about 40%, about 1% to about 60%, about 1% to about 80%, about 1% to about 90%, about 2% to about 3%, about 2% to about 4%, about 2% to about 5%, about 2% to about 10%, about 2% to about 20%, about 2% to about 40%, about 2% to about 60%, about 2% to about 80%, about 2% to about 90%, about 3% to about 4%, about 3% to about 5%, about 3% to about 10%, about 3% to about 20%, about 3% to about 40%, about 3% to about 60%, about 3% to about 80%, about 3% to about 90%, about 4% to about 5%, about 4% to about 10%, about 4% to about 20%, about 4% to about 40%, about 4% to about 60%, about 4% to about 80%, about 4% to about 90%, about 5% to about 10%, about 5% to about 20%, about 5% to about 40%, about 5% to about 60%, about 5% to about 80%, about 5% to about 90%, about 10% to about 20%, about 10% to about 40%, about 10% to about 60%, about 10% to about 80%, about 10% to about 90%, about 20% to about 40%, about 20% to about 60%, about 20% to about 80%, about 20% to about 90%, about 40% to about 60%, about 40% to about 80%, about 40% to about 90%, about 60% to about 80%, about 60% to about 90%, or about 80% to about 90% by weight of the plurality of particles. The plurality of particles may comprise the granulated particles at an amount of about 0.1%, about 1%, about 2%, about 3%, about 4%, about 5%, about 10%, about 20%, about 40%, about 60%, about 80%, or about 90% by weight of the plurality of particles.

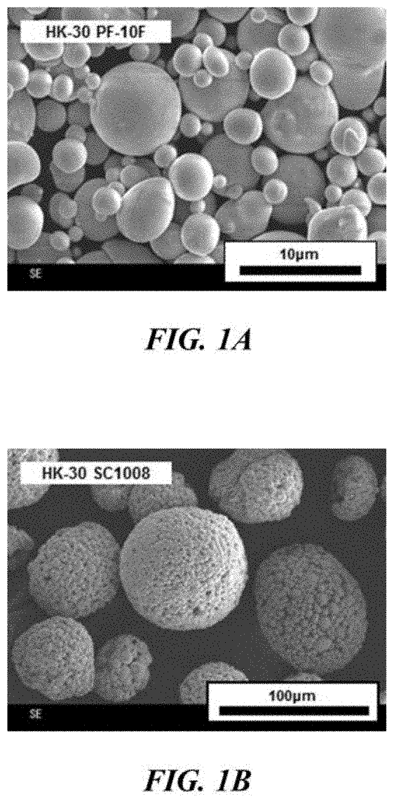

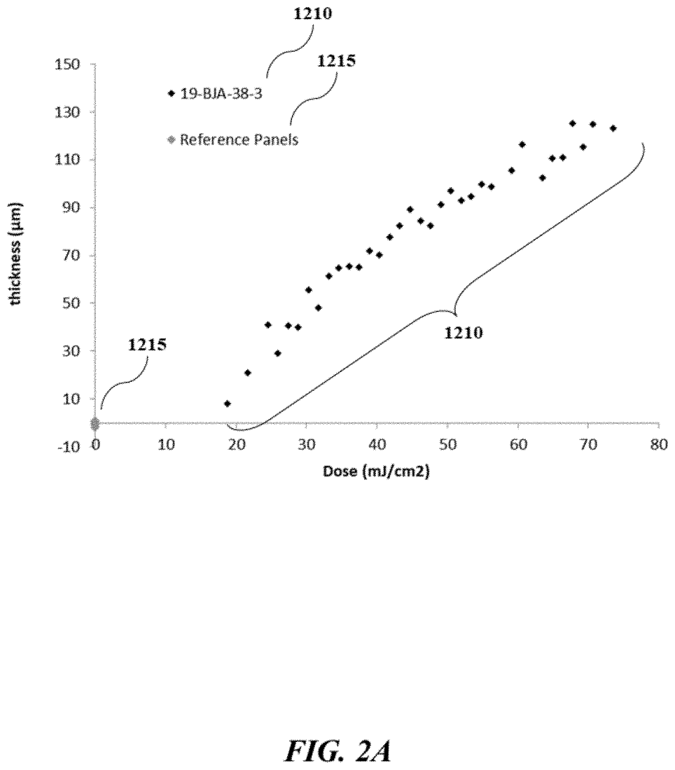

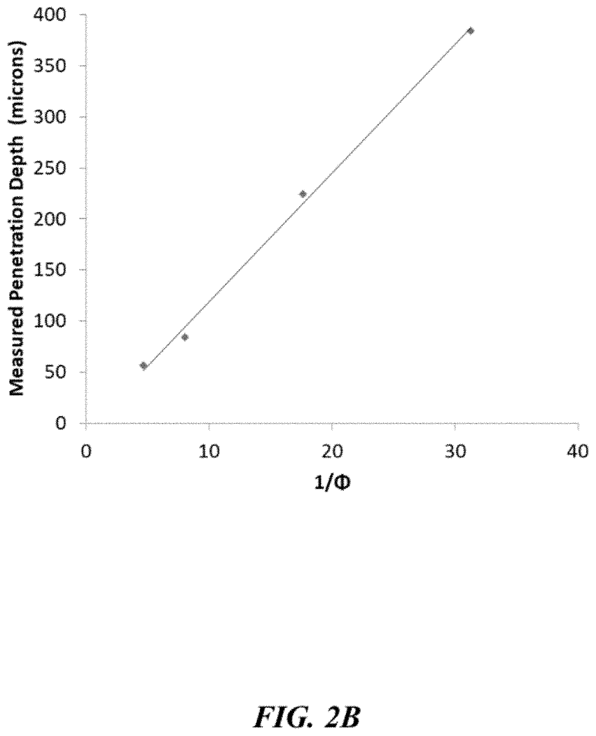

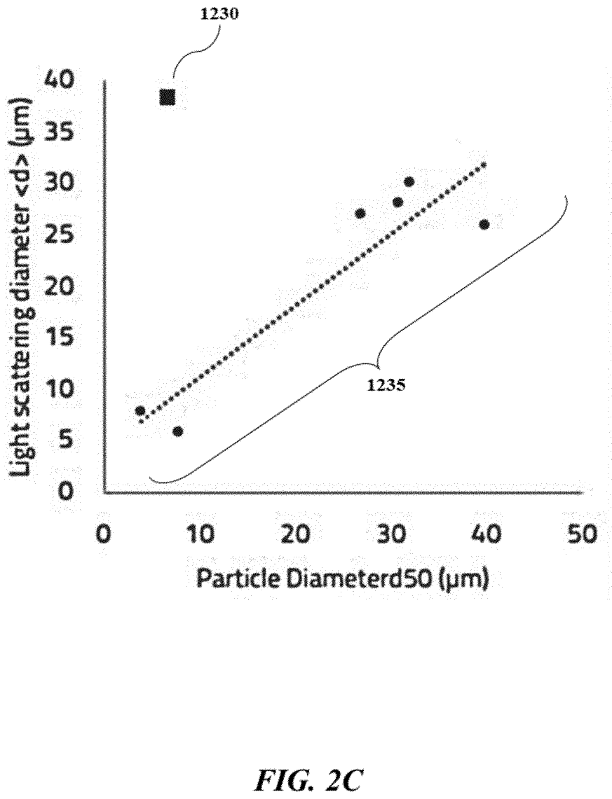

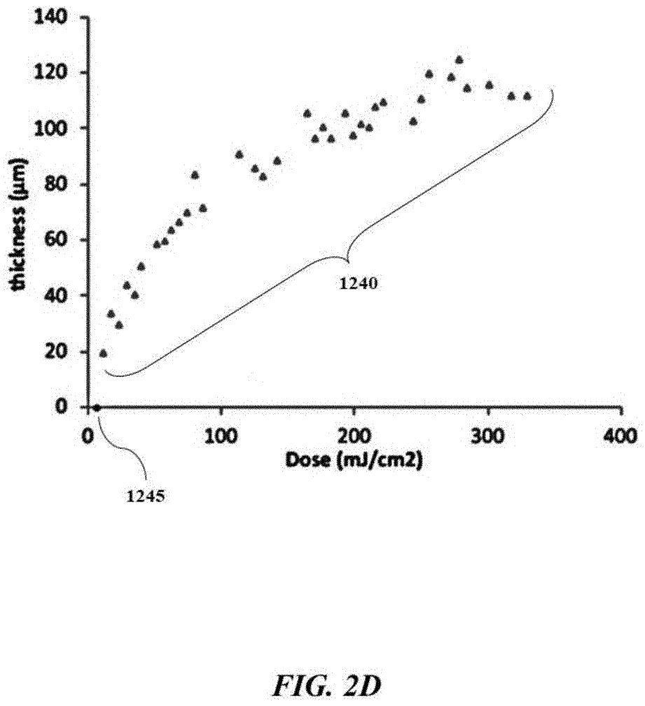

Examples of granulated particles, 3D printing mixtures comprising the granulated particles, and the effect of the granulated particles on scattering and penetration depth of the photoinitiation light are shown in FIG. 1, Table 1, and FIG. 2.

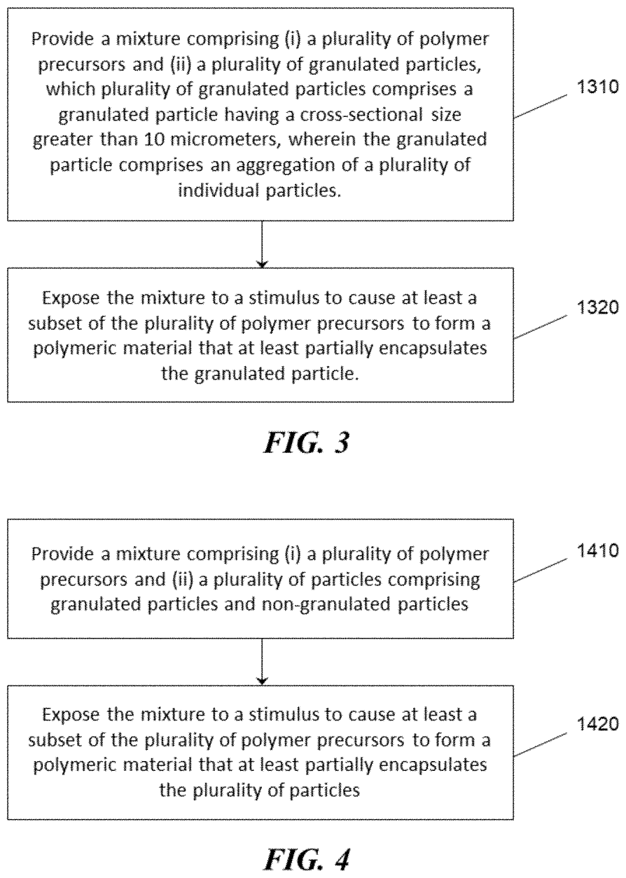

Another aspect of the present disclosure provides a method for printing a 3D object. FIG. 3 shows an example flowchart of a method for 3D printing. The method may comprise providing a mixture (process 1310). The mixture for 3D printing may comprise one or more components of any subject mixture for 3D printing, as provided in the present disclosure. In some embodiments, the mixture may comprise (i) a plurality of polymer precursors and (ii) a plurality of granulated particles, which plurality of granulated particles comprises a granulated particle having a cross-sectional size greater than 10 micrometers. The granulated particle may comprise an aggregation of a plurality of individual particles. The method may further comprise exposing the mixture to a stimulus to cause at least a subset of the plurality of polymer precursors to form a polymeric material that at least partially encapsulates the granulated particle (process 1320).

Another aspect of the present disclosure provides a different method for printing 3D object. FIG. 4 shows an example flowchart of a method for 3D printing. The method may comprise providing a mixture (process 1410). The mixture for 3D printing may comprise one or more components of any subject mixture for 3D printing, as provided in the present disclosure. In some embodiments, the method may comprise providing a mixture comprising (i) a plurality of polymer precursors and (ii) a plurality of particles comprising granulated particles and non-granulated particles. The method may further comprise exposing the mixture to a stimulus to cause at least a subset of the plurality of polymer precursors to form a polymeric material that at least partially encapsulates the plurality of particles (process 1420).

B. Precursor Compounds for Particles

In some aspects, the present disclosure describes using a plurality of particle precursors (e.g., precursors for forming one or more particles, such as nanoparticles). The plurality of particle precursors may be a part of a resin for 3D printing (e.g., a resin comprising polymeric precursors or photoinitiators). Upon exposure to a stimulus (e.g., an electromagnetic radiation or heat), the plurality of particle precursors may form a particle having two or more particle precursors from the plurality of particle precursors. Examples of a particle precursor of the plurality of particle precursors may include, but are not limited to, a soluble metal or metal alloy compound, a soluble ceramic precursor compound, and a soluble cermet precursor compound. In some cases, the particle precursor may be a sintering aid. In some embodiments, the particle precursor may be non-scattering.

In some embodiments, a soluble compound of the metal (including metal alloys), ceramic, or cermet precursor compound of interest is added to a feedstock that contains large particles (30-60 μm) made of the same metal, ceramic, or cermet. The feedstock is used to print a 3D green body. The soluble compound dissolves in the feedstock to form a homogenous part of the feedstock and does not scatter the photoradiation used in the 3D printing process. The large metal, ceramic, or cermet particles do cause some scattering, but, as shown above, they allow a penetration depth similar to their size, which is sufficient for 3D printing. On subsequent debinding (treating the green body to form a brown body), newly formed particles (e.g., nanoparticles or microparticles) of the metal, ceramic, or cermet form from the soluble precursor compound and deposit onto pre-existing particles (e.g., the large particles). The newly formed particles may serve to increase the surface energy of the large particles, which helps to drive the sintering process, allowing it to proceed in a reasonable pace and to produce a desired high density in the finished part.

A particle formed of a plurality of soluble particle precursors can be characterized by a size (e.g., an average diameter). The particle size may be at least about 0.1 nanometer, 0.2 nm, 0.3 nm, 0.4 nm, 0.5 nm, 0.6 nm, 0.7 nm, 0.8 nm, 0.9 nm, 1 nm, 2 nm, 3 nm, 4 nm, 5 nm, 6 nm, 7 nm, 8 nm, 9 nm, 10 nm, 15 nm, 20 nm, 25 nm, 30 nm, 35 nm, 40 nm, 45 nm, 50 nm, 60 nm, 70 nm, 80 nm, 90 nm, 100 nm, 200 nm, 300 nm, 400 nm, 500 nm, 600 nm, 700 nm, 800 nm, 900 nm, 1 micrometer (μm), 2 μm, 3 μm, 4 μm, 5 μm, 6 μm, 7 μm, 8 μm, 9 μm, 10 μm, 20 μm, 30 μm, 40 μm, 50 μm, 60 μm, 70 μm, 80 μm, 90 μm, 100 μm, 200 μm, 300 μm, 400 μm, 500 μm, or more. The particle size may be at most about 500 μm, 400 μm, 300 μm, 200 μm, 100 μm, 90 μm, 80 μm, 70 μm, 60 μm, 50 μm, 40 μm, 30 μm, 20 μm, 10 μm, 9 μm, 8 μm, 7 μm, 6 μm, 5 μm, 4 μm, 3 μm, 2 μm, 1 μm, 900 nm, 800 nm, 700 nm, 600 nm, 500 nm, 400 nm, 300 nm, 200 nm, 100 nm, 90 nm, 80 nm, 70 nm, 60 nm, 50 nm, 40 nm, 30 nm, 20 nm, 10 nm, 9 nm, nm, 7 nm, 6 nm, 5 nm, 4 nm, 3 nm, 2 nm, 1 nm, 0.9 nm, 0.8 nm, 0.7 nm, 0.6 nm, 0.5 nm, 0.4 nm, 0.3 nm, 0.2 nm, 0.1 nm, or less.

In some cases, the particle formed of a plurality of soluble particle precursors may be a nanoparticle. The nanoparticle size can be about 0.1 nm to about 500 nm. The nanoparticle size can be at least about 0.1 nm. The nanoparticle size can be at most about 500 nm. The nanoparticle size can be about 0.1 nm to about 0.5 nm, about 0.1 nm to about 1 nm, about 0.1 nm to about 5 nm, about 0.1 nm to about 10 nm, about 0.1 nm to about 50 nm, about 0.1 nm to about 100 nm, about 0.1 nm to about 500 nm, about 0.5 nm to about 1 nm, about 0.5 nm to about 5 nm, about 0.5 nm to about 10 nm, about 0.5 nm to about 50 nm, about 0.5 nm to about 100 nm, about 0.5 nm to about 500 nm, about 1 nm to about 5 nm, about 1 nm to about 10 nm, about 1 nm to about 50 nm, about 1 nm to about 100 nm, about 1 nm to about 500 nm, about 5 nm to about 10 nm, about 5 nm to about 50 nm, about 5 nm to about 100 nm, about 5 nm to about 500 nm, about 10 nm to about 50 nm, about 10 nm to about 100 nm, about 10 nm to about 500 nm, about 50 nm to about 100 nm, about 50 nm to about 500 nm, or about 100 nm to about 500 nm. The nanoparticle size can be about 0.1 nm, about 0.5 nm, about 1 nm, about 5 nm, about 10 nm, about 50 nm, about 100 nm, or about 500 nm. In some cases, the nanoparticle size can be about 10 nm to about 100 nm.

In some cases, the particle formed of a plurality of soluble particle precursors may be a microparticle. The microparticle size can be about 0.5 μm to about 500 μm. The microparticle size can be at least about 0.5 μm. The microparticle size can be at most about 500 μm. The microparticle size can be about 0.5 μm to about 1 μm, about 0.5 μm to about 5 μm, about 0.5 μm to about 10 μm, about 0.5 μm to about 50 μm, about 0.5 μm to about 100 μm, about 0.5 μm to about 500 μm, about 1 μm to about 5 μm, about 1 μm to about 10 μm, about 1 μm to about 50 μm, about 1 μm to about 100 μm, about 1 μm to about 500 μm, about 5 μm to about 10 μm, about 5 μm to about 50 μm, about 5 μm to about 100 μm, about 5 μm to about 500 μm, about 10 μm to about 50 μm, about 10 μm to about 100 μm, about 10 μm to about 500 μm, about 50 μm to about 100 μm, about 50 μm to about 500 μm, or about 100 μm to about 500 μm. The microparticle size can be about 0.5 μm, about 1 μm, about 5 μm, about 10 μm, about 50 μm, about 100 μm, or about 500 μm.

In some cases, a soluble particle precursor compound may comprise (i) a first portion (e.g., metal, ceramic, or cermet molecules) configured to form a particle upon exposure to a stimulus (e.g., heat) and (ii) a second portion (e.g., organic materials) that do not form any particle upon exposure to the stimulus. Upon exposure to such stimulus, a plurality of the first portion of the soluble particle precursor compound may form one or more of first particles (e.g., nanoparticles or microparticles). For example, a first portion of copper acetate may be copper, while the second portion thereof may be acetate. In some cases, a mixture comprising the soluble particle precursor compound may further comprise a plurality of pre-formed particles (e.g., nanoparticles or microparticles). The pre-formed particle may be formed prior to 3D printing (and sintering). A subject mixture for 3D printing may comprise a plurality of the pre-formed particles prior to 3D printing (and sintering). The first portion of the soluble particle precursor compound and a preformed particle of the plurality of pre-formed particles may comprise the same material (e.g., the same metal, ceramic, or cermet material) or different materials. Upon exposure to the stimulus, (i) the first portion of the soluble particle precursor compound and (ii) one or more of the pre-formed particles may collectively form one or more second particles (e.g., via coalescence) that are larger in size than the pre-formed particles.

An individual particle of the one or more second particles may comprise the first portion of the soluble particle precursor compound (e.g., copper from copper acetate) at an amount of at least about 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, or more by weight of the individual particle. An individual particle of the one or more second particles may comprise the first portion of the soluble particle precursor compound at an amount of at most about 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, 0.09%, 0.08%, 0.07%, 0.06%, 0.05%, 0.04%, 0.03%, 0.02%, 0.01%, or less.

An individual particle of the one or more second particles may comprise one or more of the pre-formed particles (e.g., copper nanoparticles or microparticles) at an amount of at least about 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, or more by weight of the individual particle. An individual particle of the one or more second particles may comprise the first portion of the soluble particle precursor compound at an amount of at most about 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, 0.09%, 0.08%, 0.07%, 0.06%, 0.05%, 0.04%, 0.03%, 0.02%, 0.01%, or less.

In a mixture comprising a plurality of soluble particle precursor compound (e.g., copper acetate) and a plurality of pre-formed particles (e.g., copper nanoparticles or microparticles), an amount of the plurality of the soluble particle precursor compound may be at least about 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, or more by weight of the mixture. In a mixture comprising a plurality of soluble particle precursor compound and a plurality of pre-formed particles, an amount of the plurality of the soluble particle precursor compound may be at most about 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, 0.09%, 0.08%, 0.07%, 0.06%, 0.05%, 0.04%, 0.03%, 0.02%, 0.01%, or less by weight of the mixture.

In a mixture comprising a plurality of soluble particle precursor compound (e.g., copper acetate) and a plurality of pre-formed particles (e.g., copper nanoparticles or microparticles), an amount of the plurality of pre-formed particles may be at least about 0.01%, 0.02%, 0.03%, 0.04%, 0.05%, 0.06%, 0.07%, 0.08%, 0.09%, 0.1%, 0.2%, 0.3%, 0.4%, 0.5%, 0.6%, 0.7%, 0.8%, 0.9%, 1%, 2%, 3%, 4%, 5%, 6%, 7%, 8%, 9%, 10%, 11%, 12%, 13%, 14%, 15%, 16%, 17%, 18%, 19%, 20%, 25%, 30%, 35%, 40%, 45%, 50%, 55%, 60%, 65%, 70%, or more by weight of the mixture. In a mixture comprising a plurality of soluble particle precursor compound and a plurality of pre-formed particles, an amount of the plurality of pre-formed particles may be at most about 70%, 65%, 60%, 55%, 50%, 45%, 40%, 35%, 30%, 25%, 20%, 19%, 18%, 17%, 16%, 15%, 14%, 13%, 12%, 11%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, 0.1%, 0.09%, 0.08%, 0.07%, 0.06%, 0.05%, 0.04%, 0.03%, 0.02%, 0.01%, or less by weight of the mixture.

In a mixture comprising a plurality of soluble particle precursor compound (e.g., copper acetate) and a plurality of pre-formed particles (e.g., copper nanoparticles or microparticles), the weight ratio of (a) the plurality of soluble particle precursor compound to (b) the plurality of pre-formed particles (a:b) may be about 0.1 to 100, 0.2 to 100, 0.3 to 100, 0.4 to 100,0.5 to 100, 0.6 to 100, 0.7 to 100, 0.8 to 100, 0.9 to 100, 1 to 100, 2 to 100, 3 to 100, 4 to 100, 5 to 100, 6 to 100, 7 to 100, 8 to 100, 9 to 100, 10 to 100, 15 to 100, 20 to 100, 25 to 100, 30 to 100, 35 to 100, 40 to 100, 45 to 100, 50 to 100, 60 to 100, 70 to 100, 80 to 100, 90 to 100, 100 to 100, or any range within the aforementioned range.

In a mixture comprising a plurality of soluble particle precursor compound (e.g., copper acetate) and a plurality of pre-formed particles (e.g., copper nanoparticles or microparticles), the weight ratio of (b) the plurality of pre-formed particles to (a) the plurality of soluble particle precursor compound (b:a) may be about 0.1 to 100, 0.2 to 100, 0.3 to 100, 0.4 to 100, 0.5 to 100, 0.6 to 100, 0.7 to 100, 0.8 to 100, 0.9 to 100, 1 to 100, 2 to 100, 3 to 100, 4 to 100, 5 to 100, 6 to 100, 7 to 100, 8 to 100, 9 to 100, 10 to 100, 15 to 100, 20 to 100, 25 to 100, 30 to 100, 35 to 100, 40 to 100, 45 to 100, 50 to 100, 60 to 100, 70 to 100, 80 to 100, 90 to 100, 100 to 100, or any range within the aforementioned range.

A particle of the plurality of pre-formed particles may be between about 500 nm to about 500 μm. A size of the particle of the plurality of pre-formed particles may be at least about 500 nm, 600 nm, 700 nm, 800 nm, 900 nm, 1 μm, 5 μm, 10 μm, 20 μm, 30 μm, 40 μm, 50 μm, 60 μm, 70 μm, 80 μm, 90 μm, 100 μm, 150 μm, 200 μm, 250 μm, 300 μm, 350 μm, 400 μm, 450 μm, 500 μm, or more. A size of the particle of the plurality of pre-formed particles may be at most about 500 μm, 450 μm, 400 μm, 350 μm, 300 μm, 250 μm, 200 μm, 150 μm, 100 μm, 90 μm, 80 μm, 70 μm, 60 μm, 50 μm, 40 μm, 30 μm, 20 μm, 10 μm, 5 μm, 1 μm, 900 nm, 800 nm, 700 nm, 600 nm, 500 nm, or less. In some cases, a size of the particle of the plurality of pre-formed particles may be between about 1 μm and about 500 μm, about 1 μm and about 200 μm, about 1 μm and about 150 μm, or about 1 μm and about 100 μm.

In some cases, the particle may be a microparticle. The microparticle size can be about 0.5 μm to about 500 μm. The microparticle size can be at least about 0.5 μm. The microparticle size can be at most about 500 μm. The microparticle size can be about 0.5 μm to about 1 μm, about 0.5 μm to about 5 μm, about 0.5 μm to about 10 μm, about 0.5 μm to about 50 μm, about 0.5 μm to about 100 μm, about 0.5 μm to about 500 μm, about 1 μm to about 5 μm, about 1 μm to about 10 μm, about 1 μm to about 50 μm, about 1 μm to about 100 μm, about 1 μm to about 500 μm, about 5 μm to about 10 μm, about 5 μm to about 50 μm, about 5 μm to about 100 μm, about 5 μm to about 500 μm, about 10 μm to about 50 μm, about 10 μm to about 100 μm, about 10 μm to about 500 μm, about 50 μm to about 100 μm, about 50 μm to about 500 μm, or about 100 μm to about 500 μm. The microparticle size can be about 0.5 μm, about 1 μm, about 5 μm, about 10 μm, about 50 μm, about 100 μm, or about 500 μm.

In some cases, the soluble particle precursor may be a soluble metal precursor. The soluble metal precursor may comprise a metal-ligand complex. Examples of the metal of the metal-ligand complex may include, but are not limited to, Ag, Cu, Ni, Fe, Co, Pb, Au, Sn, Al, Zr, Li, Mn, Cr, Be, Cd, Si, Ti, V, Hf, Sr, Ba, Ge, and combinations thereof. In some cases, a metal-ligand complex may comprise a metal alloy. Examples of the metal alloy may include, but are not limited to, metal alloys include CdSe, CdTe, Pb Se, PbTe, FeNi (perm alloy), Fe—Pt intermetallic compound, Pt—Pb, Pt—Pd, Pt—Bi, Pd—Cu, Pd—Hf, variations thereof, and combinations thereof. Examples of the ligand of the metal-ligand complex may include, but are not limited to, a carboxylate, a nitrate, a halide, a diketone, an alkoxide, functional variants thereof, and combinations thereof. In some cases, the ligand of the metal-ligand complex may be associated with (e.g., coupled to or covalently coupled to) a polymer. Examples of such polymer may include, but are not limited to, polyvinyl alcohol (PVA), polyvinyl acetate (PVAc), polyethylene oxide (PEO), polyvinyl ether, polyvinyl pyrrolidone, polyglycolic acid, hydroxyethylcellulose (HEC), ethylcellulose, cellulose ethers, polyacrylic acid, polyisocyanate, a variant thereof, and a combination thereof. Examples of the metal-ligand complex may include, but are not limited to, metal acetate (e.g., copper acetate), metal nitrate, metal chloride, metal methoxide, a variant thereof, and a combination thereof.

In some cases, the soluble particle precursor may be a soluble ceramic precursor. The soluble ceramic precursor may comprise a ceramic (e.g., metal oxide)-ligand complex. Examples of the ceramic of the ceramic-ligand complex may include, but are not limited to, Al₂O₃, ZrO₂, Fe₂O₃, CuO, NiO, ZnO, CdO, C, Ge, Si, SiO₂, TiO₂, V₂O₅, VO₂, Fe₃O₄, SnO, SnO₂, CoO, CoO₂, Co₃O₄, HfO₂, BaTiO₃, SrTiO₃, and BaSrTiO₃., variants thereof, and combinations thereof. Alternatively or in addition to, the soluble ceramic precursor may comprise a polymer that can be heated (or pyrolyzed) to form a ceramic material. Examples of such polymer may include polyorganozirconates, polyorganoaluminates, polysiloxanes, polysilanes, polysilazanes, polycarbosilanes, polyborosilanes, etc. Additional examples of the pre-ceramic material include zirconium tetramethacrylate, zirconyl dimethacrylate, or zirconium 2-ethylhexanoate; aluminum III s-butoxide, aluminum III diisopropoxide-ethylacetoacetate; 1,3-bis(chloromethyl) 1,1,3,3-Tetrakis(trimethylsiloxy)disiloxane; 1,3-bis(3-carboxypropyl)tetramethyldisiloxane; 1,3,5,7-tetraethyl-2,4,6,8-tetramethylcyclotetrasilazane; tris(trimethylsilyl)phosphate; tris(trimethylsiloxy)boron, variations thereof, and combinations thereof.

A resin comprising (i) a plurality of polymeric precursors and (ii) a plurality of precursor compounds (e.g., for forming metal and/or ceramic particles or coalescing other metal and/or ceramic particles) may be used to print a 3D object comprising a polymeric material and the plurality of precursor compounds. Each precursor compound of the plurality of precursor compounds may comprise an organic portion and an inorganic portion.

The organic portion of the precursor compound may decompose (e.g., upon heating) to allow the inorganic portion (e.g., the metal or ceramic moiety) to (i) coalesce to form nano- or microparticles, (ii) couple to other nano—or microparticles, and/or (iii) coalesce other nano—or microparticles into even larger aggregates. Such heating may be less than, approximately equal to, or greater than a temperature sufficient to decompose (or degrade) the printed polymeric material. In some examples, the organic portion of the precursor compound may decompose at a temperature that is substantially the same as a decomposition temperature of the polymeric material. In some cases, the heating may be less than, approximately equal to, or greater than a temperature sufficient to sinter the printed object.

In some cases, the organic portion of the precursor compound may decompose at a temperature that is lower than a decomposition temperature of the polymeric material. The decomposition temperature of the organic portion of the precursor compound may be lower than the decomposition temperature of the polymeric material by at least about 1 degree Celsius, 2 degrees Celsius, 3 degrees Celsius, 4 degrees Celsius, 5 degrees Celsius, 10 degrees Celsius, 15 degrees Celsius, 20 degrees Celsius, 25 degrees Celsius, 30 degrees Celsius, 35 degrees Celsius, 40 degrees Celsius, 45 degrees Celsius, 50 degrees Celsius, 60 degrees Celsius, 70 degrees Celsius, 80 degrees Celsius, 90 degrees Celsius, 100 degrees Celsius, 150 degrees Celsius, 200 degrees Celsius, 250 degrees Celsius, 300 degrees Celsius, 350 degrees Celsius, 400 degrees Celsius, 450 degrees Celsius, 500 degrees Celsius, or more. The decomposition temperature of the organic portion of the precursor compound may be lower than the decomposition temperature of the polymeric material by at most about 500 degrees Celsius, 450 degrees Celsius, 400 degrees Celsius, 350 degrees Celsius, 300 degrees Celsius, 250 degrees Celsius, 200 degrees Celsius, 150 degrees Celsius, 100 degrees Celsius, 90 degrees Celsius, 80 degrees Celsius, 70 degrees Celsius, 60 degrees Celsius, 50 degrees Celsius, 45 degrees Celsius, 40 degrees Celsius, 35 degrees Celsius, 30 degrees Celsius, 25 degrees Celsius, 20 degrees Celsius, 15 degrees Celsius, 10 degrees Celsius, 5 degrees Celsius, 4 degrees Celsius, 3 degrees Celsius, 2 degrees Celsius, 1 degrees Celsius, or less.

In some cases, the organic portion of the precursor compound may decompose at a temperature that is higher than a decomposition temperature of the polymeric material. The decomposition temperature of the organic portion of the precursor compound may be higher than the decomposition temperature of the polymeric material by at least about 1 degree Celsius, 2 degrees Celsius, 3 degrees Celsius, 4 degrees Celsius, 5 degrees Celsius, 10 degrees Celsius, 15 degrees Celsius, 20 degrees Celsius, 25 degrees Celsius, 30 degrees Celsius, 35 degrees Celsius, 40 degrees Celsius, 45 degrees Celsius, 50 degrees Celsius, 60 degrees Celsius, 70 degrees Celsius, 80 degrees Celsius, 90 degrees Celsius, 100 degrees Celsius, 150 degrees Celsius, 200 degrees Celsius, 250 degrees Celsius, 300 degrees Celsius, 350 degrees Celsius, 400 degrees Celsius, 450 degrees Celsius, 500 degrees Celsius, or more. The decomposition temperature of the organic portion of the precursor compound may be higher than the decomposition temperature of the polymeric material by at most about 500 degrees Celsius, 450 degrees Celsius, 400 degrees Celsius, 350 degrees Celsius, 300 degrees Celsius, 250 degrees Celsius, 200 degrees Celsius, 150 degrees Celsius, 100 degrees Celsius, 90 degrees Celsius, 80 degrees Celsius, 70 degrees Celsius, 60 degrees Celsius, 50 degrees Celsius, 45 degrees Celsius, 40 degrees Celsius, 35 degrees Celsius, 30 degrees Celsius, 25 degrees Celsius, 20 degrees Celsius, 15 degrees Celsius, 10 degrees Celsius, 5 degrees Celsius, 4 degrees Celsius, 3 degrees Celsius, 2 degrees Celsius, 1 degrees Celsius, or less.

In some embodiments, a resin for 3D printing may be a mixture comprising an inert filler configured to decompose at a first temperature; a plurality of polymeric precursors configured to form a polymeric material, wherein the polymeric material is configured to decompose at a second temperature that is greater than the first temperature; a photoinitiator configured to initiate formation of the polymeric material from the plurality of polymeric precursors when exposed to photoradiation having a first wavelength; a photoinhibitor configured to inhibit formation of the polymeric material from the plurality of polymeric precursors when exposed to photoradiation having a second wavelength; and a plurality of soluble metal, ceramic, or cermet precursor compounds. The soluble metal, ceramic, or cermet precursor compound may be configured to react (e.g., break down) at the first temperature, the second temperature, or both to form metal, ceramic, or cermet nanoparticles.

Examples of soluble copper-containing compounds that may be added to feedstocks that include copper or copper alloy particles, which are used for making copper or copper alloy parts is given below in Table 1.

TABLE 1
Exemplary Copper Soluble Metal Compounds
for use in 3D Printing Resin

| Name | Structure |
|---|---|
| Copper (II) acetate | 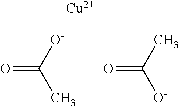 |
| Copper (II) D-gluconate | 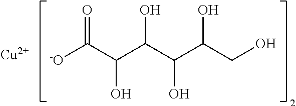 |
| Copper (II) tartrate hydrate | 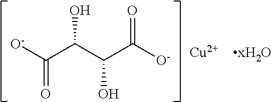 |
| Monobutyl Phthalate Copper (II) | 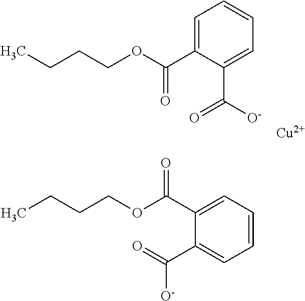 |
| Copper (II) tert- butylacetoacetate | 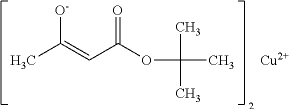 |
| Copper (II) 3,5- diisopropylsalicylate hydrate | 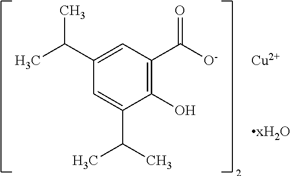 |
| Copper (II) cyclohexanebutyrate | 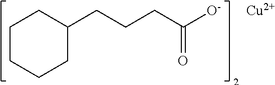 |
| Benzoic acid, copper (II) salt dehydrate | 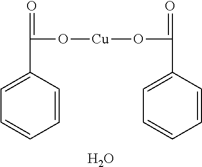 |

Other copper-containing compounds could include species that react with copper particles to form copper salts that could then go on to form copper nanoparticles during sintering (possible compounds include more noble metals e.g., silver salts, gold salts, platinum salts). For example, a salt of a metal more noble than copper can react with copper to form a copper salt with the more noble metal as a precipitate, e.g., silver salts react with copper to form copper salts and silver metal, as shown below:

2AgNO₃+Cu→Ag+Cu(NO₃)₂

Similarly-matched soluble compounds can be added to feedstocks that contain other metals, alloys, ceramics, and cermets.

Advantages of a number of ceramics can include high strength, high dimensional stability, and excellent chemical stability. Examples of useful ceramics that can be 3D printed include, but are not limited to, alumina, silica, zirconia, and silicon nitride. Soluble precursor compounds used to form nanoparticles of such ceramics can aid in subsequent sintering when added to feedstocks that include larger ceramic particles.

For example, for 3D printing of alumina, soluble aluminum precursor compounds such as aluminum diacetate hydroxide, aluminum sulfate, or aluminum potassium sulfate can be used along with alumina particles in the feedstock. After printing, when a green body is heated in an oxidative atmosphere during debinding and the soluble aluminum compounds form alumina nanoparticles on and between the larger alumina particles from the feedstock, which aids in densification during subsequent sintering.

In another example, silica-forming soluble compounds are numerous due to silicon's tetravalency and similar reactivity to carbon. Common examples of soluble organosilicons include tetramethylsilane and hexamethylcyclotrisiloxane. These compounds can be used along with silica particles in the feedstock. After printing, when the green body is heated in an oxidative atmosphere during debinding, silica-forming soluble compounds form silica nanoparticles on and between the larger silica particles from the feedstock, which aids in densification during subsequent sintering.

Once the at least the portion of the 3D object is printed (herein referred to as a green body), the method may further comprise removing the green body from the build head. In some cases, the green body may be separated from the build head by inserting a thin material (e.g. a steel blade) between the green body and the build head. In some cases, a first layer of the green body that is in contact with the build head may not comprise the plurality of particles for easy removal from the build head by the thin material. The method may further comprise washing the green body. In some cases, the green body may be washed by jetting a solvent (e.g., isopropanol) to remove any excess polymeric precursor.

A green body formed of a mixture comprising a plurality of precursor compounds and/or a plurality of particles (e.g., metal, ceramic, or both) of the present disclosure may be subjected to heating to remove at least a portion of organic material in the green body. The heating may be sufficient to degrade (or decompose) only a portion of the organic material in the green body to form a brown body. Alternatively, the heating may be sufficient to (i) degrade (or decompose) substantially all of the organic material in the green body and (ii) sinter the plurality of particles in the green body to form a desired 3D object. A first temperature sufficient for forming a brown body may be lower than a second temperature for sintering.

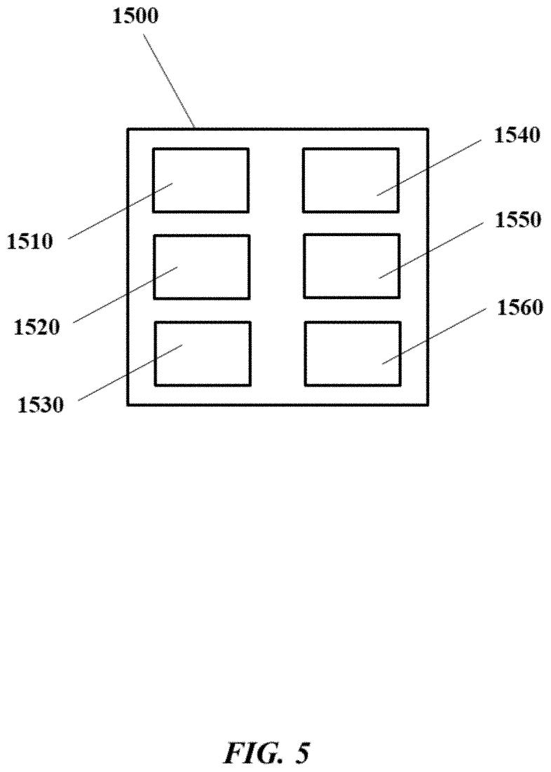

An example of a 3D printing mixture comprising a plurality of polymeric precursors is provided in FIG. 5.

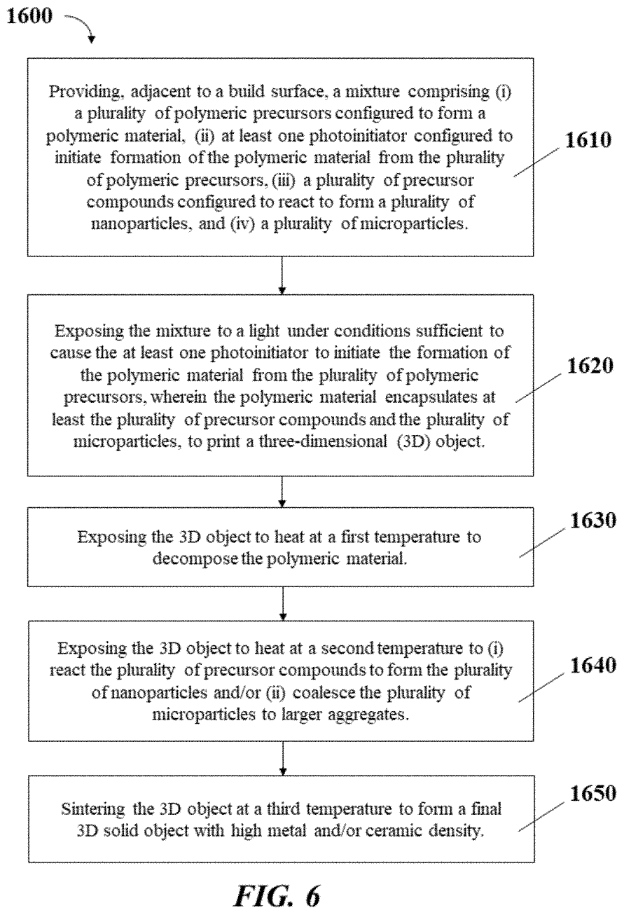

Another aspect of the present disclosure provides a method for printing a 3D object. FIG. 6 illustrates a flowchart 1600 of an example method for printing a 3D object. The method may comprise providing, adjacent to a build surface, a mixture comprising (i) a plurality of polymeric precursors configured to form a polymeric material, (ii) at least one photoinitiator configured to initiate formation of the polymeric material from the plurality of polymeric precursors, (iii) a plurality of precursor compounds configured to react to form a plurality of nanoparticles, and (iv) a plurality of microparticles (process 1610). The method may further comprise exposing the mixture to a light under conditions sufficient to cause the at least one photoinitiator to initiate the formation of the polymeric material from the plurality of polymeric precursors, wherein the polymeric material encapsulates at least the plurality of precursor compounds and the plurality of microparticles, to print a three-dimensional (3D) object (process 1620). The method may further comprise exposing the 3D object to heat at a first temperature to decompose the polymeric material (process 1630). The method may further comprise exposing the 3D object to heat at a second temperature to (i) react the plurality of precursor compounds to form the plurality of nanoparticles and/or (ii) coalesce the plurality of microparticles to larger aggregates (process 1640). The method may further comprise sintering the 3D object at a third temperature to form a final 3D solid object with high metal and/or ceramic density (process 1650)).

C. Other Components of the Mixture

The mixture of the present disclosure may further comprise a photoinhibitor. The photoinhibitor may be present in the mixture at an amount from about 0.001 wt. % to about 5 wt. %. The photoinhibitor may be present in the mixture at amount greater than or equal to about 0.001 wt. %, 0.002 wt. %, 0.003 wt. %, 0.004 wt. %, 0.005 wt. %, 0.006 wt. %, 0.007 wt. %, 0.008 wt. %, 0.009 wt. %, 0.01 wt. %, 0.02 wt. %, 0.03 wt. %, 0.04 wt. %, 0.05 wt. %, 0.1 wt. %, 0.5 wt. %, 1 wt. %, 5 wt. %, or more. The photoinhibitor may be present in the mixture at an amount less than or equal to about 5 wt. %, 1 wt. %, 0.5 wt. %, 0.1 wt. %, 0.05 wt. %, 0.04 wt. %, 0.03 wt. %, 0.02 wt. %, 0.01 wt. %, 0.009 wt. %, 0.008 wt. %, 0.007 wt. %, 0.006 wt. %, 0.005 wt. %, 0.004 wt. %, 0.003 wt. %, 0.002 wt. %, 0.001 wt. %, or less.

Some photoactivated radicals can preferentially terminate free radical polymerization, rather than initiating polymerizations, and the species that become such photoactivated radicals upon photoactivation may be used as photoinhibitors. In an example, ketyl radicals may terminate rather than initiate photopolymerizations. Most controlled radical polymerization techniques utilize a radical species that selectively terminates growing radical chains. Examples of such radical species include sulfanylthiocarbonyl and other radicals generated in photoiniferter (photo-initiator, transfer agent, and terminator) mediated polymerizations; sulfanylthiocarbonyl radicals used in reversible addition-fragmentation chain transfer polymerization; and nitrosyl radicals used in nitroxide mediate polymerization. In addition, lophyl radicals may be non-reactive towards the polymerization of acrylates in the absence of strong chain transfer agents. Other non-radical species that may be generated to terminate growing radical chains may include the numerous metal/ligand complexes used as deactivators in atom-transfer radical polymerization (ATRP). Non-limiting examples of the photoinhibitor include thiocarbamates, xanthates, dithiobenzoates, photoinititators that generate ketyl and other radicals that tend to terminate growing polymer chains radicals (i.e., camphorquinone and benzophenones), ATRP deactivators, and polymeric versions thereof.

In some cases, the photoinhibitor may comprise a hexaarylbiimidazole (HABI) or a functional variant thereof. In some cases, the hexaarylbiimidazole may comprise a phenyl group with a halogen and/or an alkoxy substitution. In an example, the phenyl group comprises an ortho-chloro-substitution. In another example, the phenyl group comprises an ortho-methoxy-substitution. In another example, the phenyl group comprises an ortho-ethoxy-substitution. Examples of the functional variants of the hexaarylbiimidazole include: 2,2′-Bis(2-chlorophenyl)-4, 4′,5,5′-tetraphenyl-1,2′-biimidazole; 2-(2-methoxyphenyl)-1-[2-(2-methoxyphenyl)-4,5-diphenyl-2H-imidazol-2-yl]-4,5-diphenyl-1H-imidazole; 2-(2-ethoxyphenyl)-1-[2-(2-ethoxyphenyl)-4,5-diphenyl-2H-imidazol-2-yl]-4,5-diphenyl-1H-imidazole; and 2,2′,4-tris-(2-Chlorophenyl)-5-(3,4-dimethoxyphenyl)-4′,5′-diphenyl-1,1′-biimidazole.

Other examples of the photoinhibitor in the mixture include one or more of: zinc dimethyl dithiocarbamate: zinc dimethyl dithiocarbamate; zinc diethyl dithiocarbamate; zinc dibutyl dithiocarbamate; nickel dibutyl dithiocarbamate; zinc dibenzyl dithiocarbamate; tetramethylthiuram disulfide; tetraethylthiuram disulfide (TEDS); tetramethylthiuram monosulfide; tetrabenzylthiuram disulfide; tetraisobutylthiuram disulfide; dipentamethylene thiuram hexasulfide; N,N′-dimethyl N,N′-di(4-pyridinyl)thiuram disulfide; 3-Butenyl 2-(dodecylthiocarbonothioylthio)-2-methylpropionate; 4-Cyano-4-[(dodecylsulfanylthiocarbonyl)sulfanyl]pentanoic acid; 4-Cyano-4-[(dodecylsulfanylthiocarbonyl)sulfanyl]pentanol; Cyanomethyl dodecyl trithiocarbonate; Cyanomethyl [3-(trimethoxysilyl)propyl] trithiocarbonate; 2-Cyano-2-propyl dodecyl trithiocarbonate; S,S-Dibenzyl trithiocarbonate; 2-(Dodecylthiocarbonothioylthio)-2-methylpropionic acid; 2-(Dodecylthiocarbonothioylthio)-2-methylpropionic acid N-hydroxysuccinimide; Benzyl 1H-pyrrole-1-carbodithioate; Cyanomethyl diphenylcarbamodithioate; Cyanomethyl methyl(phenyl)carbamodithioate; Cyanomethyl methyl(4-pyridyl)carbamodithioate; 2-Cyanopropan-2-yl N-methyl-N-(pyridin-4-yl)carbamodithioate; Methyl 2-[methyl(4-pyridinyl)carbamothioylthio]propionate; 1-Succinimidyl-4-cyano-4-[N-methyl-N-(4-pyridyl)carbamothioylthio]pentanoate; Benzyl benzodithioate; Cyanomethyl benzodithioate; 4-Cyano-4-(phenylcarbonothioylthio)pentanoic acid; 4-Cyano-4-(phenylcarbonothioylthio)pentanoic acid N-succinimidyl ester; 2-Cyano-2-propyl benzodithioate; 2-Cyano-2-propyl 4-cyanobenzodithioate; Ethyl 2-(4-methoxyphenylcarbonothioylthio)acetate; 2-Phenyl-2-propyl benzodithioate; Cyanomethyl methyl(4-pyridyl)carbamodithioate; 2-Cyanopropan-2-yl N-methyl-N-(pyridin-4-yl)carbamodithioate; Methyl 24methyl(4-pyridinyl)carbamothioylthio]propionate; 1,1′-Bi-1H-imidazole; and functional variants thereof.

For photoinhibition to occur during the 3D printing, the amount of the photoinhibitor in the mixture may be sufficient to generate inhibiting radicals at a greater rate that initiating radicals are generated. The ratio of the amount of the photoinhibitor and/or the photoinitiator may be modified based on the intensity of the optical sources available, and/or the quantum yields and light absorption properties of the photoinhibitor and the photoinitiator in the mixture.

The mixture of the present disclosure may further comprise a photoinitiator. A photoinitiator may be present in the mixture at an amount from about 0.001 wt. % to about 5 wt. %. The photoinitiator may be present in the mixture at an amount greater than or equal to about 0.001 wt. %, 0.002 wt. %, 0.003 wt. %, 0.004 wt. %, 0.005 wt. %, 0.006 wt. %, 0.007 wt. %, 0.008 wt. %, 0.009 wt. %, 0.01 wt. %, 0.02 wt. %, 0.03 wt. %, 0.04 wt. %, 0.05 wt. %, 0.1 wt. %, 0.5 wt. %, 1 wt. %, 5 wt. %, or more. The photoinitiator may be present in the mixture at an amount less than or equal to about 5 wt. %, 1 wt. %, 0.5 wt. %, 0.1 wt. %, 0.05 wt. %, 0.04 wt. %, 0.03 wt. %, 0.02 wt. %, 0.01 wt. %, 0.009 wt. %, 0.008 wt. %, 0.007 wt. %, 0.006 wt. %, 0.005 wt. %, 0.004 wt. %, 0.003 wt. %, 0.002 wt. %, 0.001 wt. %, or less.

The photoinitiator may be selected to absorb little (e.g., less than or equal to about 10%, 5%, 4%, 3%, 2%, 1%, 0.1%, or less) or no light at the one or more wavelengths used to activate the photoinhibitor. In some cases, some overlap of the light absorption spectra of the photoinitiator and the photoinhibitor may be tolerated depending on the relative reaction rates (e.g., the figure of merit described above). Suitable photoinitiators include one or more of benzophenones, thioxanthones, anthraquinones, benzoylformate esters, hydroxyacetophenones, alkylaminoacetophenones, benzil ketals, dialkoxyacetophenones, benzoin ethers, phosphine oxides, acyloximino esters, alphahaloacetophenones, trichloromethyl-S-triazines, titanocenes, dibenzylidene ketones, ketocoumarins, dye sensitized photoinitiation systems, maleimides, and functional variants thereof. In some cases, the photoinitiator may comprise camphorquinone (CQ) and/or a functional variant thereof.

Example families of useful photoinitators include: hydroxyacetophenones, alkylaminoacetonphenones, benzil ketals, dialkoxyacetophenones, benzoin ethers, phosphine oxides, acyloximino esters, alphahaloacetophenones, benzophenones, thioxanthones, anthraquinones, camphorquinones, ketocoumarins, and curcumin derivatives. Examples of the photoinitiator in the mixture include one or more of: 1-hydroxy-cyclohexyl-phenyl-ketone (Irgacure™ 184; BASF, Hawthorne, N.J.); a 1:1 mixture of 1-hydroxy-cyclohexyl-phenyl-ketone and benzophenone (Irgacure™ 500; BASF); 2-hydroxy-2-methyl-1-phenyl-1-propanone (Darocur™ 1173; BASF); 2-hydroxy-1-[4-(2-hydroxyethoxy)phenyl]-2-methyl-1-propanone (Irgacure™ 2959; BASF); methyl benzoylformate (Darocur™ MBF; BASF); oxy-phenyl-acetic acid 2-[2-oxo-2-phenyl-acetoxy-ethoxy]-ethyl ester; oxy-phenyl-acetic 2-[2-hydroxy-ethoxy]-ethyl ester; a mixture of oxy-phenyl-acetic acid 2-[2-oxo-2-phenyl-acetoxy-ethoxy]-ethyl ester and oxy-phenyl-acetic 2[2-hydroxy-ethoxy]-ethyl ester (Irgacure™ 754; BASF); alpha,alpha-dimethoxy-alpha-phenylacetophenone (Irgacure™ 651; BASF); 2-benzyl-2-(dimethylamino)-144-(4-morpholinyl)-phenyl]-1-butanone (Irgacure™ 369; BASF); 2-methyl-1[4-(methylthio)phenyl]-2-(4-morpholinyl)-1-propanone (Irgacure™ 907; BASF); a 3:7 mixture of 2-benzyl-2-(dimethylamino)-1-[4-(4-morpholinyl) phenyl]-1-butanone and alpha,alpha-dimethoxy-alpha-phenylacetophenone per weight (Irgacure™ 1300; BASF); diphenyl-(2,4,6-trimethylbenzoyl) phosphine oxide (Darocur™ TPO; BASF); a 1:1 mixture of diphenyl-(2,4,6-trimethylbenzoyl)-phosphine oxide and 2-hydroxy-2-methyl-1-phenyl-1-propanone (Darocur™ 4265; BASF); phenyl bis(2,4,6-trimethyl benzoyl) phosphine oxide, which may be used in pure form (Irgacure™ 819; BASF, Hawthorne, N.J.) or dispersed in water (45% active, Irgacure™ 819DW; BASF); 2:8 mixture of phosphine oxide, phenyl bis(2,4,6-trimethyl benzoyl) and 2-hydroxy-2-methyl-1-phenyl-1-propanone (Irgacure™ 2022; BASF); Irgacure™ 2100, which comprises phenyl-bis(2,4,6-trimethylbenzoyl)-phosphine oxide); bis-(eta 5-2,4-cyclopentadien-1-yl)-bis-[2,6-difluoro-3-(1H-pyrrol-1-yl) phenyl]-titanium (Irgacure™ 784; BASF); (4-methylphenyl) [4-(2-methylpropyl) phenyl]-iodonium hexafluorophosphate (Irgacure™ 250; BASF); 2-(4-methylbenzyl)-2-(dimethylamino)-1-(4-morpholinophenyl)-butan-1-one (Irgacure™ 379; BASF); 4-(2-hydroxyethoxy)phenyl-(2-hydroxy-2-propyl)ketone (Irgacure™ 2959; BASF); bis-(2,6-dimethoxybenzoyl)-2,4,4-trimethylpentylphosphine oxide; a mixture of bis-(2,6-dimethoxybenzoyl)-2,4,4-trimethylpentylphosphine oxide and 2 hydroxy-2-methyl-1-phenyl-propanone (Irgacure™ 1700; BASF); 4-Isopropyl-9-thioxanthenone; Bis[4-(dimethylamino)phenyl]methanone; Bis[4-(diethylamino)phenyl]methanone; and functional variants thereof.

The mixture of the present disclosure may further comprise a stabilizer. The stabilizer may be configured to inhibit formation of the polymeric material from at least a portion of the polymeric precursor. The stabilizer may be present in the mixture at an amount from about 0.0001 wt. % to about 0.5 wt. %. The stabilizer may be present in the mixture at an amount greater than or equal to about 0.0001 wt. %, 0.0002 wt. %, 0.0003 wt. %, 0.0004 wt. %, 0.0005 wt. %, 0.0006 wt. %, 0.0007 wt. %, 0.0008 wt. %, 0.0009 wt. %, 0.001 wt. %, 0.002 wt. %, 0.003 wt. %, 0.004 wt. %, 0.005 wt. %, 0.01 wt. %, 0.05 wt. %, 0.1 wt. %, 0.5 wt. %, or more. The stabilizer may be present in the mixture at an amount less than or equal to about 0.5 wt. %, 0.1 wt. %, 0.05 wt. %, 0.01 wt. %, 0.005 wt. %, 0.004 wt. %, 0.003 wt. %, 0.002 wt. %, 0.001 wt. %, 0.0009 wt. %, 0.0008 wt. %, 0.0007 wt. %, 0.0006 wt. %, 0.0005 wt. %, 0.0004 wt. %, 0.0003 wt. %, 0.0002 wt. %, 0.0001 wt. %, or less.

The presence of the stabilizer in the mixture may increase the critical energy of the light for the mixture. In some cases, the stabilizer may be a radical inhibitor. Examples of the radical inhibitor include a quinone, hydroquinoe, nitrosamine, copper-comprising compound, stable free radical (e.g., (2,2,6,6-tetramethylpiperidin-1-yl)oxidanyl), substituted phenol, mequinol, t-butyl catechol, Nitorosophenylhydroxylamine alminium salt, functional variants thereof, or mixtures thereof. In some examples, the radical inhibitor may comprise phenothiazine, copper napthalate, butylated hydroxytoluene, or functional variants thereof. The radical inhibitor may be added to the polymeric precursor (e.g., acrylate monomers) as stabilizers to prevent premature curing (e.g., polymerization, cross-linking) during handling prior to 3D printing. In some cases, in at least a portion of the mixture that is exposed to the second light (photoinhibition light), formation of the polymeric material from the polymeric precursors may not begin until most if not all of the photoinhibitors are activated and consumed (e.g., by initiating radicals) in the at least the portion of the mixture. Depending on steric, electronic, and/or mechanistic properties of the stabilizer (e.g., the radical inhibitor), the effect of the stabilizer on the critical energy of the photoinitiation light or the photoinhibition light may be different. In some cases, the addition of the stabilizer to the mixture may disproportionally increase the critical energy of the photoinhibition light for the mixture relative to the critical energy of the photoinitiation light for the mixture. In some cases, the addition of the stabilizer to the mixture may disproportionally increase the critical energy of the photoinitiation light for the mixture relative to the critical energy of the photoinhibition light for the mixture.

The mixture of the present disclosure may further comprise a co-initiator. A co-initiator may be configured to initiate formation of the polymeric material from the polymeric precursor. In some cases, the co-initiator is present in the mixture at an amount from about 0.01 wt. % to about 10 wt. %. The co-initiator may be present in the mixture at an amount greater than or equal to about 0.01 wt. %, 0.02 wt. %, 0.03 wt. %, 0.04 wt. %, 0.05 wt. %, 0.06 wt. %, 0.07 wt. %, 0.08 wt. %, 0.09 wt. %, 0.1 wt. %, 0.2 wt. %, 0.3 wt. %, 0.4 wt. %, 0.5 wt. %, 1 wt. %, 2 wt. %, 3 wt. %, 4 wt. %, 5 wt. %, 6 wt. %, 7 wt. %, 8 wt. %, 9 wt. %, 10 wt. %, or more. The co-initiator may be present in the mixture at an amount less than or equal to about 10 wt. %, 9 wt. %, 8 wt. %, 7 wt. %, 6 wt. %, 5 wt. %, 4 wt. %, 3 wt. %, 2 wt. %, 1 wt. %, 0.5 wt. %, 0.4 wt. %, 0.3 wt. %, 0.2 wt. %, 0.1 wt. %, 0.09 wt. %, 0.08 wt. %, 0.07 wt. %, 0.06 wt. %, 0.05 wt. %, 0.04 wt. %, 0.03 wt. %, 0.02 wt. %, 0.01 wt. %, or less. In other instances, the co-initiator configured to initiate formation of the polymeric material comprises one or more functional groups that act as a co-initiator. The one or more functional groups may be diluted by being attached to a larger molecule. In such cases, the co-initiator may be present in the mixture at an amount greater than or equal to about 0.01 wt. %, 0.02 wt. %, 0.03 wt. %, 0.04 wt. %, 0.05 wt. %, 0.06 wt. %, 0.07 wt. %, 0.08 wt. %, 0.09 wt. %, 0.1 wt. %, 0.2 wt. %, 0.3 wt. %, 0.4 wt. %, 0.5 wt. %, 1 wt. %, 2 wt. %, 3 wt. %, 4 wt. %, 5 wt. %, 6 wt. %, 7 wt. %, 8 wt. %, 9 wt. %, 10 wt. %, 11 wt. %, 12 wt. %, 13 wt. %, 14 wt. %, 15 wt. %, 16 wt. %, 17 wt. %, 18 wt. %, 19 wt. %, 20 wt. %, 21 wt. %, 22 wt. %, 23 wt. %, 24 wt. %, 25 wt. %, or more. The co-initiator may be present in the mixture at an amount less than or equal to about 25 wt. %, 24 wt. %, 23 wt. %, 22 wt. %, 21 wt. %, 20 wt. %, 19 wt. %, 18 wt. %, 17 wt. %, 16 wt. %, 15 wt. %, 14 wt. %, 13 wt. %, 12 wt. %, 11 wt. %, 10 wt. %, 9 wt. %, 8 wt. %, 7 wt. %, 6 wt. %, 5 wt. %, 4 wt. %, 3 wt. %, 2 wt. %, 1 wt. %, 0.5 wt. %, 0.4 wt. %, 0.3 wt. %, 0.2 wt. %, 0.1 wt. %, 0.09 wt. %, 0.08 wt. %, 0.07 wt. %, 0.06 wt. %, 0.05 wt. %, 0.04 wt. %, 0.03 wt. %, 0.02 wt. %, 0.01 wt. %, or less.

The co-initiator in the mixture may enhance the rate of formation of the polymeric material from the polymeric precursor. The co-initiator may comprise primary, secondary, and tertiary amines, alcohols, and thiols. In some cases, the co-initiator may comprise a tertiary amine. In some cases, the co-initiator may comprise ethyl-dimethyl-amino benzoate (EDMAB) or a functional variant thereof. Additional examples of the co-initiator include one or more of: isoamyl 4-(dimethylamino)benzoate, 2-ethylhexyl 4-(dimethylamino)benzoate; ethyl 4-(dimethylamino)benzoate; 3-(dimethylamino)propyl acrylate; 2-(dimethylamino)ethyl methacrylate; 4-(dimethylamino)benzophenones, 4-(diethylamino)benzophenones; 4,4-Bis(diethylamino)benzophenones; methyl diethanolamine; triethylamine; hexane thiol; heptane thiol; octane thiol; nonane thiol; decane thiol; undecane thiol; dodecane thiol; isooctyl 3-mercaptopropionate; pentaerythritol tetrakis(3-mercaptopropionate); 4,4--thiobisbenzenethiol; trimethylolpropane tris(3-mercaptopropionate); CN374 (Sartomer); CN371 (Sartomer), CN373 (Sartomer), Genomer 5142 (Rahn); Genomer 5161 (Rahn); Genomer(5271 (Rahn); Genomer 5275 (Rahn), TEMPIC (Bruno Boc, Germany), and functional variants thereof.

Alternatively or in addition to, performance of a photoinitiator can also be improved through the addition of a sensitizing dye. Examples of the sensitizing dye may include, but are not limited to, eosin, cyanine, acridinium, flavine, xanthene, thiazine based dyes, functional variants thereof, and combinations thereof.

The mixture of the present disclosure may further comprise a light absorber. The light may be configured to absorb at least the first wavelength of the first light or the second wavelength of the second light. In some cases, the light absorber is present in the mixture at an amount from about 0.001 wt. % to about 5 wt. %. The light absorber may be present in the mixture at amount greater than or equal to about 0.001 wt. %, 0.002 wt. %, 0.003 wt. %, 0.004 wt. %, 0.005 wt. %, 0.006 wt. %, 0.007 wt. %, 0.008 wt. %, 0.009 wt. %, 0.01 wt. %, 0.02 wt. %, 0.03 wt. %, 0.04 wt. %, 0.05 wt. %, 0.1 wt. %, 0.5 wt. %, 1 wt. %, 5 wt. %, or more. The light absorber may be present in the mixture at an amount less than or equal to about 5 wt. %, 1 wt. %, 0.5 wt. %, 0.1 wt. %, 0.05 wt. %, 0.04 wt. %, 0.03 wt. %, 0.02 wt. %, 0.01 wt. %, 0.009 wt. %, 0.008 wt. %, 0.007 wt. %, 0.006 wt. %, 0.005 wt. %, 0.004 wt. %, 0.003 wt. %, 0.002 wt. %, 0.001 wt. %, or less.

In some cases, the light absorber may be a dye or pigment. The light absorber can be used to both attenuate light and to transfer energy (e.g., via Förster resonance energy transfer (FRET)) to photoactive species (e.g., the photoinitiator or the photoinhibitor), thereby to increase the sensitivity of the resulting mixture to a given wavelength suitable for the photoinitiation and/or the photoinhibition process. A concentration of the light absorber may be highly dependent on the light absorption properties of the light absorber, as well as the optical attenuation from other components in the mixtures. In an example, the light absorber may be configured to absorb at the second wavelength, and exposing the mixture to the second light having the second wavelength may initiate the light absorber to reduce an amount of the second light exposed to at least a portion of the mixture. One or more light absorbers may be combined at a plurality of concentrations to restrict the penetration of the photoinhibition light to a given thickness such that the photoinhibition layer is thick enough to permit separation of the newly formed layer of the 3D object from the print surface (e.g., the window). The one or more light absorbers may be combined at the plurality of concentrations to restrict penetration and/or propagation of the photoinitiating light during printing at least a portion of the 3D object. In some cases, a plurality of light absorbers may be used to independently control both photoinhibition and photoinitiation processes.

Examples of the light absorber include compounds commonly used as UV absorbers for decreasing weathering of coatings, such as: 2-hydroxyphenyl-benzophenones; 2-(2-hydroxyphenyl)-benzotriazoles(and chlorinated derivatives); and 2-hydroxyphenyl-s-triazines. Additional examples of the light absorber include those used for histological staining or dying of fabrics. Pigments such as carbon black, pthalocyanine, toluidine red, quinacridone, titanium dioxide, and functional variants thereof may also be used as light absorbers in the mixture. Dyes that may be used as light absorbers include: Martius yellow; quinolone yellow; Sudan red, Sudan I, Sudan IV, eosin, eosin Y, neutral red, acid red, Sun Chemical UVDS 150; Sun Chemical UVDS 350; Penn Color Cyan; Sun Chemical UVDJ107; 2-tert-Butyl-6-(5-chloro-2H-benzotriazol-2-yl)-4-methylphenol; 2-(2H-Benzotriazol-2-yl)-4,6-di-tert-pentylphenol; 7-diethylamino-4-methyl coumarin; 9,10-Dibutoxyanthracene; 9-phenyl acridine; and functional variants thereof.

A polymeric precursor of the mixture of the present disclosure may comprise monomers, one or more oligomers, or both. The monomers may be configured to polymerize to form the polymeric material. The one or more oligomers may be configured to cross-link to form the polymeric material. The monomers may be of the same or different types. An oligomer may comprise two or more monomers that are covalently linked to each other. The oligomer may be of any length, such as greater than or equal to about 2 (dimer), 3 (trimer), 4 (tetramer), 5 (pentamer), 6 (hexamer), 7, 8, 9, 10, 20, 30, 40, 50, 100, 200, 300, 400, 500, or more monomers. As an alternative, the oligomer may be of a length less than or equal to about 500, 400, 300, 200, 100, 50, 40, 30, 20, 10, 9, 8, 7, 6, 5, 4, 3, 2, or less monomers. Alternatively or in addition to, the polymeric precursor may include a dendritic precursor (monodisperse or polydisperse). The dendritic precursor may be a first generation (G1), second generation (G2), third generation (G3), fourth generation (G4), or higher with functional groups remaining on the surface of the dendritic precursor. The resulting polymeric material may comprise a monopolymer and/or a copolymer. The copolymer may be a linear copolymer or a branched copolymer. The copolymer may be an alternating copolymer, periodic copolymer, statistical copolymer, random copolymer, and/or block copolymer. In some cases, the polymeric precursor (e.g., monomer, oligomer, or both) may comprise one or more acrylates.

In some cases, the monomers is present in the mixture at an amount from about 1 wt. % to about 80 wt. %. The monomers may be present in the mixture at an amount greater than or equal to about 1 wt. %, 2 wt. %, 3 wt. %, 4 wt. %, 5 wt. %, 6 wt. %, 7 wt. %, 8 wt. %, 9 wt. %, 10 wt. %, 15 wt. %, 20 wt. %, 25 wt. %, 30 wt. %, 35 wt. %, 40 wt. %, 45 wt. %, 50 wt. %, 55 wt. %, 60 wt. %, 65 wt. %, 70 wt. %, 75 wt. %, 80 wt. %, or more. The monomers may be present in the mixture at an amount less than or equal to about 80 wt. %, 75 wt. %, 70 wt. %, 65 wt. %, 60 wt. %, 55 wt. %, 50 wt. %, 45 wt. %, 40 wt. %, 35 wt. %, 30 wt. %, 25 wt. %, 20 wt. %, 15 wt. %, 10 wt. %, 9 wt. %, 8 wt. %, 7 wt. %, 6 wt. %, 5 wt. %, 4 wt. %, 3 wt. %, 2 wt. %, 1 wt. %, or less. In some cases, the mixture may not have any monomers. In such a scenario, the mixture may have one or more oligomers.

Examples of monomers include one or more of hydroxyethyl methacrylate; n-Lauryl acrylate; tetrahydrofurfuryl methacrylate; 2, 2, 2-trifluoroethyl methacrylate; isobornyl methacrylate; polypropylene glycol monomethacrylates, aliphatic urethane acrylate (i.e., Rahn Genomer 1122); hydroxyethyl acrylate; n-Lauryl methacrylate; tetrahydrofurfuryl acrylate; 2, 2, 2-trifluoroethyl acrylate; isobornyl acrylate; polypropylene glycol monoacrylates; trimethylpropane triacrylate; trimethylpropane trimethacrylate; pentaerythritol triacrylate; pentaerythritol tetraacrylate; ethoxylated pentaerythritol tetraacrylate; ethoxylated pentaerythritol triacrylate; dipentaerythritol pentacrylate; dipentaerythritol hexacrylate; triethyleneglycol diacrylate; triethylene glycol dimethacrylate; tetrathyleneglycol diacrylate; tetrathylene glycol dimethacrylate; neopentyldimethacrylate; neopentylacrylate; hexane diol dimethacylate; hexane diol diacrylate; polyethylene glycol 400 dimethacrylate; polyethylene glycol 400 diacrylate; diethylglycol diacrylate; diethylene glycol dimethacrylate; ethyleneglycol diacrylate; ethylene glycol dimethacrylate; ethoxylated bis phenol A dimethacrylate; ethoxylated bis phenol A diacrylate; bisphenol A glycidyl methacrylate; bisphenol A glycidyl acrylate; ditrimethylolpropane tetraacrylate; and functional variants thereof. In some cases, the monomers may comprise (i) tricyclodecanediol diacrylate, tricyclodecanediol dimethacrylate, or a functional variant thereof, (ii) tris(2-hydroxy ethyl) isocyanurate triacrylate or a functional variant thereof, or (iii) phenoxy ethyl acrylate or a functional variant thereof. In some cases, one or more monomers provided in the present disclosure may be ethoxylated. In some cases, the one or more monomers may be ethoxylated and then functionalized to generate one or more functional variants, e.g., ethoxylated(4) pentaerythritol acrylate.

In some cases, the one or more oligomers is present in the mixture at an amount from about 1 wt. % to about 30 wt. %. The one or more oligomers may be present in the mixture at an amount greater than or equal to about 1 wt. %, 2 wt. %, 3 wt. %, 4 wt. %, 5 wt. %, 6 wt. %, 7 wt. %, 8 wt. %, 9 wt. %, 10 wt. %, 15 wt. %, 20 wt. %, 25 wt. %, 30 wt. %, or more. The one or more oligomers may be present in the mixture at an amount less than or equal to about 30 wt. %, 25 wt. %, 20 wt. %, 15 wt. %, 10 wt. %, 9 wt. %, 8 wt. %, 7 wt. %, 6 wt. %, 5 wt. %, 4 wt. %, 3 wt. %, 2 wt. %, 1 wt. %, or less. In some cases, the mixture may not have the one or more oligomers. In such a scenario, the mixture may have the monomers.

In some cases, the one or more oligomers may include one or more of: polyether; polyol; epoxy; thioether; polyester; urethane; silicon; polybutadiene; phenolic based acrylates; methacrylates; and functional variants thereof. In some cases, the one or more oligomers may comprise one or more (meth)acrylate monomers from: urethane (meth)acrylate, polyester urethane (meth)acrylate, epoxy(meth)acrylate, polyether (meth)acrylate, polyol (meth)acrylate, dendritic (meth)acrylate, silicone (meth)acrylate, polybutadiene (meth)acrylate, phenolic (meth)acrylate, or a functional variant thereof. Additional examples of the one or more oligomers include Esstech Exothane 126, Esstech Exothane 108, and Sartomer CN9009.

In some embodiments of any of the mixtures disclosed herein, polymeric precursors of the mixture may include acrylates, methacrylates, epoxides, lactones, styrenics, and acrylamides. Polymers formed from such polymeric precursors include, but are not limited to, polyacrylates, polymethacrylates, polyethers, polylactones, polystyrenes, or polyacrylamides.

In some embodiments of any of the mixtures disclosed herein, photoinhibitors of the mixture may include thiocarbamates, xanthates, dithiobenzoates, hexaarylbiimidazoles, photoinititators that generate ketyl and other radicals that tend to terminate growing polymer chains radicals (i.e., camphorquinone and benzophenones), ATRP deactivators, or polymeric versions thereof.

In some embodiments of any of the mixtures disclosed herein, the mixture may comprise inert fillers. Suitable inert fillers include, but are not limited to, polyethylene waxes, polypropylene, polystyrene, polyalphamethylstyrene, polycarbonate, polyethyleneoxide, polypropyleneoxide, or copolymers thereof.

A ratio of the monomers and the one or more oligomers in the polymeric precursor of the mixture may be based on one or more properties of the mixture (e.g., viscosity, curing rate, etc.) that is optimal for each particular 3D printing method. In an example, in the absence of inorganic particles (e.g., metal or ceramic particles) in the mixture, the ratio of the monomer and the one or more oligomers may be optimized to yield a viscosity below 3000 centipoise (cP). In some cases, the viscosity of the mixture may be below 300 cP. In some cases, the viscosity of the mixture is less than or equal to about 3000 cP, 2900 cP, 2800 cP, 2700 cP, 2600 cP, 2500 cP, 2400 cP, 2300 cP, 2200 cP, 2100 cP, 2000 cP, 1500 cP, 1000 cP, 500 cP, 100 cP, or less. As an alternative, the viscosity of the mixture may be greater than or equal to about 100 cP, 500 cP, 1000 cP, 1500 cP, 2000 cP, 2100 cP, 2200 cP, 2300 cP, 2400 cP, 2500 cP, 2600 cP, 2700 cP, 2800 cP, 2900 cP, 3000 cP, or more.

When the mixture comprises one or more particles (e.g., granulated and/or non-granulated particles), the mixture may have a viscosity ranging from about 4,000 cP to about 2,000,000 cP. When the mixture comprises the one or more particles, the mixture may have a viscosity greater than or equal to about 4,000 cP, 10,000 cP, 20,000 cP, 30,000 cP, 40,000 cP, 50,000 cP, 60,000 cP, 70,000 cP, 80,000 cP, 90,000 cP, 100,000 cP, 200,000 cP, 300,000 cP, 400,000 cP, 500,000 cP, 600,000 cP, 700,000 cP, 800,000 cP, 900,000 cP, 1,000,000 cP, 2,000,000 cP, or more. When the mixture comprises the one or more particles, the mixture may have a viscosity less than or equal to about 2,000,000 cP, 1,000,000 cP, 900,000 cP, 800,000 cP, 700,000 cP, 600,000 cP, 500,000 cP, 400,000 cP, 300,000 cP, 200,000 cP, 100,000 cP, 90,000 cP, 80,000 cP, 70,000 cP, 60,000 cP, 50,000 cP, 40,000 cP, 30,000 cP, 20,000 cP, 10,000 cP, 4,000 cP, or less.

D. Debinding and Sintering

Any of the methods disclosed herein may further comprise subjecting a printed 3D object (e.g., a green body) to heating (e.g., in a furnace) to, for example, heat a plurality of particles in the mixture. In some embodiments, the plurality of particles may be granulated particles, as provided herein. Alternatively or in addition to, the plurality of particles may comprise nanoparticles formed from reaction of a plurality of precursor compounds. The heating may be under conditions sufficient to sinter the plurality of particles to form a final product that is at least a portion of a 3D object or an entire 3D object. During heating (e.g., sintering), the organic components (e.g., the polymeric material, additives, etc.) may decompose and leave the green body. At least a portion of the decomposed organic components may leave the green body in gas phase.

The green body may be heated in a processing chamber. The temperature of the processing temperature may be regulated with at least one heater. The processing chamber may be an oven or a furnace. The oven or furnace may be heated with various heating approaches, such as resistive heating, convective heating and/or radiative heating. Examples of the furnace include an induction furnace, electric arc furnace, gas-fired furnace, plasma arc furnace, microwave furnace, and electric resistance furnace. Such heating may be employed at a fixed or variating heating rate from an initial temperature to a target temperature or temperature range.

A green body comprising metallic and/or intermetallic particles may be heated from room temperature to a processing temperature. The processing temperature may be kept constant or substantially constant for a given period of time, or may be adjusted to one or more other temperatures. The processing temperature may be selected based on the material of the particles in the green body (e.g., the processing temperature may be higher for material having a higher melting point than other materials). The processing temperature may be sufficient to sinter but not completely melt the particles in the green body. As an alternative, the processing temperature may be sufficient to melt the particles in the green body.

The processing temperature for heating (e.g., sintering) the green body (including the metal and/or intermetallic particles) may range between about 300 degrees Celsius to about 2200 degrees Celsius. The processing temperature for sintering the green body may be at least about 300 degrees Celsius, 350 degrees Celsius, 400 degrees Celsius, 450 degrees Celsius, 500 degrees Celsius, 550 degrees Celsius, 600 degrees Celsius, 650 degrees Celsius, 700 degrees Celsius, 750 degrees Celsius, 800 degrees Celsius, 850 degrees Celsius, 900 degrees Celsius, 950 degrees Celsius, 1000 degrees Celsius, 1050 degrees Celsius, 1100 degrees Celsius, 1150 degrees Celsius, 1200 degrees Celsius, 1250 degrees Celsius, 1300 degrees Celsius, 1350 degrees Celsius, 1400 degrees Celsius, 1450 degrees Celsius, 1500 degrees Celsius, 1550 degrees Celsius, 1600 degrees Celsius, 1700 degrees Celsius, 1800 degrees Celsius, 1900 degrees Celsius, 2000 degrees Celsius, 2100 degrees Celsius, 2200 degrees Celsius, or more. The processing temperature for sintering the green body (including the particles) may be at most about 2200 degrees Celsius, 2100 degrees Celsius, 2000 degrees Celsius, 1900 degrees Celsius, 1800 degrees Celsius, 1700 degrees Celsius, 1600 degrees Celsius, 1550 degrees Celsius, 1500 degrees Celsius, 1450 degrees Celsius, 1400 degrees Celsius, 1350 degrees Celsius, 1300 degrees Celsius, 1250 degrees Celsius, 1200 degrees Celsius, 1150 degrees Celsius, 1100 degrees Celsius, 1050 degrees Celsius, 1000 degrees Celsius, 950 degrees Celsius, 900 degrees Celsius, 850 degrees Celsius, 800 degrees Celsius, 750 degrees Celsius, 700 degrees Celsius, 650 degrees Celsius, 600 degrees Celsius, 550 degrees Celsius, 500 degrees Celsius, 450 degrees Celsius, 400 degrees Celsius, 350 degrees Celsius, 300 degrees Celsius, or less.

In an example, a green body comprising aluminum particles may be heated from room temperature to a processing temperature ranging between about 350 degrees Celsius to about 700 degrees Celsius. In another example, a green body comprising copper particles may be heated from room temperature to a processing temperature of about 1000 degrees Celsius. In another example, a green body comprising stainless steel particles may be heated from room temperature to a processing temperature ranging between about 1200 degrees Celsius to about 1500 degrees Celsius. In another example, a green body comprising other tool steel particles may be heated from room temperature to a processing temperature of about 1250 degrees Celsius. In another example, a green body comprising tungsten heavy alloy particles may be heated from room temperature to a processing temperature of about 1500 degrees Celsius.

During sintering the green body comprising the metallic and/or intermetallic particles, the temperature of the processing chamber may change at a rate ranging between about 0.1 degrees Celsius per minute (degrees Celsius/min) to about 200 degrees Celsius/min. The temperature of the processing chamber may change at a rate of at least about 0.1 degrees Celsius/min, 0.2 degrees Celsius/min, 0.3 degrees Celsius/min, 0.4 degrees Celsius/min, 0.5 degrees Celsius/min, 1 degrees Celsius/min, 2 degrees Celsius/min, 3 degrees Celsius/min, 4 degrees Celsius/min, 5 degrees Celsius/min, 6 degrees Celsius/min, 7 degrees Celsius/min, 8 degrees Celsius/min, 9 degrees Celsius/min, 10 degrees Celsius/min, 20 degrees Celsius/min, 50 degrees Celsius/min, 100 degrees Celsius/min, 150 degrees Celsius/min, 200 degrees Celsius/min, or more. The temperature of the processing chamber may change at a rate of at most about 200 degrees Celsius/min, 150 degrees Celsius/min, 100 degrees Celsius/min, 50 degrees Celsius/min, 20 degrees Celsius/min, 10 degrees Celsius/min, 9 degrees Celsius/min, 8 degrees Celsius/min, 7 degrees Celsius/min, 6 degrees Celsius/min, 5 degrees Celsius/min, 4 degrees Celsius/min, 3 degrees Celsius/min, 2 degrees Celsius/min, 1 degrees Celsius/min, 0.5 degrees Celsius/min, 0.4 degrees Celsius/min, 0.3 degrees Celsius/min, 0.2 degrees Celsius/min, 0.1 degrees Celsius/min, or less.

In some cases, during sintering the green body comprising the metallic and/or intermetallic particles, the process may comprise holding at a fixed temperature between room temperature and the processing temperature for a time ranging between about 1 min to about 240 min. The sintering process may comprise holding at a fixed temperature for at least about 10 min, 20 min, 30 min, 40 min, 50 min, 60 min, 90 min, 120 min, 150 min, 180 min, 210 min, 240 min, or more. The sintering process may comprise holding at a fixed temperature for at most about 240 min, 210 min, 180 min, 150 min, 120 min, 90 min, 60 min, 50 min, 40 min, 30 min, 20 min, 10 min, 1 min, or less. In some cases, during the sintering process, the temperature may not be held at a processing temperature for an extended period of time (e.g., once a target temperature is reached, the temperature may be reduced). In an example, the sintering process may increase the temperature to a first temperature and immediately (e.g., without holding at the first temperature for a period of time) lower the temperature to a second temperature that is lower than the first temperature.

A green body comprising ceramic particles may be heated from room temperature to a processing temperature ranging between about 900 degrees Celsius to about 2000 degrees Celsius. The processing temperature may be kept constant or substantially constant for a given period of time, or may be adjusted to one or more other temperatures. The processing temperature for sintering the green body (including the particles) may be at least about 900 degrees Celsius, 950 degrees Celsius, 1000 degrees Celsius, 1050 degrees Celsius, 1100 degrees Celsius, 1150 degrees Celsius, 1200 degrees Celsius, 1300 degrees Celsius, 1400 degrees Celsius, 1500 degrees Celsius, 1600 degrees Celsius, 1700 degrees Celsius, 1800 degrees Celsius, 1900 degrees Celsius, 2000 degrees Celsius, or more. The processing temperature for sintering the green body may be at most about 2000 degrees Celsius, 1900 degrees Celsius, 1800 degrees Celsius, 1700 degrees Celsius, 1600 degrees Celsius, 1500 degrees Celsius, 1400 degrees Celsius, 1300 degrees Celsius, 1200 degrees Celsius, 1150 degrees Celsius, 1100 degrees Celsius, 1050 degrees Celsius, 1000 degrees Celsius, 950 degrees Celsius, 900 degrees Celsius, or less.

In an example, a green body comprising alumina particles may be heated from room temperature to a processing temperature ranging between about 1500 degrees Celsius to about 1950 degrees Celsius. In an example, a green body comprising cemented carbide particles may be heated from room temperature to a processing temperature ranging between about 1700 degrees Celsius. In an example, a green body comprising zirconia particles may be heated from room temperature to a processing temperature ranging between about 1100 degrees Celsius.

During sintering the green body comprising the ceramic particles, the temperature of the processing chamber may change at a rate ranging between about 0.1 degrees Celsius per minute (degrees Celsius/min) to about 200 degrees Celsius/min. The temperature of the processing chamber may change at a rate of at least about 0.1 degrees Celsius/min, 0.2 degrees Celsius/min, 0.3 degrees Celsius/min, 0.4 degrees Celsius/min, 0.5 degrees Celsius/min, 1 degrees Celsius/min, 2 degrees Celsius/min, 3 degrees Celsius/min, 4 degrees Celsius/min, 5 degrees Celsius/min, 6 degrees Celsius/min, 7 degrees Celsius/min, 8 degrees Celsius/min, 9 degrees Celsius/min, 10 degrees Celsius/min, 20 degrees Celsius/min, 50 degrees Celsius/min, 100 degrees Celsius/min, 150 degrees Celsius/min, 200 degrees Celsius/min, or more. The temperature of the processing chamber may change at a rate of at most about 200 degrees Celsius/min, 150 degrees Celsius/min, 100 degrees Celsius/min, 50 degrees Celsius/min, 20 degrees Celsius/min, 10 degrees Celsius/min, 9 degrees Celsius/min, 8 degrees Celsius/min, 7 degrees Celsius/min, 6 degrees Celsius/min, 5 degrees Celsius/min, 4 degrees Celsius/min, 3 degrees Celsius/min, 2 degrees Celsius/min, 1 degrees Celsius/min, 0.5 degrees Celsius/min, 0.4 degrees Celsius/min, 0.3 degrees Celsius/min, 0.2 degrees Celsius/min, 0.1 degrees Celsius/min, or less.

In some cases, during sintering the green body comprising the ceramic particles, the process may comprise holding at a fixed temperature between room temperature and the processing temperature for a time ranging between about 1 min to about 240 min. The sintering process may comprise holding at a fixed temperature for at least about 1 min, 10 min, 20 min, 30 min, 40 min, 50 min, 60 min, 90 min, 120 min, 150 min, 180 min, 210 min, 240 min, or more. The sintering process may comprise holding at a fixed temperature for at most about 240 min, 210 min, 180 min, 150 min, 120 min, 90 min, 60 min, 50 min, 40 min, 30 min, 20 min, 10 min, 1 min, or less. In some cases, during the sintering process, the temperature may not be held at a processing temperature for an extended period of time (e.g., once a target temperature is reached, the temperature may be reduced). In an example, the sintering process may increase the temperature to a first temperature and immediately (e.g., without holding at the first temperature for a period of time) lower the temperature to a second temperature that is lower than the first temperature.

During sintering the green body comprising the plurality of particles (e.g. metal, intermetallic, and/or ceramic), the green body may be subjected to cooling by a fluid (e.g., liquid or gas). The fluid may be applied to the green body and/or the processing chamber to decrease the temperature of the green body. The fluid may be subjected to flow upon application of positive or negative pressure. Examples of the fluid for cooling the green body include water, oil, hydrogen, nitrogen, argon, etc. Cooling the green body during the sintering process may control grain size within the sintered body.

In some cases, the mixture (e.g., the viscous liquid) may further comprise an extractable material. Accordingly, the method may comprise additional steps of treating the green body prior to subjecting the green body to sintering.

The extractable material may be removed by heat that is lower or substantially the same as a temperature sufficient for sintering. Alternatively, the extractable material may be soluble in the polymeric precursor and/or dispersed throughout the mixture. Accordingly, the method may comprise curing the polymeric precursor of the mixture in at least a portion of the mixture, thereby creating a first solid phase comprising the polymeric material and a second solid phase comprising the extractable material within the at least the portion of the 3D object. Such method may be a polymerization-induced phase separation (PIPS) process. The plurality of particles (e.g., metallic, intermetallic, and/or ceramic particles) may be encapsulated by the first solid phase comprising the polymeric material. In some cases, the at least the portion of the 3D object may be a green body that can undergo heating to sinter at least a portion of the plurality of particles and burn off at least a portion of other components (i.e., organic components).

In some cases, the extractable material may be soluble in a solvent (e.g., isopropanol). The solvent may be an extraction solvent. A first solubility of the extractable material in the solvent may be higher than a second solubility of the polymeric material in the solvent. The solvent may be a poor solvent for the polymeric material. Accordingly, the method may further comprise (i) treating (e.g., immersed, jetted, etc.) the green body with the solvent (liquid or vapor), (ii) solubilizing and extracting at least a portion of the extractable material from the second solid phase of the green body into the solvent, and (iii) generating one or more pores in the green body. The one or more pores in the green body may be a plurality of pores. In some cases, the method may further comprise treating the green body with the solvent and heat at the same time. The one or more pores may create at least one continuous porous network in the green body. Such process may be a solvent de-binding process.

The solvent for the solvent de-binding process may not significantly swell the polymeric material in the green body. In some cases, the viscous liquid may comprise acrylate-based polymeric precursors. Since acrylate-based polymers are of intermediate polarity, both protic polar solvents (e.g., water and many alcohols such as isopropanol) and non-polar solvents (e.g., heptane) may be used. Examples of the solvent for the solvent de-binding process include water, isopropanol, heptane, limolene, toluene, and palm oil. On the other hand, intermediate polarity solvents (e.g., acetone) may be avoided.

In some cases, the solvent de-binding process may involve immersing the green body in a container comprising the liquid solvent. A volume of the solvent may be at least about 2 times the volume of the green body. The volume of the solvent may be at least about 2, 3, 4, 5, 6, 7, 8, 9, 10 times or more than the volume of the green body. The container comprising the liquid solvent and the green body may be heated to a temperature ranging between about 25 degrees Celsius to about 50 degrees Celsius. The container comprising the liquid solvent and the green body may be heated (e.g., a water bath, oven, or a heating unit from one or more sides of the green body) to a temperature of at least about 25 degrees Celsius, 26 degrees Celsius, 27 degrees Celsius, 28 degrees Celsius, 29 degrees Celsius, 30 degrees Celsius, 35 degrees Celsius, 40 degrees Celsius, 45 degrees Celsius, 50 degrees Celsius, or more. The container comprising the liquid solvent and the green body may be heated to a temperature of at most about 50 degrees Celsius, 45 degrees Celsius, 40 degrees Celsius, 35 degrees Celsius, 30 degrees Celsius, 29 degrees Celsius, 28 degrees Celsius, 27 degrees Celsius, 26 degrees Celsius, 25 degrees Celsius, or less. The solvent de-binding process may last between about 0.1 hours (h) to about 48 h. The solvent de-binding process may last between at least about 0.1 h, 0.2 h, 0.3 h, 0.4 h, 0.5 h, 1 h, 2 h, 3 h, 4 h, 5 h, 6 h, 12 h, 18 h, 24 h, 30 h, 36 h, 42 h, 48 h, or more. The solvent de-binding may last between at most about 48 h, 42 h, 36 h, 30 h, 24 h, 18 h, 12 h, 6 h, 5 h, 4 h, 3 h, 2 h, 1 h, 0.5 h, 0.4 h, 0.3 h, 0.2 h, 0.1 h, or less. After the solvent de-binding process, the solvent may be removed and the green body may be allowed to dry. A weight of the green body may be measured before and after the solvent de-binding to determine the amount of material extracted from the green body.

After the solvent de-binding process, the green body may be heated (e.g., sintered) and/or cooled as abovementioned. During heating (e.g., sintering), at least a portion of the organic components (e.g., the polymeric material, additives, etc.) may decompose and leave the green body in part through the at least one continuous porous network. The presence of the at least one continuous porous network from the solvent de-binding step may improve the speed of the sintering process.

Subsequent to heating the green body, the heated (e.g., sintered) particles as part of a nascent 3D object may be further processed to yield the 3D object. This may include, for example, performing surface treatment, such as polishing, on the nascent 3D object.

Additional Aspects for 3D Printing

Another aspect of the present disclosure provides systems for printing a 3D object. A system for printing a 3D object may comprise a build surface configured to support a mixture provided in the present disclosure, e.g., a mixture comprising (i) a polymeric precursor, (ii) a photoinitiator configured to initiate formation of a polymeric material from the polymeric precursor, and (iii) a photoinhibitor configured to inhibit formation of the polymeric material from the polymeric precursor. The system may also include one or more optical sources and a controller operatively coupled to the one or more optical sources. The controller may be configured to direct the one or more optical sources to expose the mixture to (i) a first light having a first wavelength sufficient to cause the photoinitiator to initiate formation of the polymeric material from the polymeric precursor at a location disposed away from the build surface, to print at least a portion of the 3D object, and (ii) a second light having a second wavelength sufficient to cause the photoinhibitor to inhibit formation of the polymeric material from the polymeric precursor at a location adjacent to the build surface. During printing of the at least the portion of the 3D object, a ratio of (i) an energy of the second light sufficient to initiate formation of the polymeric material relative to (ii) an energy of the first light sufficient to initiate formation of the polymeric material may be greater than 1. The systems disclosed herein may utilize all components and configurations described in methods for printing a 3D object of the present disclosure.

The ratio of (i) the energy of the second light sufficient to initiate formation of the polymeric material relative to (ii) the energy of the first light sufficient to initiate formation of the polymeric material may be greater than at least about 1, 2, 3, 4, 5, 6, 7, 8, 9, 10, 11, 12, 13, 14, 15, 16, 17, 18, 19, 20, 25, 30, 40, 50, 100, or more. In an example, the ratio is greater than 5. In another example, the ratio is greater than 10. In another example, the ratio is greater than 20. As an alternative, the ratio may be less than or equal to about 100, 50, 40, 30, 25, 20, 19, 18, 17, 16, 15, 14, 13, 12, 11, 10, 9, 8, 7, 6, 5, 4, 3, or 2.

In some cases, the controller may be operatively coupled to a computer system and the system for printing the 3D object. The controller may be configured or programmed to receive or generate a computer model of the 3D object. The at least the portion of the 3D object may be in accordance to the computer model of the 3D object.

In some cases, the controller may be operatively coupled to the build head. The controller may be configured or programmed to direct movement of the build head along a direction away from the build surface during printing the at least the portion of the 3D object. Alternatively or in addition to, the controller may be operatively coupled to the vat or the open platform. The controller may be configured or programmed to direct movement of the vat or the open platform relative to the build head during printing the at least the portion of the 3D object. In some cases, the controller may direct movement of both (i) the build head and (ii) the vat or the open plat form, thereby to direct their relative movement during printing the 3D object.

The controller may be operatively coupled to other components and their configurations described in the aforementioned method for printing a 3D object.

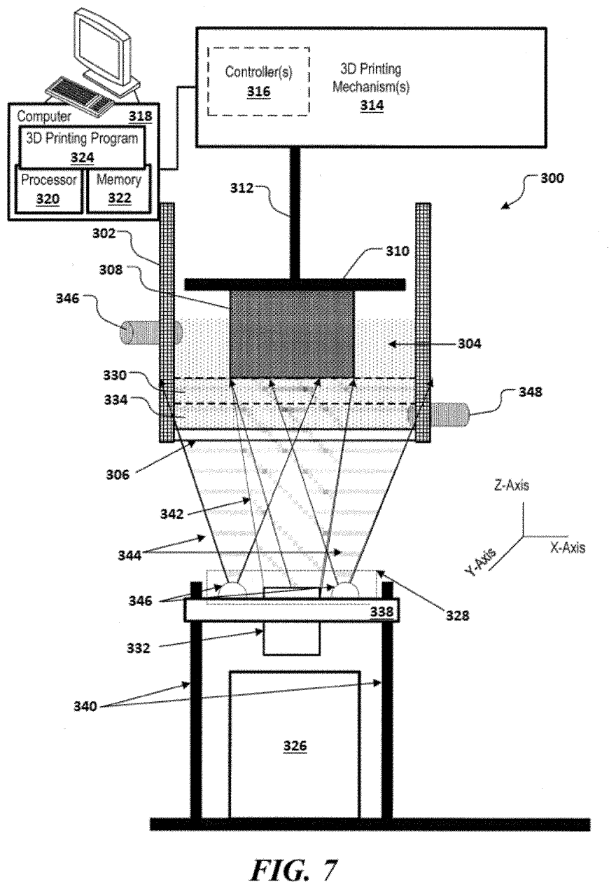

FIG. 7 shows an example of a 3D printing system 300. The system 300 includes a vat 302 to hold a mixture 304, which includes a polymeric precursor. The vat 302 includes a window 306 in its bottom through which illumination is transmitted to cure a 3D printed structure 308. The 3D printed structure 308 is shown in FIG. 7 as a block, however, in practice a wide variety of complicated shapes can be 3D printed. In some cases, the 3D printed structure 308 includes entirely solid structures, hollow core prints, lattice core prints and generative design geometries. Additionally, a 3D printed structure 308 can be partially cured such that the 3D printed structure 308 has a gel-like or viscous mixture characteristic.

The 3D printed structure 308 is 3D printed on a build head 310, which is connected by a rod 312 to one or more 3D printing mechanisms 314. The 3D printing mechanisms 314 can include various mechanical structures for moving the build head 310 within and above the vat 302. This movement is a relative movement, and thus moving pieces can be the build head 310, the vat 302, or both, in various cases. In some cases, the 3D printing mechanisms 314 include Cartesian (xyz) type 3D printer motion systems or delta type 3D printer motion systems. In some cases, the 3D printing mechanisms 314 include one or more controllers 316 which can be implemented using integrated circuit technology, such as an integrated circuit board with embedded processors and firmware. Such controllers 316 can be in communication with a computer or computer systems 318. In some cases, the 3D printing system 100 includes a computer 318 that connects to the 3D printing mechanisms 314 and operates as a controller for the 3D printing system 100.

A computer 318 can include one or more hardware (or computer) processors 320 and a memory 322. For example, a 3D printing program 324 can be stored in the memory 322 and run on the one or more processors 320 to implement the techniques described herein. The controller 318, including the one or more hardware processors 320, may be individually or collectively programmed to implement methods of the present disclosure.

Multiple devices emitting various wavelengths and/or intensities of light, including a light projection device 326 and light sources 328, can be positioned below the window 306 and in communication to the computer 318 (or other controller). In some cases, the multiple devices include the light projection device 326 and the light sources 328. The light sources 328 can include greater than or equal to about 2, 3, 4, 5, 6, 7, 8, 9, 10, or more light sources. As an alternative, the light sources 328 may include less than or equal to about 10, 9, 8 7, 6, 5, 4, 3, 2 or less light sources. As an alternative to the light sources 328, a single light source may be used. The light projection device 326 directs a first light having a first wavelength into the mixture 304 within the vat 302 through window 306. The first wavelength emitted by the light projection device 326 is selected to produce photoinitiation and is used to create the 3D printed structure 308 on the build head 310 by curing the photoactive mixture in the mixture 304 within a photoinitiation layer 330. In some cases, the light projection device 326 is utilized in combination with one or more projection optics 332 (e.g. a projection lens for a digital light processing (DLP) device), such that the light output from the light projection device 326 passes through one or more projection optics 332 prior to illuminating the mixture 304 within the vat 302.

In some cases, the light projection device 326 is a DLP device including a digital micro-mirror device (DMD) for producing patterned light that can selectively illuminate and cure 3D printed structures 308. The light projection device 326, in communication with the computer 318, can receive instructions from the 3D printing program 324 defining a pattern of illumination to be projected from the light projection device 326 into the photoinitiation layer 330 to cure a layer of the photoactive mixture onto the 3D printed structure 308.

In some cases, the light projection device 326 and projection optics 332 are a laser and a scanning mirror system, respectively (e.g., stereolithography apparatus). Additionally, in some cases, the light source includes a second laser and a second scanning mirror system. Such light source may emit a beam of a second light having a second wavelength. The second wavelength may be different from the first wavelength. This may permit photoinhibition to be separately controlled from photoinitiation. Additionally, in some cases, the platform 338 is separately supported on adjustable axis rails 340 from the projection optics 332 such that the platform 338 and the projection optics 332 can be moved independently.

The relative position (e.g., vertical position) of the platform 338 and the vat 302 may be adjusted. In some examples, the platform 338 is moved and the vat 302 is kept stationary. As an alternative, the platform 338 is kept stationary and the vat 302 is moved. As another alternative, both the platform 338 and the vat 302 are moved.

The light sources 328 direct a second light having a second wavelength into the mixture 304 in the vat 302. The second light may be provided as multiple beams from the light sources 328 into the build area simultaneously. As an alternative, the second light may be generated from the light sources 328 and provided as a single beam (e.g., uniform beam) into the beam area. The second wavelength emitted by the light sources 328 is selected to produce photoinhibition in the photoactive mixture in the mixture 304 and is used to create a photoinhibition layer 334 within the mixture 304 directly adjacent to the window 306. The light sources 328 can produce a flood light to create the photoinhibition layer 334, the flood light being a non-patterned, high-intensity light. In some cases, the light sources 328 are light emitting diodes (LEDs) 336. The light sources 328 can be arranged on a platform 338. The platform 338 is mounted on adjustable axis rails 340. The adjustable axis rails 340 allow for movement of the platform 338 along an axis. In some cases, the platform 338 additionally acts as a heat-sink for at least the light sources 328 arranged on the platform 338.

For each of the light projection device 326 and the light sources 328, there is a beam path for light emitted from the respective light source under normal operating conditions (e.g., device is “on”). For example, a depiction of a beam path for light projection device 326 is shown in FIG. 7 as a projection beam path 342. Beam paths 344 are a depiction of exemplary beam paths for two LEDs 336. Although beam paths 342 and 344 are depicted in FIG. 7 as two-dimensional, a beam path can be three-dimensional with a cross-section that can be circular, elliptical, rectangular, or the like. In some cases, the photoinitiation wavelength is approximately 460 nm, and the photoinhibition wavelength is approximately 365 nm.

The respective thicknesses of the photoinitiation layer 330 and the photoinhibition layer 334 can be adjusted by computer 318 (or other controller). In some cases, this change in layer thickness(es) is performed for each new 3D printed layer, depending on the desired thickness of the 3D printed layer, and/or the type of 3D printing process being performed. The thickness(es) of the photoinitiation layer 330 and the photoinhibition layer 334 can be changed, for example, by changing the intensity of the respective light emitting devices, exposure times for the respective light emitting devices, the photoactive species in the mixture 304, or a combination thereof. In some cases, by controlling relative rates of reactions between the photoactive species (e.g., by changing relative or absolute amounts of photoactive species in the mixture, or by adjusting light intensities of the first and/or second wavelength), the overall rate of polymerization can be controlled. This process can thus be used to prevent polymerization from occurring at the mixture-window interface and control the rate at which polymerization takes place in the direction normal to the mixture-window interface.

For example, in some cases, an intensity of the light sources 328 emitting a photoinhibiting wavelength to create a photoinhibition layer 334 is altered in order to change a thickness of the photoinhibition layer 334. Altering the intensity of the light sources 328 can include increasing the intensity or decreasing the intensity of the light sources 328. Increasing the intensity of the light sources 328 (e.g., LEDs) can be achieved by increasing a power input to the light sources 328 by controllers 316 and/or computer 318. Decreasing the intensity of the light sources 328 (e.g., LEDs) can be achieved by decreasing a power input to the light sources 328 by controllers 316 and/or computer 318. In some cases, increasing the intensity of the light sources 328, and thereby increasing the thickness of the photoinhibition layer 334, will result in a decrease in thickness of the photoinitiation layer 330. A decreased photoinitiation layer thickness can result in a thinner 3D printed layer on the 3D printed structure 308.

In some cases, the intensities of all of the light sources 328 are altered equally (e.g., decreased by a same level by reducing power input to all the light sources by an equal amount). The intensities of the light sources 328 can also be altered where each light source of a set of light sources 328 produces a different intensity. For example, for a set of four LEDs generating a photoinhibition layer 334, two of the four LEDs can be decreased in intensity by 10% (by reducing power input to the LEDs) while the other two of the four LEDs can be increased in intensity by 10% (by increasing power input to the LEDs). Setting different intensities for a set of light sources 328 can produce a gradient of thickness in a cured layer of the 3D printed structure or other desirable effects.

In some cases, the computer 318 (in combination with controllers 316) adjusts an amount of a photoinitiator species and/or a photoinhibitor species in the mixture 304. The photoinitiator and photoinhibitor species can be delivered to the vat 302 via an inlet 346 and evacuated from the vat 302 via an outlet 348. In general, one aspect of the photoinhibitor species is to prevent curing (e.g., suppress cross-linking of the polymers) of the photoactive mixture in the mixture 304. In general, one aspect of the photoinitiation species is to promote curing (e.g., enhance cross-linking of the polymers) of the photoactive mixture in the mixture 304. In some cases, the 3D printing system 100 includes multiple containment units to hold input/output flow from the vat 302.

In some cases, the intensities of the light sources 328 are altered based in part on an amount (e.g., volumetric or weight fraction) of the one or more photoinhibitor species in the mixture and/or an amount (e.g., volumetric or weight fraction) of the one or more photoinitiator species in the mixture. Additionally, the intensities of the light sources 328 are altered based in part on a type (e.g., a particular reactive chemistry, brand, composition) of the one or more photoinhibitor species in the mixture and/or a type (e.g., a particular reactive chemistry, brand, composition) of the one or more photoinitiator species in the mixture. For example, an intensity of the light sources 328 for a mixture 304 including a first photoinhibitor species of a high sensitivity (e.g., a high reactivity or conversion ratio to a wavelength of the light sources 328) can be reduced when compared to the intensity of the light sources 328 for a mixture 304 including a second photoinhibitor species of a low sensitivity (e.g., a low reactivity or conversion ratio to a wavelength of the light sources 328).

In some cases, the changes to layer thickness(es) is performed during the creation of the 3D printed structure 308 based on one or more details of the 3D printed structure 308 at one or more points in the 3D printing process. For example, the respective layer thickness(es) can be adjusted to improve resolution of the 3D printed structure 308 in the dimension that is the direction of the movement of the build head 310 relative to the vat 302 (e.g., z-axis) in the layers that require it.

Though the 3D printing system 300 is described in FIG. 1 as a bottom-up system where the light projection device 326 and the light sources 328 are located below the vat 302 and build head 310, other configurations can be utilized. For example, a top-down system, where the light projection device 326 and the light sources 328 are located above the vat 302 and build head 310, can also be employed.

Other features of the printing system 300 of FIG. 1 may be as described in, for example, U.S. Patent Publication No. 2016/0067921 (“THREE DIMENSIONAL PRINTING ADHESION REDUCTION USING PHOTOINHIBITION”), which is entirely incorporated herein by reference.

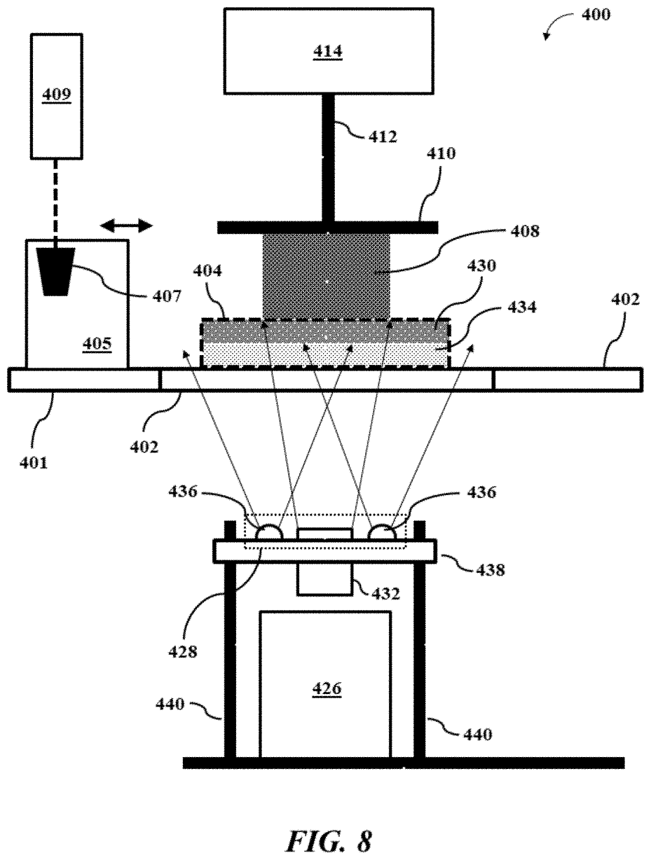

FIG. 8 shows an example of another 3D printing system 400. The system 400 includes an open platform 401 comprising a print window 402 to hold a film of a mixture (e.g., a viscous liquid) 404, which includes a photoactive mixture. The mixture 404 may also include a plurality of particles (e.g., metal, intermetallic, and/or ceramic particles). The system 400 includes a deposition head 405 that comprises a nozzle 407 that is in fluid communication with a source of the mixture 409. The source of the mixture 409 may be a syringe. The syringe may be operatively coupled to a syringe pump. The syringe pump can direct the syringe in a positive direction (from the source of the mixture 409 towards the nozzle 407) to dispense the mixture. The syringe pump can direct the syringe in a negative direction (away from the nozzle 407 towards the source of the mixture 409) to retract any excess mixture in the nozzle and/or on the print window back into the syringe. The deposition head 405 is configured to move across the open platform 401 comprising the print window 402 to deposit the film of the mixture 404. In some cases, the system 400 may comprise an additional source of an additional mixture that is in fluid communication with the nozzle 407 or an additional nozzle of the deposition head 405. In some cases, the system 400 may comprise an additional deposition head comprising an additional nozzle that is in fluid communication with an additional source of an additional mixture. In some cases, the system 400 may comprise three or more deposition heads and three or more sources of the same or different mixtures.

Illumination may be transmitted through the print window 402 to cure at least a portion of the film of the mixture 404 to print at least a portion of a 3D structure 408. The at least the portion of the 3D structure 408 is shown as a block, however, in practice a wide variety of complicated shapes may be printed. In some cases, the at least the portion of the 3D structure 408 includes entirely solid structures, hollow core prints, lattice core prints, and generative design geometries.

The at least the portion of the 3D structure 408 may be printed on a build head 410, which may be connected by a rod 412 to one or more 3D printing mechanisms 414. The 3D printing mechanisms 414 may include various mechanical structures for moving the build head 410 in a direction towards and/or away from the open platform 401. This movement is a relative movement, and thus moving pieces can be the build head 410, the open platform 401, or both, in various embodiments. In some cases, the 3D printing mechanisms 414 include Cartesian (xyz) type 3D printer motion systems or delta type 3D printer motion systems. In some cases, the 3D printing mechanisms 414 include one or more controllers to direct movement of the build head 410, the open platform 401, or both.

Multiple devices emitting various wavelengths and/or intensities of light, including a light projection device 426 and light sources 428, may be positioned below the print window 402 and in communication with the one or more controllers. In some cases, the light sources 428 include greater than or equal to about 2, 3, 4, 5, 6, 7, 8, 9, 10, or more light sources. As an alternative, the light sources 428 can include less than or equal to about 10, 9, 8, 7, 6, 5, 4, 3, 2, or less light sources. As an alternative to the light sources 428, a single light source may be used. The light projection device 426 directs a first light having a first wavelength through the print window 402 and into the film of the mixture 404 adjacent to the print window 402. The first wavelength emitted by the light projection device 426 is selected to produce photoinitiation and is used to create at least a portion of the 3D structure on the at least the portion of the 3D structure 408 that is adjacent to the build head 410 by curing the photoactive mixture in the film of the mixture 404 within a photoinitiation layer 430. In some cases, the light projection device 426 is utilized in combination with one or more projection optics 432 (e.g. a projection lens for a digital light processing (DLP) device), such that the light output from the light projection device 426 passes through the one or more projection optics 432 prior to illuminating the film of the mixture 404 adjacent to the print window 402.

In some cases, the light projection device 426 is a DLP device including a digital micro-mirror device (DMD) for producing patterned light that can selectively illuminate and cure the photoactive mixture in the photoinitiation layer 430. The light projection device 426, in communication with the one or more controllers, may receive instructions defining a pattern of illumination to be projected from the light projection device 426 into the photoinitiation layer 430 to cure a layer of the photoactive mixture onto the at least the portion of the 3D structure 408.

The light sources 428 direct a second light having a second wavelength into the film of the mixture 404 adjacent to the open platform 401 comprising the print window 402. The second light may be provided as multiple beams from the light sources 428 through the print window 402 simultaneously. As an alternative, the second light may be generated from the light sources 428 and provided as a single beam through the print window 402. The second wavelength emitted by the light sources 428 is selected to produce photoinhibition in the photoactive mixture in the film of the mixture 404 and is used to create a photoinhibition layer 434 within the film of the mixture 404 directly adjacent to the print window 402. The light sources 428 can produce a flood light to create the photoinhibition layer 434, the flood light being a non-patterned, high-intensity light. In some cases, the light sources 428 are light emitting diodes (LEDs) 436. The light sources 428 can be arranged on a light platform 438. The light platform 438 is mounted on adjustable axis rails 440. The adjustable axis rails 440 allow for movement of the light platform 438 along an axis towards or away from the print window 402. The light platform 438 and the one or more projection optics 432 may be moved independently. A relative position of the light platform comprising the light sources may be adjusted to project the second light into the photoinhibition layer 434 at the respective peak intensity and/or in a uniform projection manner. In some cases, the light platform 438 functions as a heat-sink for at least the light sources 428 arranged on the light platform 438.

The respective thicknesses of the photoinitiation layer 430 and the photoinhibition layer 434 may be adjusted by the one or more controllers. In some cases, this change in layer thickness(es) is performed for each new 3D printed layer, depending on the desired thickness of the 3D printed layer, and/or the type of mixture in the film of the mixture 404. The thickness(es) of the photoinitiation layer 430 and the photoinhibition layer 434 may be changed, for example, by changing the intensity of the respective light emitting devices (426 and/or 428), exposure times for the respective light emitting devices, or both. In some cases, by controlling relative rates of reactions between the photoactive species (e.g., at least one photoinitiator and at least one photoinhibitor), the overall rate of curing of the photoactive mixture in the photoinitiation layer 430 and/or the photoinhibition layer 434 may be controlled. This process can thus be used to prevent curing from occurring at the film of the mixture-print window interface and control the rate at which curing of the photoactive mixture takes place in the direction normal to the film of the photoactive mixture-print window interface.

Other features of the printing system 400 of FIG. 2 may be as described in, for example, U.S. Patent Publication No. 2018/0333912 (“VISCOUS FILM THREE-DIMENSIONAL PRINTING SYSTEMS AND METHODS”), which is entirely incorporated herein by reference.

Any of the methods disclosed herein may further comprise subjecting a printed 3D object (e.g., a green body) to heating (e.g., in a furnace) to, for example, heat a plurality of particles in the mixture. In some embodiments, the plurality of particles may be granulated particles, as provided herein. Alternatively or in addition to, the plurality of particles may comprise nanoparticles formed from reaction of a plurality of precursor compounds. The heating may be under conditions sufficient to sinter the plurality of particles to form a final product that is at least a portion of a 3D object or an entire 3D object. During heating (e.g., sintering), the organic components (e.g., the polymeric material, additives, etc.) may decompose and leave the green body. At least a portion of the decomposed organic components may leave the green body in gas phase.

Computer Systems

The present disclosure provides computer systems that are programmed to implement methods of the disclosure. Computer systems of the present disclosure may be used to regulate various operations of 3D printing, such as (i) providing a vat containing a mixture comprising a photoactive mixture or a film of the mixture adjacent to an open platform and (ii) directing an optical source to provide light to the mixture to cure at least a portion of the mixture.

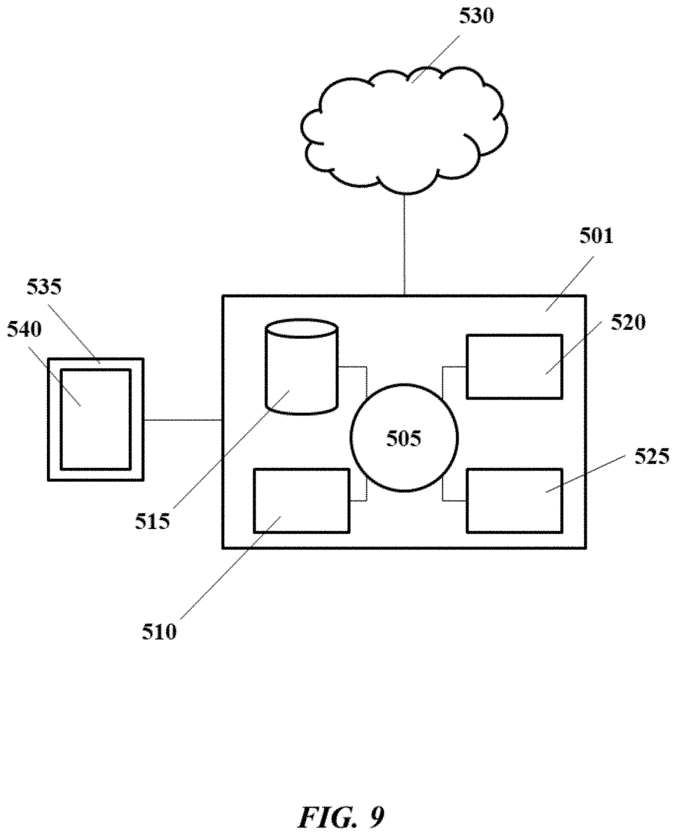

FIG. 9 shows a computer system 501 that is programmed or otherwise configured to communicate with and regulate various aspects of a 3D printer of the present disclosure. The computer system 501 can communicate with the light sources, build head, the inlet and/or outlet of a vat containing the mixture, and/or the open platform configured to hold a film of the mixture. The computer system 501 may also communicate with the 3D printing mechanisms or one or more controllers of the present disclosure. The computer system 501 can be an electronic device of a user or a computer system that is remotely located with respect to the electronic device. The electronic device can be a mobile electronic device.

The computer system 501 includes a central processing unit (CPU, also “processor” and “computer processor” herein) 505, which can be a single core or multi core processor, or a plurality of processors for parallel processing. The computer system 501 also includes memory or memory location 510 (e.g., random-access memory, read-only memory, flash memory), electronic storage unit 515 (e.g., hard disk), communication interface 520 (e.g., network adapter) for communicating with one or more other systems, and peripheral devices 525, such as cache, other memory, data storage and/or electronic display adapters. The memory 510, storage unit 515, interface 520 and peripheral devices 525 are in communication with the CPU 505 through a communication bus (solid lines), such as a motherboard. The storage unit 515 can be a data storage unit (or data repository) for storing data. The computer system 501 can be operatively coupled to a computer network (“network”) 530 with the aid of the communication interface 520. The network 530 can be the Internet, an internet and/or extranet, or an intranet and/or extranet that is in communication with the Internet. The network 530 in some cases is a telecommunication and/or data network. The network 530 can include one or more computer servers, which can enable distributed computing, such as cloud computing. The network 530, in some cases with the aid of the computer system 501, can implement a peer-to-peer network, which may enable devices coupled to the computer system 501 to behave as a client or a server.

The CPU 505 can execute a sequence of machine-readable instructions, which can be embodied in a program or software. The instructions may be stored in a memory location, such as the memory 510. The instructions can be directed to the CPU 505, which can subsequently program or otherwise configure the CPU 505 to implement methods of the present disclosure. Examples of operations performed by the CPU 505 can include fetch, decode, execute, and writeback.

The CPU 505 can be part of a circuit, such as an integrated circuit. One or more other components of the system 501 can be included in the circuit. In some cases, the circuit is an application specific integrated circuit (ASIC).

The storage unit 515 can store files, such as drivers, libraries and saved programs. The storage unit 515 can store user data, e.g., user preferences and user programs. The computer system 501 in some cases can include one or more additional data storage units that are external to the computer system 501, such as located on a remote server that is in communication with the computer system 501 through an intranet or the Internet.

The computer system 501 can communicate with one or more remote computer systems through the network 530. For instance, the computer system 501 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 501 via the network 530.

Methods as described herein can be implemented by way of machine (e.g., computer processor) executable code stored on an electronic storage location of the computer system 501, such as, for example, on the memory 510 or electronic storage unit 515. The machine executable or machine readable code can be provided in the form of software. During use, the code can be executed by the processor 505. In some cases, the code can be retrieved from the storage unit 515 and stored on the memory 510 for ready access by the processor 505. In some situations, the electronic storage unit 515 can be precluded, and machine-executable instructions are stored on memory 510.

The code can be pre-compiled and configured for use with a machine having a processer adapted to execute the code, or can be compiled during runtime. The code can be supplied in a programming language that can be selected to enable the code to execute in a pre-compiled or as-compiled fashion.

Aspects of the systems and methods provided herein, such as the computer system 501, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 501 can include or be in communication with an electronic display 535 that comprises a user interface (UI) 540 for providing, for example, a window displaying a plurality of mixtures that the user can select to use for 3D printing. Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 505. The algorithm can, for example, determine appropriate intensity and exposure time of (i) the photoinitiation light and/or (ii) the photoinitiation light during the 3D printing.

Methods and systems of the present disclosure may be combined with or modified by other methods and systems, such as, for example, those described U.S. Patent Publication No. 2016/0067921 (“THREE DIMENSIONAL PRINTING ADHESION REDUCTION USING PHOTOINHIBITION”), U.S. Patent Publication No. 2016/0167301 (“POLYMERIC PHOTOINITIATORS FOR 3D PRINTING APPLICATIONS”), U.S. Patent Publication No. 2018/0348646 (“MULTI WAVELENGTH STEREOLITHOGRAPHY HARDWARE CONFIGURATIONS”), U.S. Patent Publication No. 2018/0333912 (“VISCOUS FILM THREE-DIMENSIONAL PRINTING SYSTEMS AND METHODS”), U.S. Patent Publication No. 20180361666 (“METHODS AND SYSTEMS FOR STEREOLITHOGRAPHY THREE-DIMENSIONAL PRINTING”), and International Patent Application No. PCT/US2020/033279 (“STEREOLITHOGRAPHY THREE-DIMENSIONAL PRINTING SYSTEMS AND METHODS”), each of which is entirely incorporated herein by reference.

### EXAMPLES

### Example 1: Granulated Particles

FIG. 1A shows a SEM image of small and non-granulated metal particles that can be used to form granulated metal particles, as shown in FIG. 1B. The small metal particles in FIG. 1A have an average diameter (e.g., d₅₀) of about 6.1 μm. The granulated particles in FIG. 1B have an average diameter (e.g., d₅₀) of 70 μm.

### Example 2: Granulated Particle

Granulated 17-4PH stainless steel particles were obtained from Atmix (17-4PH SC1308). The granulated particles were aggregations of 8 μm stainless steel particles using at least one water-soluble binder. The granulated particles were put through a sieve to limit the particle size distribution to between about 45 μm and about 105 μm. Composite mixtures (#1-#5) for 3D printing were made using various formulations as shown in Table 2. The formulations included photopolymers (monomers), photoinitiators (including co-initiators), UV absorbers, photoinhibitors, inert fillers and metal particles. The formulations were mixed using a SpeedMixer™ from FlackTek, Inc.

Thin films made from each composite mixture (#1-#5) and were cast onto methacrylate functionalized slides. Different portions of the films were exposed to different doses of photoinitiation light of 460 nm wavelength (energy per unit area) for curing. The thicknesses of the cured portions were then measured using an optical profilometer. FIG. 2A is a plot that shows thickness of the cured layer portions as a function of dose of the photoinitiation light. Data point 1215 indicates a measurement of reference panel, and dada points 1210 indicate measurements of Formulation #3 of Table 2. As illustrated by FIG. 2A, the mixture comprising a plurality of granulated particles exhibited near linear increase in the thickness of the cured layer as a function of the dose of the photoinitiation light. This may suggest that the plurality of granulated particles suspended in the mixture exhibited minimal scattering of the photoinitiation light.

The penetration depth of the photoinitiation light into the mixture can be determined by the slope of a semi-log regression of the curve shown in FIG. 2A using equation (1) of the present disclosure. A plot of penetration depth as a function of inverse volume fraction (1/Φ) of the granulated particles in the mixture is shown in FIG. 2B, suggesting an inverse relationship between the measured penetration depth and the volume fraction of the granulated particles in the mixture. From equation (2) the slope allows the effective scattering diameter to be estimated to be about 38 μm (as indicated by data point 1230 in FIG. 2C). In comparison, FIG. 2C is a plot that shows light scattering diameter<d> for the small particles (non-granulated) as a function of mean metal particle diameter (d₅₀), as indicated by data points 1235. The effective scattering diameter for the granulated particles comprising an aggregation of a plurality of small particles (1230) is much greater than 8 μm that would be expected from the small particles from which they were made, and it is smaller or within the lower range of light scattering diameter of 45-106 μm that would be expected from solid non-granulated particles having similar dimensions as the granulated particles.

FIG. 2D illustrates a working curve that shows thickness of the cured layer portions as a function of dose of the photoinitiation light for a control mixture that comprises small individual stainless steel particles that (i) are not granulated and (ii) have an average diameter of about 4 μm. Composition of the control mixture may be similar to that of the Formulation #3 in Table 2, except for the presence of the granulated particles. For example, an amount (weight %) of the non-granulated stainless steel particles in the control mixture may be similar or substantially the same as an amount (weight %) of the granulated stainless steel particles in Formulation #3. As illustrated by FIG. 2D, data point 1245 indicates a measurement of reference panel, and dada points 1240 indicate measurements of the control mixture. The control mixture comprising non-granulated stainless steel particles may require a dose of the photoinitiation light at about 200 millijoule per square (mJ/cm²) to achieve a cured thickness of about 100 μm. In contrast, as shown in FIG. 2A, Formulation #3 comprising granulated stainless steel particles may require a dose of the photoinitiation light at about 50 mJ/cm², about 70-75% less than that requires for the control mixture. This may suggest that while the total amount (weight %) of stainless steel particles may be similar, the granulated particles may scatter the photoinitiation light less than the non-granulated particles, thereby (i) improving light penetration depth and/or (ii) decreasing a required dose of the photoinitiation light to form a polymeric material from a plurality of polymeric precursors.

TABLE 2
Composite Mixture Formulations and Measured Penetration Depths

| | | Material | Formulations (wt %) | | | | |
|---|---|---|---|---|---|---|---|
| Supplier | Material Name | Function | # 1 | # 2 | # 3 | # 4 | # 5 |
| Sartomer | SR339 | monomer | 9.74 | 7.80 | 6.67 | 4.53 | 3.56 |
| Alined | Ebecryl 130 | monomer | 38.94 | 31.18 | 26.68 | 18.12 | 14.24 |
| Hampford | CQ | photointiator | 0.98 | 0.78 | 0.67 | 0.45 | 0.36 |
| Research | | | | | | | |
| TCI | EDMAB | co-initiator | 0.59 | 0.47 | 0.40 | 0.27 | 0.22 |
| America | | | | | | | |
| Tronly | HABI 102 | photoinhibitor | 0.98 | 0.78 | 0.67 | 0.46 | 0.36 |
| Everlight | Eversorb 109 | UV absorber | 1.83 | 1.47 | 1.26 | 0.85 | 0.67 |
| | Benzotriazole | | | | | | |
| Atmix | Stainless Steel | metal particles | 0.00 | 19.94 | 31.50 | 53.47 | 70.92 |
| | Granulated | | | | | | |
| | Particles (17- | | | | | | |
| | 4PHSC1308) | | | | | | |
| Miralax | Micronized PEG | inert filler | 46.94 | 37.58 | 32.15 | 21.84 | 9.68 |

| | | | | | |
|---|---|---|---|---|---|
| Penetration Depth, dₚ (μm) | 832 | 384 | 224 | 83.7 | 56.2 |

### Example 3: Precursor Compounds to Form and/or Coalesce Particles

FIG. 5 schematically illustrates an example of a mixture 1500 for 3D printing, as provided herein. The mixture 1500 comprises a plurality of polymeric precursors 1510 configured to form a polymeric material. The mixture 1500 further comprises at least one photoinitiator 1520 configured to initiate formation of the polymeric material from the plurality of polymeric precursors. The mixture 1500 further comprises at least one photoinhibitor 1530 configured to inhibit formation of the polymeric material from the plurality of polymeric precursors. The mixture 1500 further comprises a plurality of precursor compounds 1540 configured to react to form a first population of particles (e.g., nanoparticles). In an example, the mixture 1500 comprises a plurality of organometallic compounds configured to react to form a population of metallic nanoparticles. The mixture 1500 further comprises a second population of particles 1550 (e.g., pre-formed microparticles of metal, ceramic, and/or cermet). The mixture 1500 further comprises a filler 1560 (e.g., an inert filler).

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1-53. (canceled)

54. A mixture for printing a three-dimensional (3D) object, comprising:
a plurality of polymeric precursors configured to form a polymeric material;
at least one photoinitiator configured to initiate formation of said polymeric material from said plurality of polymeric precursors; and
a plurality of precursor compounds configured to react to form a first plurality of particles.

55. The mixture of claim 54, wherein a precursor of said plurality of precursor compounds comprises an inorganic material coupled to an organic material, wherein a plurality of said inorganic material is configured to form said first plurality of particles.

56. The mixture of claim 54, wherein said plurality of precursor compounds is configured to decompose to form said first plurality of particles.

57. The mixture of claim 54, wherein (i) at least a portion of said polymeric material is configured to decompose at a first temperature and (ii) said plurality of precursor compounds is configured to decompose at a second temperature.

58. (canceled)

59. (canceled)

60. The mixture of claim 54, wherein said first plurality of particles comprises a plurality of nanoparticles, wherein a nanoparticle of said plurality of nanoparticles has a size less than about 500 nanometers (nm).

61. The mixture of claim 54, wherein said first plurality of particles comprises a plurality of nanoparticles, wherein a nanoparticle of said plurality of nanoparticles has a size between about 1 nm and about 200 nm.

62. The mixture of claim 54, further comprising a second plurality of particles, wherein (i) a size of a particle of said second plurality of particles is greater than (ii) a size of a particle of said first plurality of particles.

63. The mixture of claim 62, wherein said size of said particle of said second plurality of particles is greater than about 500 nm.

64. (canceled)

65. The mixture of claim 54, wherein said first plurality of particles comprises one or more members selected from the group comprising at least one metal particle, at least one ceramic particle, and at least one cermet particle.

66-78. (canceled)

79. A method for printing a three-dimensional (3D) object, comprising:
(a) providing, adjacent to a build surface, a mixture comprising (i) a plurality of polymeric precursors configured to form a polymeric material, (ii) at least one photoinitiator configured to initiate formation of said polymeric material from said plurality of polymeric precursors, and (iii) a plurality of precursor compounds configured to react to form a first plurality of particles; and
(b) exposing said mixture to a light under conditions sufficient to cause said at least one photoinitiator to initiate said formation of said polymeric material from said plurality of polymeric precursors, wherein said polymeric material encapsulates at least said plurality of precursor compounds, to print at least a portion of said 3D object.

80. (canceled)

81. The method of claim 79, wherein a precursor of said plurality of precursor compounds comprises an inorganic material coupled to an organic material, wherein a plurality of said inorganic material is configured to form said first plurality of particles.

82. The method of claim 79, further comprising, subsequent to (b), decomposing said plurality of precursors to form said first plurality of particles.

83. The method of claim 82, further comprising (i) exposing said polymeric material to heat at a first temperature to decompose said at least said portion of said polymeric material and (ii) exposing said plurality of precursor compounds to heat at a second temperature to decompose said plurality of precursor compounds.

84. (canceled)

85. (canceled)

86. The method of claim 79, wherein said first plurality of particles comprises a plurality of nanoparticles, wherein a nanoparticle of said plurality of nanoparticles has a size less than about 500 nanometers (nm).

87. The method of claim 79, wherein said first plurality of particles comprises a plurality of nanoparticles, wherein a nanoparticle of said plurality of nanoparticles has a size between about 1 nm and about 200 nm.

88. The method of claim 79, wherein said mixture further comprises a second plurality of particles, wherein (i) a size of a particle of said second plurality of particles is greater than (ii) a size of a particle of said first plurality of particles.

89. The method of claim 88, further comprising (i) forming said first plurality of particles from said plurality of precursor compounds and (ii) subjecting said second plurality of particles and said first plurality of particles to heat at a third temperature, to coalesce said second plurality of particles and said first plurality of particles to heat, to form a 3D structure.

90. (canceled)

91. The method of claim 89, wherein said third temperature is between about 800 degrees Celsius (° C.) and about 2000° C.

92. The method of claim 88, wherein said size of said particle of said second plurality of particles is greater than about 500 nm.

93. (canceled)

94. The method of claim 79, wherein said first plurality of particles comprises one or more members selected from the group comprising at least one metal particle, at least one ceramic particle, and at least one cermet particle.
